(19) United States
(12) Patent Application Publication
(10) Pub. No.: US 2025/0076762 A1
(43) Pub. Date: Mar. 6, 2025

(54) RADIATION-SENSITIVE RESIN COMPOSITION AND METHOD FOR FORMING PATTERN

(71) Applicant: JSR CORPORATION, Tokyo (JP)

(72) Inventors: Ryuichi NEMOTO, Tokyo (JP); Masayuki MIYAKE, Tokyo (JP); Hajime INAMI, Tokyo (JP); Tsuyoshi FURUKAWA, Tokyo (JP); Noboru OTSUKA, Tokyo (JP); Kensuke MIYAO, Tokyo (JP)

(73) Assignee: JSR CORPORATION, Tokyo (JP)

(21) Appl. No.: 18/951,861

(22) Filed: Nov. 19, 2024

Related U.S. Application Data
(63) Continuation of application No. PCT/JP2023/018515, filed on May 18, 2023.

(30) Foreign Application Priority Data
May 23, 2022 (JP) 2022-083678

(51) Int. Cl. G03F 7/029; G03F 7/004

(52) U.S. Cl. CPC G03F 7/0295; G03F 7/0045

(57) ABSTRACT

A radiation-sensitive resin composition includes: a first onium salt compound represented by formula (1); a second onium salt compound represented by formula (2); a resin including an acid-dissociable group; and a solvent. R¹ is a substituted or unsubstituted monovalent hydrocarbon group or the like; R² and R³ are each independently a hydrogen atom, a fluorine atom, or the like; and Z⁺ represents a monovalent radiation-sensitive onium cation. R⁴ is a monovalent organic group; one of R^{f21} and R^{f22} is a fluorine atom, and the other is a fluorine atom or a monovalent fluorinated hydrocarbon group; Ar is a monovalent organic group including an aromatic ring; R⁵, R⁶, R⁷, and R⁸ each independently represent a hydrogen atom, a hydroxy group, a halogen atom, or a monovalent organic group; and X is a single bond or a divalent hetero atom-containing group.

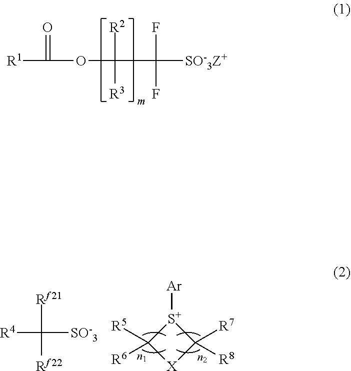

### CROSS-REFERENCE TO RELATED APPLICATIONS

The present application is a continuation-in-part application of International Patent Application No. PCT/JP2023/018515 filed May 18, 2023, which claims priority to Japanese Patent Application No. 2022-083678 filed May 23, 2022. The contents of these applications are incorporated herein by reference in their entirety.

### BACKGROUND OF THE DISCLOSURE

### Technical Field

The present disclosure relates to a radiation-sensitive resin composition and a method for forming a pattern.

### Background Art

A photolithography technology using a resist composition has been used for the fine circuit formation in a semiconductor device. As the representative procedure, for example, a resist pattern is formed on a substrate by generating an acid by irradiating the coating of the resist composition with a radioactive ray through a mask pattern, and then reacting in the presence of the acid as a catalyst to generate the difference of solubility of a resin into an alkaline or organic developer between an exposed part and a non-exposed part.

In the photolithography technique, the micronization of the pattern is promoted by using a short-wavelength radioactive ray such as an ArF excimer laser or by using an immersion exposure method (liquid immersion lithography) in which exposure is performed in a state in which a space between a lens of an exposure apparatus and a resist film is filled with a liquid medium. As a next-generation technology, lithography using shorter wavelength radiation such as electron beams, X-rays and EUV (extreme ultraviolet rays) is also being considered.

As for the photoacid generator, which is a main component of the resist composition, perfluoroalkylsulfonic acid capable of imparting strong acidity is often used from the viewpoint of improving sensitivity, resolution, etc. On the other hand, in recent years, due to the increasing environmental awareness, photoacid generators in which only the peripheral part of the sulfonic acid is fluorinated are being considered (see JP-A-2013-114085).

### SUMMARY

According to an aspect of the present disclosure, a radiation-sensitive resin composition includes: a first onium salt compound represented by formula (1); a second onium salt compound represented by formula (2), which is other than the first onium salt compound; a resin including a structural unit having an acid-dissociable group; and a solvent.

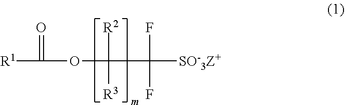

R¹ is a substituted or unsubstituted monovalent hydrocarbon group having 1 to 5 carbon atoms or a group comprising a divalent hetero atom-containing group between two adjacent carbon atoms of the hydrocarbon group; R² and R³ are each independently a hydrogen atom, a fluorine atom, a monovalent hydrocarbon group, or a monovalent fluorinated hydrocarbon group, when there are a plurality of R²s and R³s, the plurality of R²s are each the same or different from each other, and the plurality of R³s are each the same or different from each other; m is an integer of 0 to 8; and Z⁺ represents a monovalent radiation-sensitive onium cation,

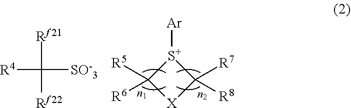

R⁴ is a monovalent organic group having 1 to 40 carbon atoms; one of R^{f21} and R^{f22} is a fluorine atom, and the other is a fluorine atom or a monovalent fluorinated hydrocarbon group; Ar is a monovalent organic group including an aromatic ring having 5 to 40 ring atoms, R⁵, R⁶, R⁷, and R⁸ each independently represent a hydrogen atom, a hydroxy group, a halogen atom, or a monovalent organic group having 1 to 20 carbon atoms, when there are a plurality of R⁵s, R⁶s, R⁷s, and R⁸s, the plurality of R²s are each the same or different from each other, the plurality of R⁶s are each the same or different from each other, the plurality of R⁷s are each the same or different from each other, and the plurality of R⁸s are each the same or different from each other; n₁ and n₂ are each independently an integer of 1 to 6; and X is a single bond or a divalent hetero atom-containing group.

According to another aspect of the present disclosure, a pattern formation method, includes: applying the above-described radiation-sensitive resin composition directly or indirectly to a substrate to form a resist film; exposing the resist film; and developing the exposed resist film with a developer.

### DESCRIPTION OF THE EMBODIMENTS

One of the applications of resist compositions is to form high-aspect-ratio resist patterns with line widths and hole diameters of 100 nm or less, and resist film thicknesses of 100 nm to 200 nm, or even greater than these thicknesses.

When forming patterns with such high aspect ratios, equivalent to or better performance than conventional pattern is required in terms of the sensitivity, LWR (Line Width Roughness) performance (which indicates the variation in line width and resist pattern line width), DOF (Depth of Focus) performance, pattern rectangularity (which indicates the rectangularity of the cross-sectional shape of the resist pattern), critical dimension uniformity (CDU) performance (which is an indicator of the uniformity of line width and hole diameter), and pattern circularity (which indicates the circularity of the hole shape).

The photosensitive resin composition of the present disclosure contains both a first and second onium salt compound as photosensitive acid generators, so it is possible to form a resist film that exhibits excellent sensitivity, LWR performance, DOF performance, pattern rectangularity, CDU performance, and pattern circularity even when forming a resist pattern with a high aspect ratio. The reason for this is not bound by any theory, but can be speculated as follows.

The anion portion of the first onium salt compound has a relatively low molecular structure, and the steric hindrance effect is small, so the diffusion length of the generated acid is relatively long. This allows the generated acid to be sufficiently distributed without being unevenly distributed even if the resist film is thick. In addition, not all of the carbon atoms in the anion portion are fluorinated, so the mobility of the carbon chain is improved, and this also enhances the homogeneity of the diffusion of the generated acid.

The cation part of the second onium salt compound is highly transparent to radiation and has a high quantum efficiency due to its structure, so even with a thick resist film, the acid can be generated efficiently throughout the thickness direction during exposure.

By combining the properties of these first and second onium salt compounds, the effects of the two are complementary, and it becomes possible to give the optimal acid diffusion length, solubility, and acidity for various pattern sizes that would be difficult to achieve with a single composition. As a result, it is thought that the given resist properties can be exhibited. Note that the term “organic group” refers to a group containing at least one carbon atom.

The pattern formation method uses the above photosensitive resin composition, which can form a resist film with excellent sensitivity, LWR performance, DOF performance, pattern rectangularity, CDU performance, and pattern circularity, so it is possible to efficiently form high-quality resist patterns.

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Hereinbelow, embodiments of the present disclosure will be described in detail, but the present disclosure is not limited to these embodiments.

### <Radiation-Sensitive Resin Composition>

The radiation-sensitive resin composition (hereinafter also simply referred to as “composition”) according to the present embodiment includes a first onium salt compound, a second onium salt compound, a resin containing a structural unit having an acid-dissociable group, and a solvent. The radiation-sensitive resin composition further includes an acid diffusion controlling agent, as necessary. The composition may further contain other optional components as long as the effects of the present invention are not impaired. Owing to the inclusion of both the first onium salt compound and the second onium salt compound as radiation-sensitive acid generators in a radiation-sensitive resin composition, the radiation-sensitive resin composition can impart sensitivity, LWR performance, DOF performance, pattern rectangularity, CDU performance, and pattern circularity at high levels to a resist film of the radiation-sensitive resin composition.

### (First Onium Salt Compound)

The first onium salt compound is represented by the formula (1), and functions as a radiation-sensitive acid generator that generates an acid in response to irradiation with radiation.

Examples of the monovalent hydrocarbon group having 1 to 5 carbon atoms in R¹ include a monovalent chain hydrocarbon group having 1 to 5 carbon atoms, and a monovalent alicyclic hydrocarbon group having 3 to 5 carbon atoms.

Examples of the monovalent chain hydrocarbon group having 1 to 5 carbon atoms include a linear or branched saturated hydrocarbon group having 1 to 5 carbon atoms and a linear or branched unsaturated hydrocarbon group having 2 to 5 carbon atoms. Examples of the monovalent linear or branched saturated hydrocarbon group having 1 to 5 carbon atoms include alkyl groups having 1 to 5 carbon atoms such as a methyl group, an ethyl group, a n-propyl group, an i-propyl group, a n-butyl group, a 2-methylpropyl group, a 1-methylpropyl group, a t-butyl group, a n-pentyl group, an isopentyl group, and a neopentyl group. Examples of the monovalent linear or branched unsaturated hydrocarbon group having 2 to 5 carbon atoms include alkenyl groups having 2 to 5 carbon atoms such as a vinyl group, an allyl group, a 1-propenyl group, an isopropenyl group, a 1-butenyl group, a 2-butenyl group, a 3-butenyl group, a 2-methyl-2-propenyl group, a 1-pentenyl group, a 2-pentenyl group, a 3-pentenyl group, a 4-pentenyl group, a 2-methyl-2-butenyl group, and a 1,2-dimethyl-2-propenyl group; and alkynyl groups having 2 to 5 carbon atoms such as an ethynyl group, a 1-propynyl group, a 2-propynyl group, a 1-butynyl group, a 2-butynyl group, a 3-butynyl group, a 1-methyl-2-propynyl group, a 1-pentynyl group, a 2-pentynyl group, a 3-pentynyl group, a 4-pentynyl group, and a 1-methyl-3-butynyl group.

Examples of the monovalent alicyclic hydrocarbon group having 3 to 5 carbon atoms include a monocyclic saturated or unsaturated hydrocarbon group and a polycyclic saturated hydrocarbon group. Examples of the monocyclic saturated hydrocarbon group include a cyclopropyl group, a 1-methylcyclopropyl group, a cyclobutyl group, a 1-methylcyclobutyl group, and a cyclopentyl group. Examples of the monocyclic unsaturated hydrocarbon group include a cyclopropenyl group, a cyclobutenyl group, and a cyclopentenyl group. Examples of the polycyclic saturated hydrocarbon group include a bicyclobutyl group and a spiropentyl group.

As the monovalent hydrocarbon group having 1 to 5 carbon atoms represented by R¹, a monovalent saturated hydrocarbon group having 1 to 5 carbon atoms is preferable, and a monovalent chain saturated hydrocarbon group having 1 to 5 carbon atoms or a monovalent alicyclic saturated hydrocarbon group having 3 to 5 carbon atoms is more preferable.

Examples of the substituent that substitutes for some or all of the hydrogen atoms of R¹ include halogen atoms such as a fluorine atom, a chlorine atom, a bromine atom, and an iodine atom; a hydroxy group; a carboxy group; a cyano group; a nitro group; an alkyl group, an alkoxy group, an alkoxycarbonyl group, an alkoxycarbonyloxy group, an acyl group, an acyloxy group, or a group in which a hydrogen atom of these groups has been substituted with a halogen atom; and an oxo group (═O).

Examples of the divalent hetero atom-containing group of a group containing a divalent hetero atom-containing group between two adjacent carbon atoms of the hydrocarbon group represented by R¹ include —CO—, —CS—, —O—, —S—, —SO₂—, and —NR″—, and a combination of two or more thereof can also be suitably used. R″ represents a hydrogen atom or a monovalent hydrocarbon group having 1 to 4 carbon atoms. When R¹ has the divalent hetero atom-containing group, the number of the divalent hetero atom-containing group is preferably 1 or 2.

When R¹ has the substituent and the divalent hetero atom-containing group, R¹ satisfies 1 to 5 carbon atoms including the number of the carbon atoms of these groups.

Examples of the monovalent hydrocarbon groups represented by R² and R³ include groups obtained by extending the monovalent chain hydrocarbon groups having 1 to 5 carbon atoms in R¹ to 20 carbon atoms, groups obtained by extending the monovalent alicyclic hydrocarbon groups having 3 to 5 carbon atoms in R¹ to 20 carbon atoms, and monovalent aromatic hydrocarbon groups having 6 to 20 carbon atoms, and combinations thereof.

Examples of the monovalent chain hydrocarbon groups having 1 to 20 carbon atoms in R² and R³ include a monovalent chain hydrocarbon group having 6 to 20 carbon atoms in addition to the groups recited as examples of the monovalent chain hydrocarbon group having 1 to 5 carbon atoms in R¹. Examples of the monovalent chain hydrocarbon group having 6 to 20 carbon atoms include alkyl groups having 6 to 20 carbon atoms such as a n-hexyl group, an isohexyl group, a sec-hexyl group, a tert-hexyl group, a neohexyl group, a 2-methylpentyl group, a 3-methylpentyl group, a 1,2-dimethylbutyl group, a 2,2-dimethylbutyl group, a 1-ethylbutyl group, a 2-ethylbutyl group, a n-heptyl group, an isoheptyl group, a sec-heptyl group, a tert-heptyl group, a neoheptyl group, a 2-methylhexyl group, a 3-methylhexyl group, a 2,2-dimethylpentyl group, a 3-ethylpentyl group, a 2,4-dimethylpentyl group, a 1-ethyl-1-methylbutyl group, a 1, 2, 3-trimethylbutyl group, a n-octyl group, an isooctyl group, a sec-octyl group, a tert-octyl group, and a neooctyl group; alkenyl groups having 6 to 20 carbon atoms such as a 1-hexenyl group, a 2-hexenyl group, a 3-hexenyl group, a 4-hexenyl group, a 5-hexenyl group, a 2-methyl-2-pentenyl group, a 1-heptenyl group, a 2-heptenyl group, a 3-heptenyl group, a 4-heptenyl group, a 5-heptenyl group, a 6-heptenyl group, a 1-octenyl group, and a 2-octenyl group; and alkynyl groups having 6 to 20 carbon atoms such as a 1-hexynyl group, a 2-hexynyl group, a 3-hexynyl group, a 4-hexynyl group, a 5-hexynyl group, a 2-methyl-4-heptynyl group, a 1-heptynyl group, a 2-heptynyl group, a 3-heptynyl group, a 4-heptynyl group, a 5-heptynyl group, a 6-heptynyl group, a 1-octynyl group, a 2-octynyl group, a 3-octynyl group, a 4-octynyl group, a 5-octynyl group, a 6-octynyl group, and a 7-octynyl group.

Examples of the monovalent alicyclic hydrocarbon group having 3 to 20 carbon atoms include monovalent monocyclic or polycyclic saturated hydrocarbon groups having 6 to 20 carbon atoms and monocyclic or polycyclic unsaturated hydrocarbon groups in addition to the groups recited as examples of the monovalent alicyclic hydrocarbon group having 3 to 5 carbon atoms in R¹. As the monocyclic saturated hydrocarbon groups, a cyclohexyl group, a cycloheptyl group, and a cyclooctyl group are preferable. As the polycyclic saturated hydrocarbon groups, bridged alicyclic hydrocarbon groups such as a norbornyl group, an adamantyl group, a tricyclodecyl group, and a tetracyclododecyl group are preferable. Examples of the monocyclic unsaturated hydrocarbon group include monocyclic cycloalkenyl groups such as a cyclohexenyl group and a cycloheptenyl group. Examples of the polycyclic unsaturated hydrocarbon group include polycyclic cycloalkenyl groups such as a norbornenyl group, a tricyclodecenyl group, and a tetracyclododecanyl group. The bridged alicyclic hydrocarbon group refers to a polycyclic alicyclic hydrocarbon group in which two carbon atoms that constitute an alicyclic ring and are not adjacent to each other are bonded by a linking group containing one or more carbon atoms.

Examples of the monovalent aromatic hydrocarbon group having 6 to 20 carbon atoms include: aryl groups such as a phenyl group, a tolyl group, a xylyl group, a naphthyl group, and an anthryl group; and aralkyl groups such as a benzyl group, a phenethyl group, and a naphthylmethyl group.

Examples of the monovalent fluorinated hydrocarbon groups represented by R² and R³ include a monovalent fluorinated chain hydrocarbon group having 1 to 20 carbon atoms and a monovalent fluorinated alicyclic hydrocarbon group having 3 to 20 carbon atoms.

Examples of the monovalent fluorinated chain hydrocarbon group having 1 to 20 carbon atoms include:
fluorinated alkyl groups such as a trifluoromethyl group, a 2,2,2-trifluoroethyl group, a pentafluoroethyl group, a 2,2,3,3,3-pentafluoropropyl group, a 1,1,1,3,3,3-hexafluoropropyl group, a heptafluoro-n-propyl group, a heptafluoro-i-propyl group, a nonafluoro-n-butyl group, a nonafluoro-i-butyl group, a nonafluoro-t-butyl group, a 2,2,3,3,4,4,5,5-octafluoro-n-pentyl group, a tridecafluoro-n-hexyl group, and a 5,5,5-trifluoro-1,1-diethylpentyl group;
fluorinated alkenyl groups such as a trifluoroethenyl group and a pentafluoropropenyl group; and
fluorinated alkynyl groups such as a fluoroethynyl group and a trifluoropropynyl group.

Examples of the monovalent fluorinated alicyclic hydrocarbon group having 3 to 20 carbon atoms include:
fluorinated cycloalkyl groups such as a fluorocyclopentyl group, a difluorocyclopentyl group, a nonafluorocyclopentyl group, a fluorocyclohexyl group, a difluorocyclohexyl group, an undecafluorocyclohexylmethyl group, a fluoronorbornyl group, a fluoroadamantyl group, a fluorobornyl group, a fluoroisobornyl group, and a fluorotricyclodecyl group; and fluorinated cycloalkenyl groups such as a fluorocyclopentenyl group and a nonafluorocyclohexenyl group.

As the fluorinated hydrocarbon group, a monovalent fluorinated chain hydrocarbon group having 1 to 8 carbon atoms is preferable, and a monovalent fluorinated linear hydrocarbon group having 1 to 5 carbon atoms is more preferable.

m is preferably an integer of 1 to 6, more preferably an integer of 1 to 5, still more preferably an integer of 1 to 4, and particularly preferably an integer of 1 to 3.

An example of the monovalent radiation-sensitive onium cation represented by Z⁺ is a radioactive ray-degradable onium cation containing an element such as S, I, O, N, P, Cl, Br, F, As, Se, Sn, Sb, Te, or Bi. Examples of such a radioactive ray-degradable onium cation include a sulfonium cation, a tetrahydrothiophenium cation, a iodonium cation, a phosphonium cation, a diazonium cation, and a pyridinium cation. Among them, a sulfonium cation or a iodonium cation is preferred. The sulfonium cation or the iodonium cation is preferably represented by any of the formulas (X-1) to (X-6).

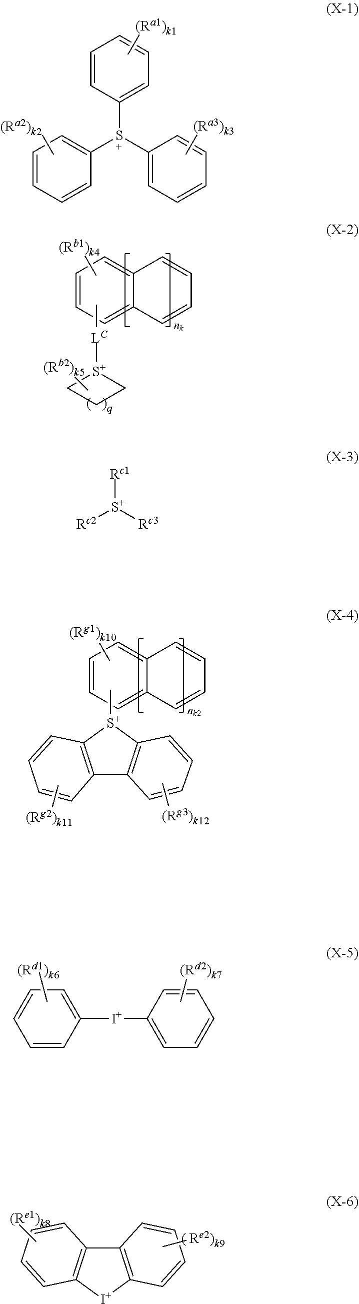

In the formula (X-1), R^{a1}, R^{a2} and R^{a3} are each independently a substituted or unsubstituted, straight or branched chain alkyl group, alkoxy group or alkoxycarbonyloxy group having a carbon number of 1 to 12; a substituted or unsubstituted, monocyclic or polycyclic cycloalkyl group having a carbon number of 3 to 12; a substituted or unsubstituted aromatic hydrocarbon group having a carbon number of 6 to 12; a hydroxy group, a halogen atom, —OSO₂—R^{P}, —SO₂—R^{Q} or —S—R^{T}; or a ring structure obtained by combining two or more of these groups. The ring structure may contain heteroatoms such as O and S between the carbon-carbon bonds forming the skeleton. R^{P}, R^{Q} and R^{T} are each independently a substituted or unsubstituted, straight or branched chain alkyl group having a carbon number of 1 to 12; a substituted or unsubstituted alicyclic hydrocarbon group having a carbon number of 5 to 25; and a substituted or unsubstituted aromatic hydrocarbon group having a carbon number of 6 to 12. k1, k2 and k3 are each independently an integer of 0 to 5. When there are a plurality of R^{a1} to R^{a3} and a plurality of R^{P}, R^{Q} and R^{T}, a plurality of R^{a1} to R^{a3} and a plurality of R^{P}, R^{Q} and R^{T} may be each identical or different.

In the formula (X-2), R^{b1} is a substituted or unsubstituted, straight chain or branched alkyl group or alkoxy group having a carbon number of 1 to 20; a substituted or unsubstituted acyl group having a carbon number of 2 to 8; or a substituted or unsubstituted aromatic hydrocarbon group having a carbon number of 6 to 8; or a hydroxy group. nₖ is 0 or 1. When nₖ is 0, k4 is an integer of 0 to 4. When nₖ is 1, k4 is an integer of 0 to 7. When there are a plurality of R^{b1}, a plurality of R^{b1} may be each identical or different. A plurality of R^{b1} may represent a ring structure obtained by combining them. R^{b2} is a substituted or unsubstituted, straight chain or branched alkyl group having a carbon number of 1 to 7; or a substituted or unsubstituted aromatic hydrocarbon group having a carbon number of 6 or 7. L^{C} is a single bond or divalent linking group. k5 is an integer of 0 to 4. When there are a plurality of R^{b2}, a plurality of R^{b2} may be each identical or different. A plurality of R^{b2} may represent a ring structure obtained by combining them. q is an integer of 0 to 3. In the formula, the ring structure containing S+ may contain a heteroatom such as 0 or S between the carbon-carbon bonds forming the skeleton.

In the formula (X-3), R^{c1}, R^{c2} and R^{c3} are each independently a substituted or unsubstituted, straight or branched chain alkyl group having a carbon number of 1 to 12.

In the formula (X-4), R^{g1} is a substituted or unsubstituted linear or branched alkyl or alkoxy group having 1 to 20 carbon atoms, a substituted or unsubstituted acyl group having 2 to 8 carbon atoms, a substituted or unsubstituted aromatic hydrocarbon group having 6 to 8 carbon atoms, or a hydroxy group. nₖ₂ is 0 or 1. When nₖ₂ is 0, k10 is an integer of 0 to 4, and when nₖ₂ is 1, k10 is an integer of 0 to 7. When there are two or more R^{g1}s, the two or more R^{g1}s are the same or different from each other, and may represent a cyclic structure formed by combining them together. R^{g2} and R^{g3} are each independently a substituted or unsubstituted linear or branched alkyl, alkoxy, or alkoxycarbonyloxy group having 1 to 12 carbon atoms, a substituted or unsubstituted monocyclic or polycyclic cycloalkyl group having 3 to 12 carbon atoms, a substituted or unsubstituted aromatic hydrocarbon group having 6 to 12 carbon atoms, a hydroxyl group, a halogen atom, or a ring structure formed by combining two or more of these groups together. K11 and k12 are each independently an integer of 0 to 4. When there are two or more R^{g2}s and two or more R^{g3}s, the two or more R^{g2}s may be the same or different from each other, and the two or more Ross may be the same or different from each other.

In the formula (X-5), R^{d1} and R^{d2} are each independently a substituted or unsubstituted, straight or branched chain alkyl group, alkoxy group or alkoxycarbonyl group having a carbon number of 1 to 12; a substituted or unsubstituted aromatic hydrocarbon group having a carbon number of 6 to 12; a halogen atom; a halogenated alkyl group having a carbon number of 1 to 4; a nitro group; or a ring structure obtained by combining two or more of these groups. k6 and k7 are each independently an integer of 0 to 5. When there are a plurality of R^{d1} and a plurality of R^{d2}, a plurality of R^{d1} and a plurality of R^{d2} may be each identical or different.

In the formula (X-6), R^{e1} and R^{e2} are each independently a halogen atom; a substituted or unsubstituted straight or branched chain alkyl group having a carbon number of 1 to 12; or a substituted or unsubstituted aromatic hydrocarbon group having a carbon number of 6 to 12. k8 and k9 are each independently an integer of 0 to 4.

The first onium salt compound is preferably represented by the formula (1-1).

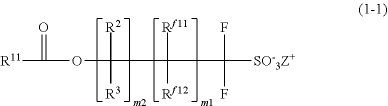

In the formula (1-1),
R¹¹ is a substituted or unsubstituted monovalent saturated hydrocarbon group having 1 to 5 carbon atoms or a group containing a divalent hetero atom-containing group between two adjacent carbon atoms of the saturated hydrocarbon group,
R¹² and R¹³ are each independently a hydrogen atom or a monovalent hydrocarbon group, when there are a plurality of R¹²s and R¹³s, the plurality of R¹²s and R¹³s are each the same or different from each other,
one of R^{f11} and R^{f12} is a fluorine atom, and the other is a hydrogen atom, a fluorine atom, or a monovalent fluorinated hydrocarbon group,
m1 is 0 or 1,
m2 is an integer of 1 to 6, and
Z⁺ has the same meaning as in the formula (1).

As the monovalent saturated hydrocarbon group having 1 to 5 carbon atoms represented by R¹¹, the monovalent saturated hydrocarbon groups having 1 to 5 carbon atoms in R¹ in the formula (1) can be suitably employed. As a group that substitutes for a hydrogen atom contained in R¹¹, the substituents in R¹ in the formula (1) can be suitably employed. As the group containing a divalent hetero atom-containing group between two adjacent carbon atoms of the saturated hydrocarbon group represented by R¹¹, a group containing the divalent hetero atom-containing group between two adjacent carbon atoms of the saturated hydrocarbon group in R¹ of the formula (1) can be suitably employed.

As the monovalent hydrocarbon groups represented by R¹² and R¹³, the monovalent hydrocarbon groups represented by R² and R³ of the formula (1) can be suitably employed.

As the monovalent fluorinated hydrocarbon groups represented by R^{f11} and R^{f12}, the monovalent fluorinated hydrocarbon groups represented by R² and R³ of the formula (1) can be suitably employed.

m2 is preferably an integer of 1 to 5, more preferably an integer of 1 to 4, still more preferably an integer of 1 to 3, and particularly preferably 1 or 2.

Specific examples of the anion moiety of the first onium salt compound include, but are not limited to, the structures represented by the formulas (1-1-1) to (1-1-30).

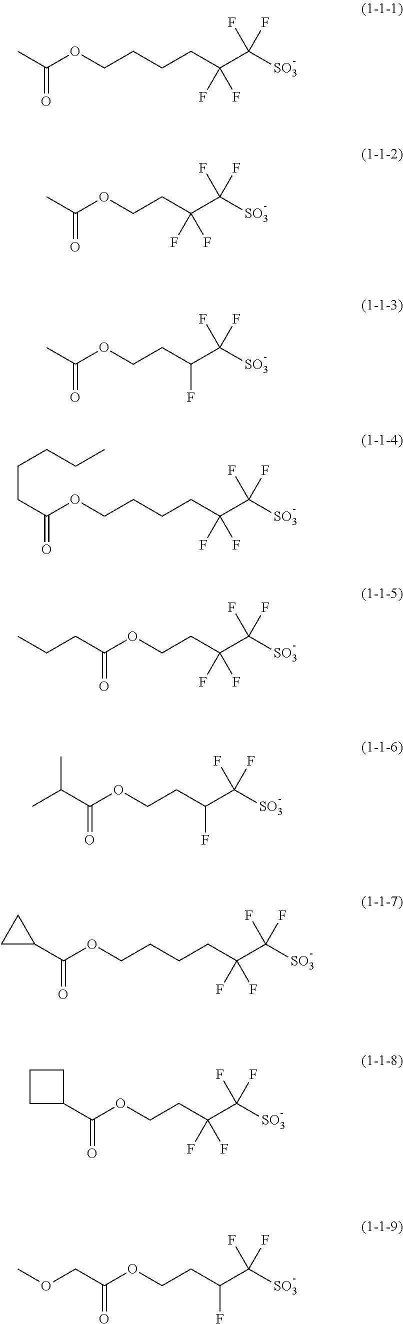

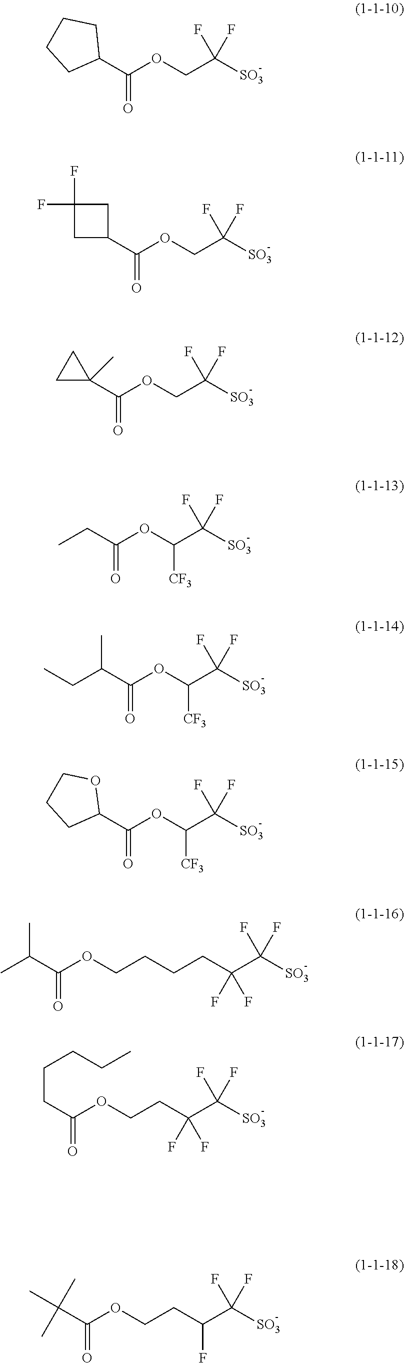

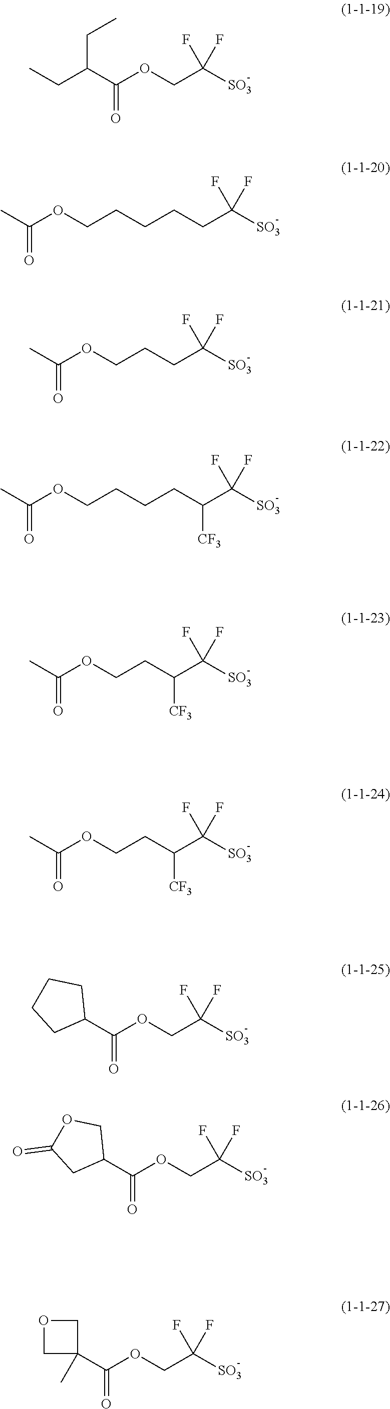

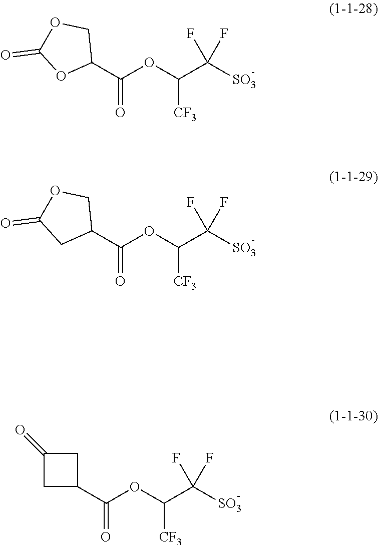

Specific examples of the radiation-sensitive onium cation include, but not limited thereto, the structures represented by the formulas (1-2-1) to (1-2-46).

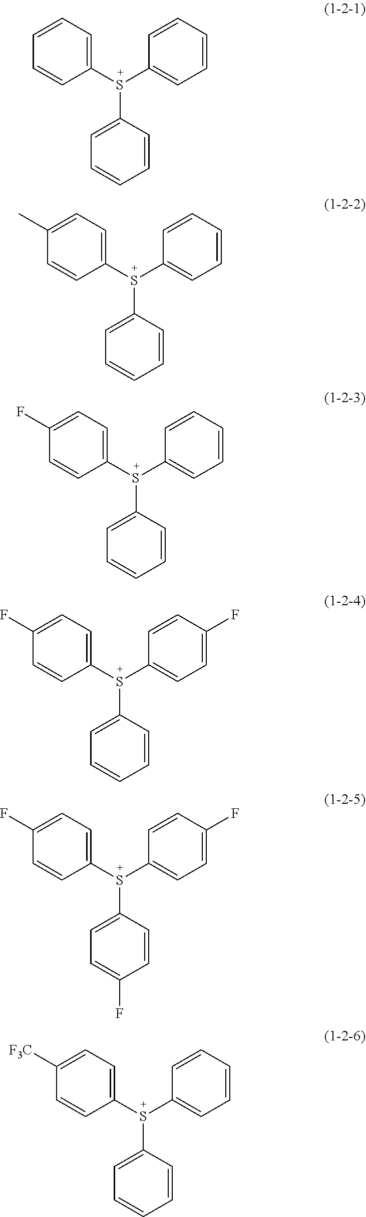

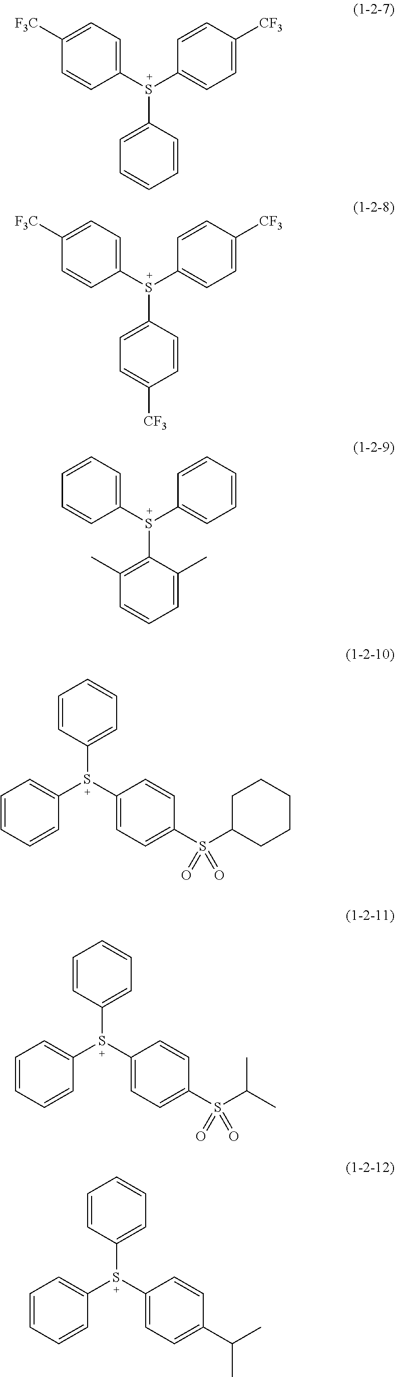

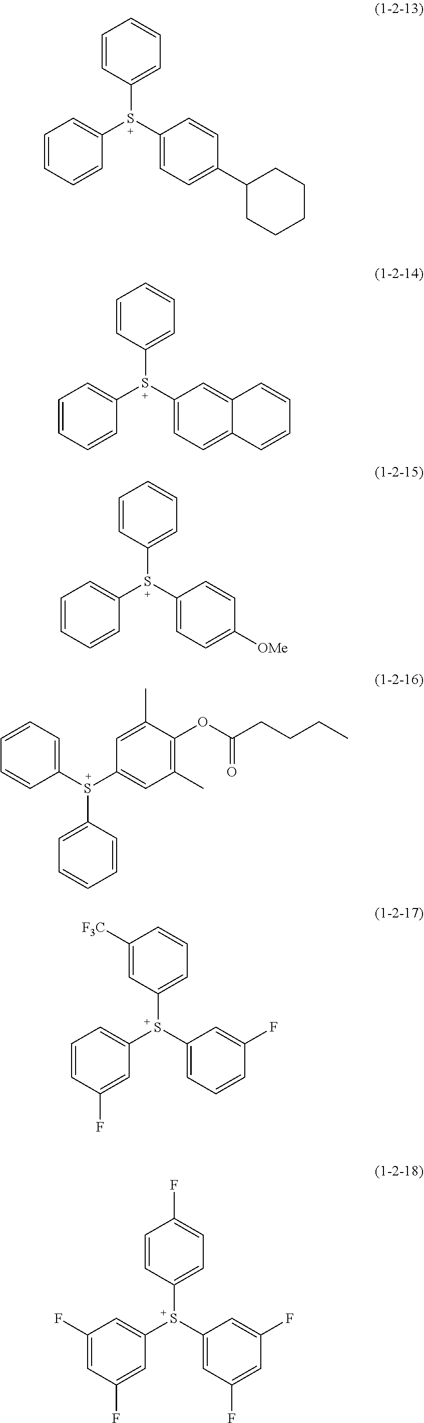

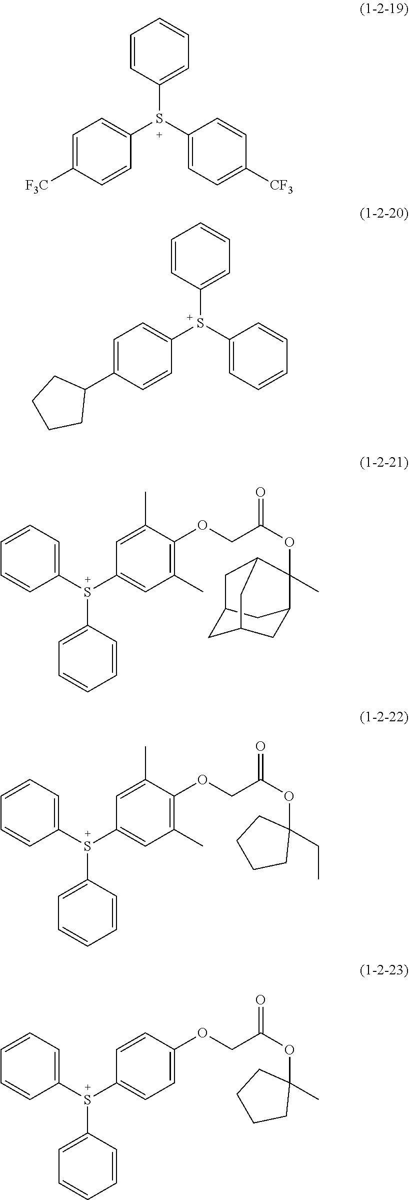

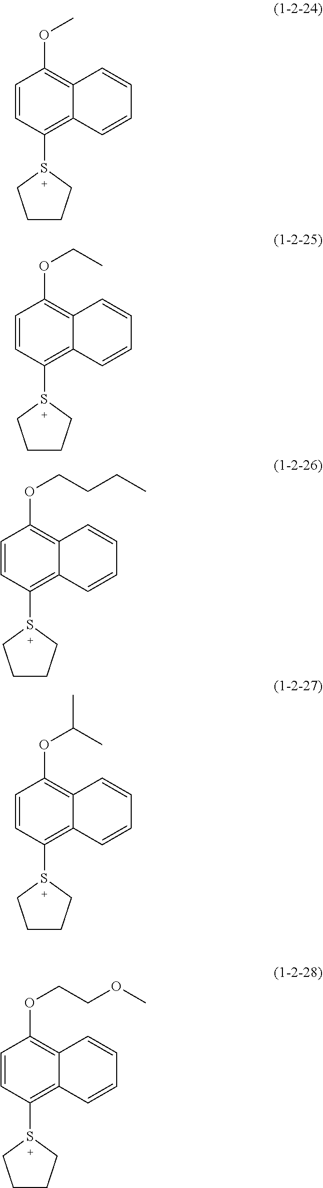

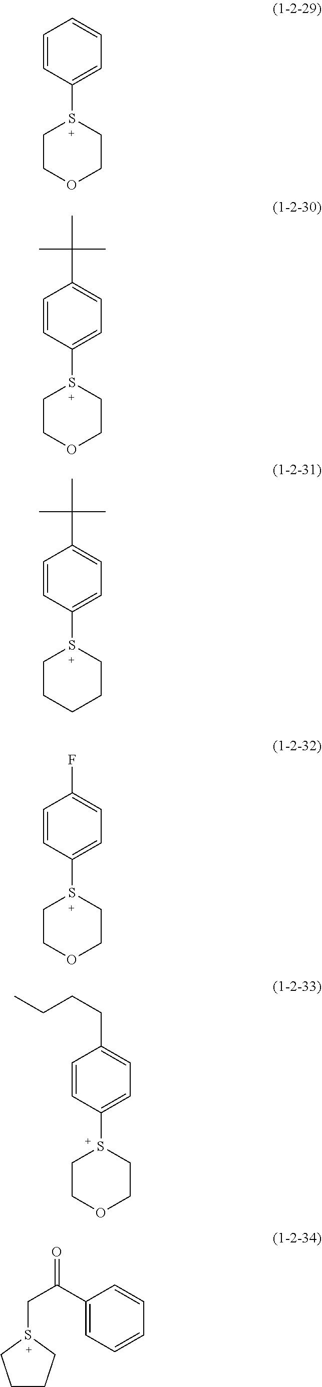

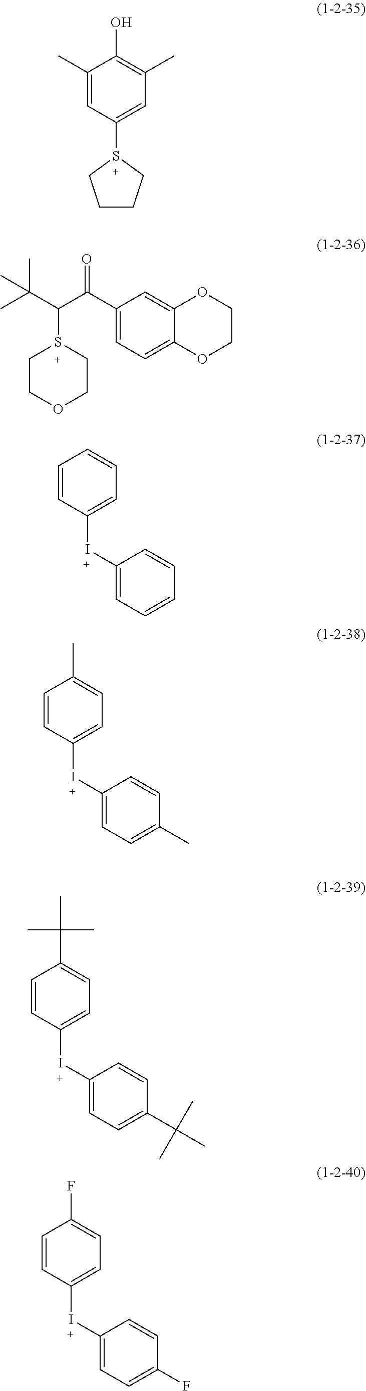

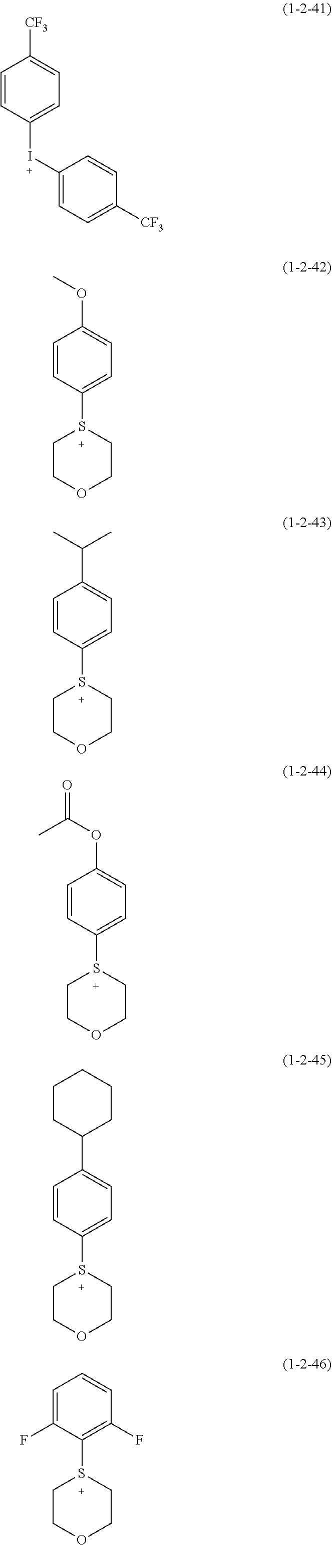

The first onium salt compound is obtained by appropriately combining the aforementioned anion moieties and the aforementioned radiation-sensitive onium cations. Specific examples of the first onium salt compound include, but not limited thereto, the structures represented by the formulas (1-A1) to (1-A30).

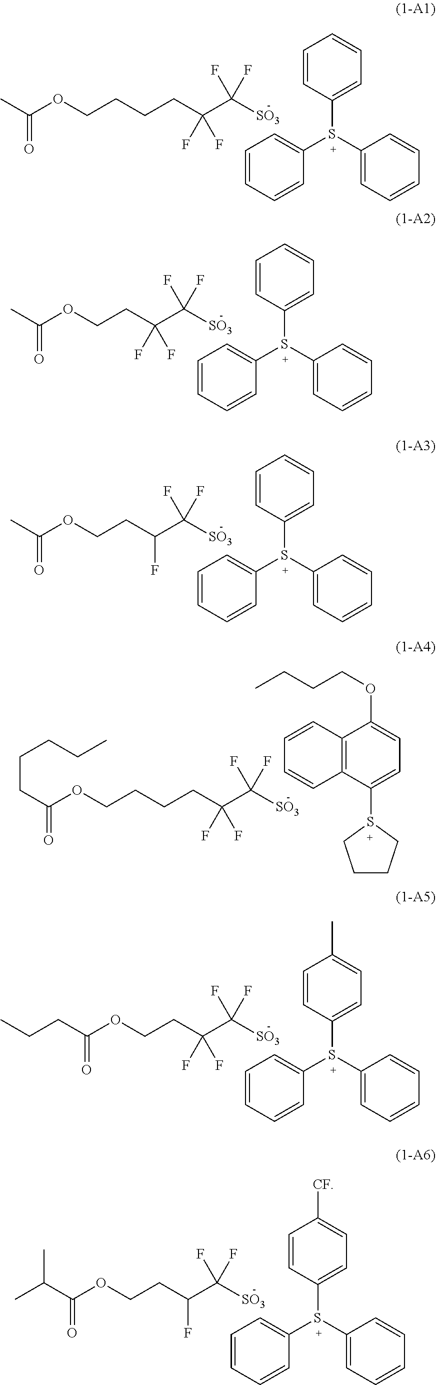

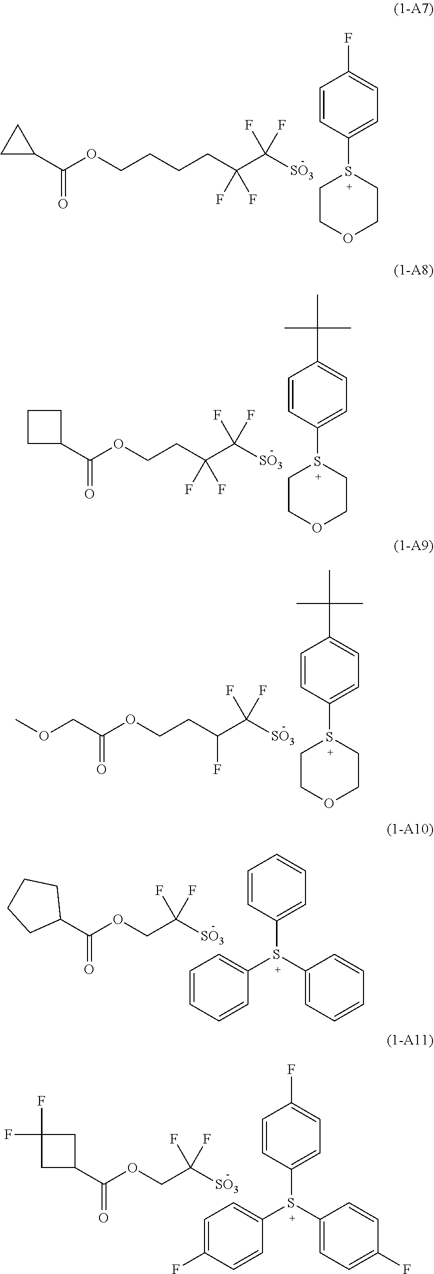

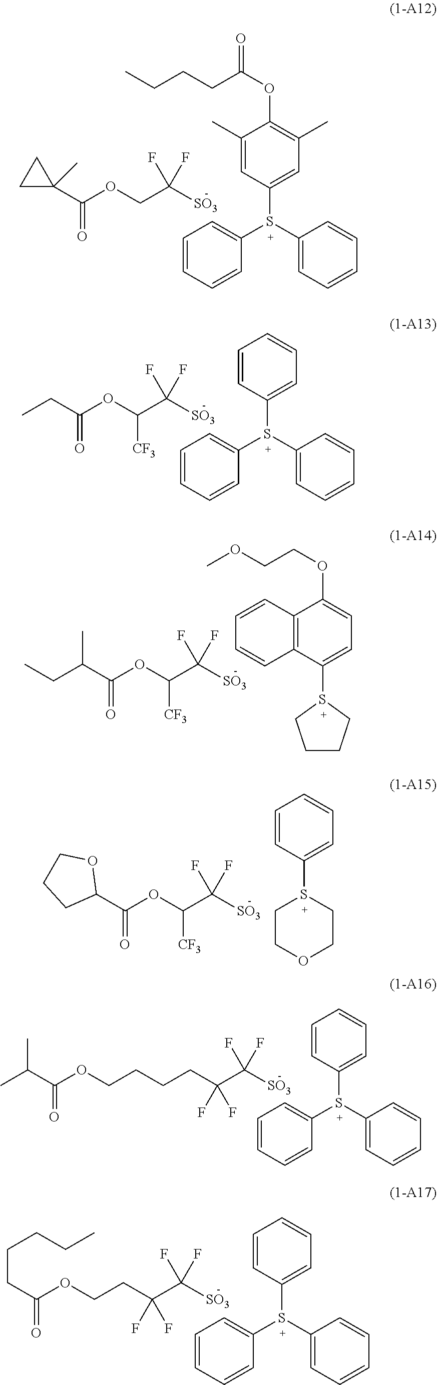

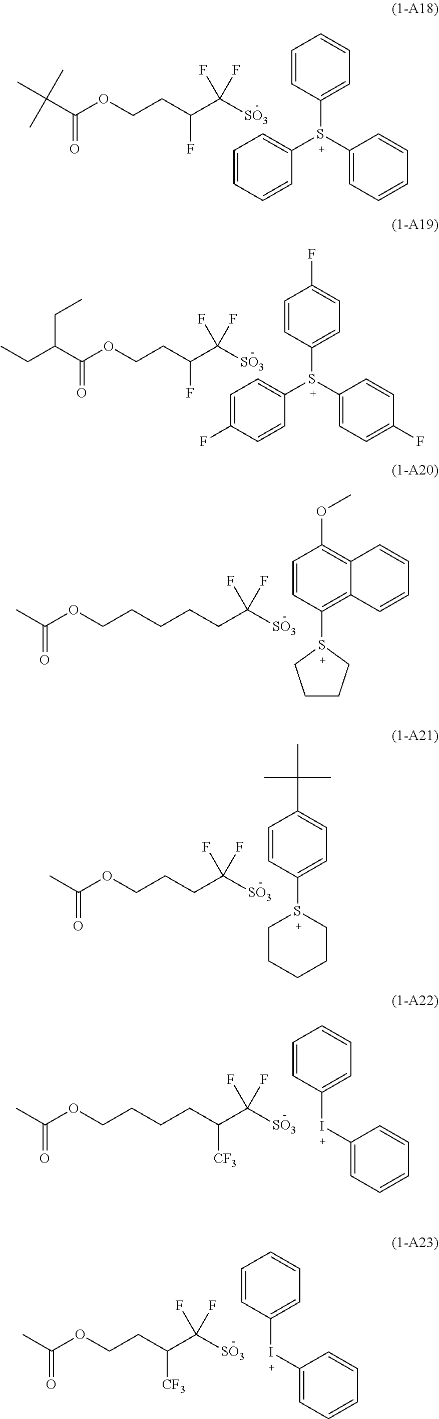

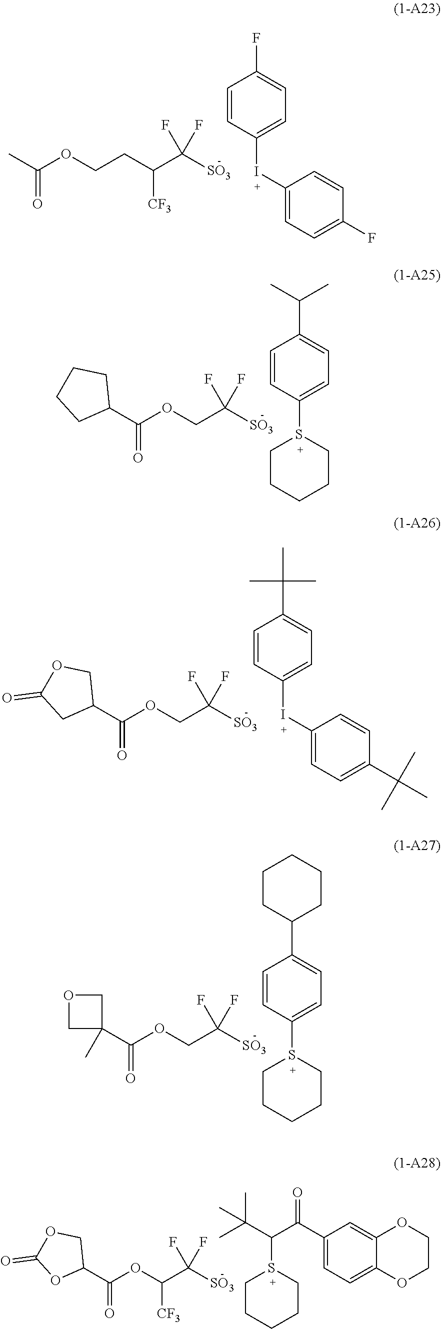

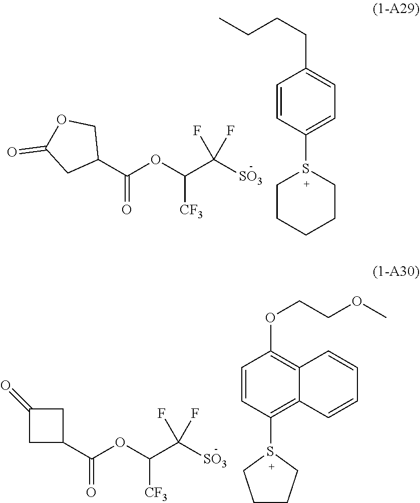

The lower limit of the content of the first onium salt compound (in the case of containing a plurality of types of the first onium salt compound, the total content thereof) is preferably 1 part by mass, more preferably 2 parts by mass, still more preferably 3 parts by mass, and particularly preferably 5 parts by mass based on 100 parts by mass of the resin to be described later. The upper limit of the content is preferably 50 parts by mass, more preferably 40 parts by mass, still more preferably 30 parts by mass, and particularly preferably 20 parts by mass. The content of the first onium salt compound is appropriately chosen according to the type of the resin to be used, the exposure conditions, the required sensitivity, etc. This makes it possible to exhibit superior sensitivity, LWR performance, DOF performance, pattern rectangularity, CDU performance, and pattern circularity when forming a resist pattern.

### (Method for Synthesizing First Onium Salt Compound)

The method for synthesizing the first onium salt compound will be described by taking as an example the case where R² and R³ are both hydrogen atoms and m is 1 in the formula (1). A representative scheme is shown below.

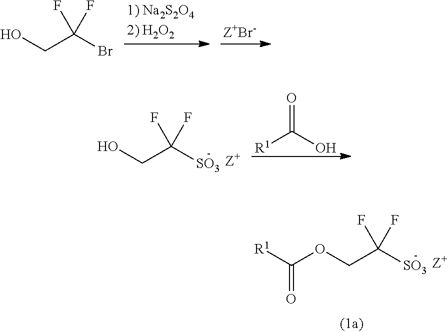

In the scheme, R¹ and Z⁺ have the same meanings as in the formula (1).

The bromo moiety of 2-bromo-2,2-difluoroethanol is converted into a sulfonate by a dithionite and an oxidizing agent, and then reacted with an onium cation halide (bromide in the scheme) corresponding to the onium cation moiety to allow salt exchange to proceed, thereby affording an onium salt. Finally, the intended first onium salt compound (la) can be synthesized by reacting the hydroxy group of the onium salt with a carboxylic acid having the structure of R¹. Similarly, first onium salt compounds having other structures can be synthesized by appropriately selecting starting materials or precursors corresponding to the anion moiety and the onium cation moiety.

### (Second Onium Salt Compound)

The second onium salt compound is represented by the formula (2), and functions as a radiation-sensitive acid generator that generates an acid in response to irradiation with radiation.

Examples of the monovalent organic group having 1 to 40 represented by R⁴ include a monovalent hydrocarbon group having 1 to 20 carbon atoms, a group containing a divalent hetero atom-containing group between two adjacent carbon atoms of the foregoing hydrocarbon group or at an end of the foregoing hydrocarbon group, and a group obtained by substituting some or all of the hydrogen atoms of the foregoing hydrocarbon group with a monovalent hetero atom-containing group, or a group obtained by combining them. The “organic group” refers to a group having at least one carbon atom.

As the monovalent hydrocarbon groups having 1 to 20 carbon atoms, the monovalent hydrocarbon groups represented by R² and R³ of the formula (1) can be suitably employed.

Examples of hetero atoms that constitute divalent or monovalent hetero atom-containing groups include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent hetero atom-containing group include —CO—, —CS—, —NR′—, —O—, —S—, —SO₂— and divalent groups obtained by combining them. R′ represents a hydrogen atom or a hydrocarbon group having 1 to 10 carbon atoms.

Examples of the monovalent hetero atom-containing group include a hydroxy group, a carboxy group, a sulfanyl group, a cyano group, a nitro group, and halogen atoms.

R⁴ is preferably a monovalent organic group having 3 to 40 carbon atoms and containing a cyclic structure. The organic group is not particularly limited, and may be either a group containing only a cyclic structure or a group containing a cyclic structure and a chain structure in combination. The cyclic structure may be any of a monocyclic structure, a polycyclic structure, or a combination thereof. In addition, the cyclic structure may be any of an alicyclic structure, an aromatic ring structure, a heterocyclic structure, or a combination thereof. In the case of combination, the cyclic structure may be a structure in which ring structures are linked by a chain structure, or two or more ring structures may form a fused ring structure. These structures are preferably contained as a minimum basic backbone of the cyclic structure. The number of the cyclic structures as the basic backbone in the organic group may be 1, or may be 2 or more. The divalent hetero atom-containing group may be present between carbon atoms forming the backbone of a cyclic structure or a chain structure or at a carbon chain terminal, and a hydrogen atom on a carbon atom of a cyclic structure or a chain structure may be substituted with another substituent.

As the alicyclic structure, structures corresponding to the monovalent alicyclic hydrocarbon groups having 3 to 20 carbon atoms in R² and R³ in the formula (1) can be suitably employed.

As the aromatic ring structure, structures corresponding to the monovalent aromatic hydrocarbon groups having 6 to 20 carbon atoms in R² and R³ in the formula (1) can be suitably employed.

As the chain structure, structures corresponding to the monovalent chain hydrocarbon groups having 1 to 20 carbon atoms in R² and R³ in the formula (1) can be suitably employed.

Examples of the heterocyclic structure include a group obtained by removing one hydrogen atom from an aromatic heterocyclic structure and a group obtained by removing one hydrogen atom from an aliphatic heterocyclic structure. A 5-membered aromatic structure having aromaticity and containing a hetero atom is also included in the heterocyclic structure. Examples of the hetero atom include an oxygen atom, a nitrogen atom, and a sulfur atom.

Examples of the aromatic heterocyclic structure include:
oxygen atom-containing aromatic heterocyclic structures such as furan and benzofuran;
nitrogen atom-containing aromatic heterocyclic structures such as pyrrole, imidazole, pyridine, pyrimidine, pyrazine, indole, quinoline, isoquinoline, acridine, phenazine, and carbazole;
sulfur atom-containing aromatic heterocyclic structures such as thiophene and benzothiophene; and
aromatic heterocyclic structures containing a plurality of hetero atoms such as thiazole, benzothiazole, thiazine, and oxazine.

Examples of the aliphatic heterocyclic structure include:
oxygen atom-containing aliphatic heterocyclic structures such as oxirane, tetrahydrofuran, tetrahydropyran, dioxolane, and dioxane;
nitrogen atom-containing aliphatic heterocyclic structures such as aziridine, pyrrolidine, piperidine, and piperazine;
sulfur atom-containing aliphatic heterocyclic structures such as thietane, thiolane, and thiane; and
aliphatic heterocyclic structures containing a plurality of heteroatoms, such as morpholine, 1,2-oxathiolane, and 1,3-oxathiolane.

The heterocyclic structures includes a lactone structure, a cyclic carbonate structure, a sultone structure, a cyclic acetal, and a combination thereof.

As the other substituent that substitutes for a hydrogen atom on a carbon atom of the cyclic structure or the chain structure, a substituent that substitutes a hydrogen atom of R¹ can be suitably employed.

As the monovalent fluorinated hydrocarbon groups represented by R^{f21} and R^{f22}, the monovalent fluorinated hydrocarbon groups represented by R² and R³ of the formula (1) can be suitably employed.

As the monovalent organic group having an aromatic ring having 5 to 40 ring atoms represented by Ar, a group containing an aromatic ring having 5 to 40 ring atoms as a cyclic structure in a case where R⁴ is a monovalent organic group having 3 to 40 carbon atoms and containing a cyclic structure can be suitably employed. Examples of the aromatic ring having 5 to 40 ring atoms include aromatic hydrocarbon rings such as a benzene ring, a naphthalene ring, an anthracene ring, a phenalene ring, a phenanthrene ring, a pyrene ring, a fluorene ring, a perylene ring, and a coronene ring; aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, and a triazine group, and combinations thereof. A fused structure ring of an aromatic ring having 5 to 40 ring atoms with at least one of the alicyclic structure and the heterocyclic structure in R⁴ is also suitable.

As the monovalent organic groups having 1 to 20 carbon atoms represented by R⁵, R⁶, R⁷, and R⁸, the groups having 1 to 20 carbon atoms among the monovalent organic groups having 1 to 40 carbon atoms represented by R⁴ can be suitably employed.

n₁ and n₂ each independently preferably represent an integer of 1 to 4, more preferably an integer of 1 to 3, and still more preferably 1 or 2.

As the divalent hetero atom-containing substituent represented by X, the divalent hetero atom-containing groups in R⁴ can be suitably employed.

The second onium salt compound is preferably represented by the formula (2-1).

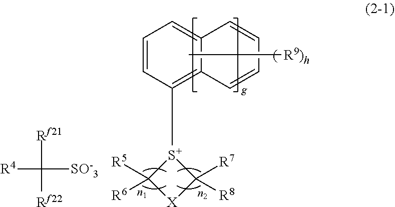

In the formula (2-1), R⁴, R^{f21}, R^{f22}, R⁵, R⁶, R⁷, and R⁸ have the same definitions as those of the formula (2),
X is a single bond or an oxygen atom,
L is a single bond or a divalent linking group,
R⁹ is a halogen atom, a hydroxy group, a carboxy group, a cyano group, a nitro group, or an alkyl group, an alkoxy group, an alkoxyalkoxy group, an alkoxycarbonyl group, an alkoxycarbonyloxy group, an acyl group, an acyloxy group, or a group in which a hydrogen atom of these groups has been substituted with a halogen atom, when there are a plurality of R⁹s, the plurality of R⁷s are the same or different from each other,
n₁ and n₂ are each independently an integer of 1 to 3,
g is 0 or 1, and
h is an integer of 0 to 4.

Examples of the divalent linking group represented by L include a divalent linear or branched hydrocarbon group having 1 to 10 carbon atoms; a divalent alicyclic hydrocarbon group having 4 to 12 carbon atoms; and a group composed of one or more of the hydrocarbon group thereof and at least one group of —CO—, —O—, —NH— and —S—.

h is preferably an integer of 0 to 3, and more preferably an integer of 0 to 2.

Specific examples of the anion moiety of the second onium salt compound include, but are not limited to, the structures represented by the formulas (2-1-1) to (2-1-24).

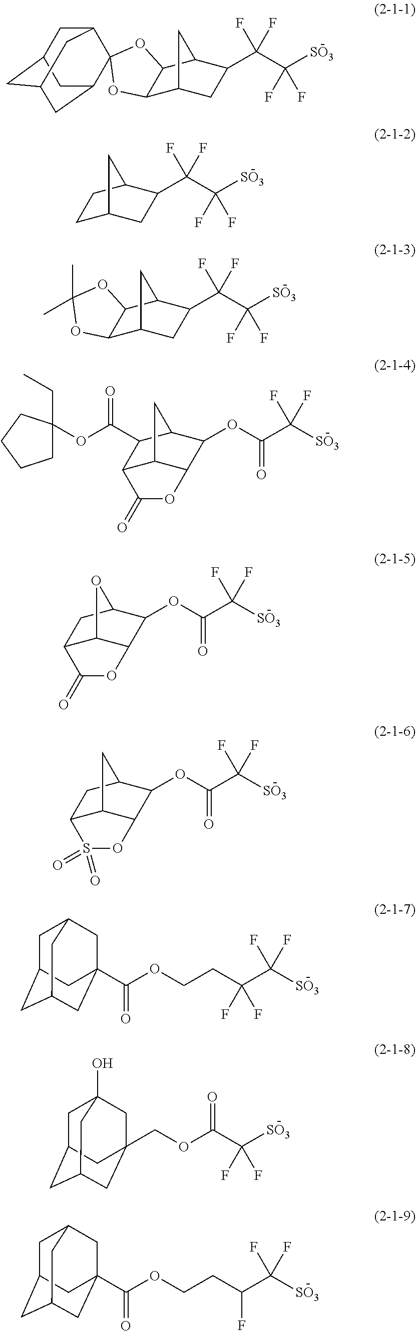

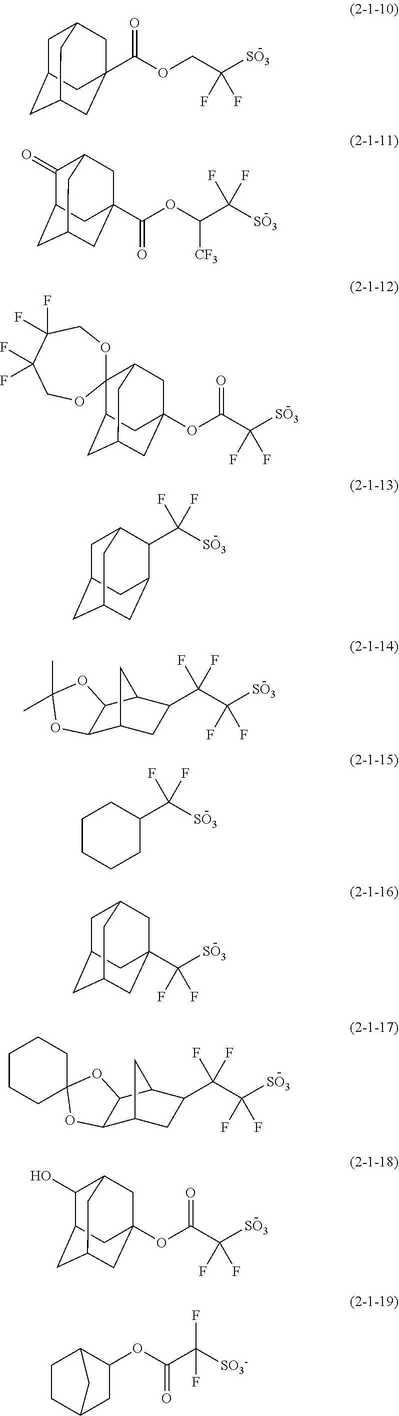

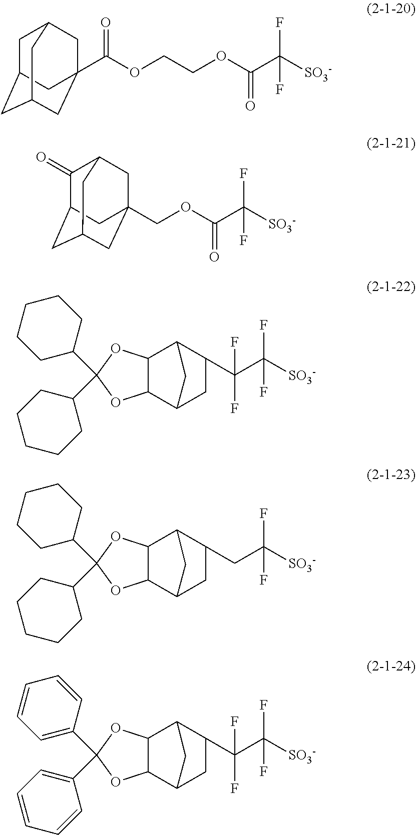

Specific examples of the radiation-sensitive onium cation of the second onium salt compound include, but not limited thereto, the structures represented by the formulas (2-2-1) to (2-2-29).

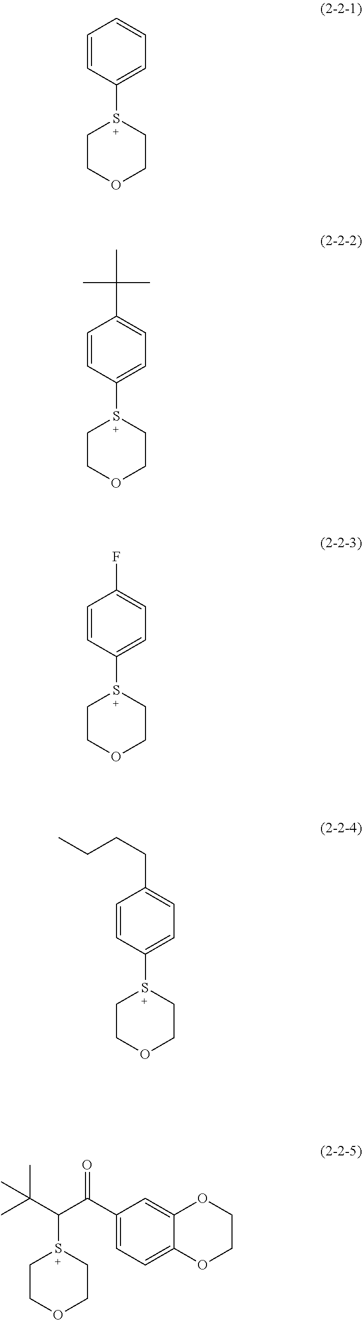

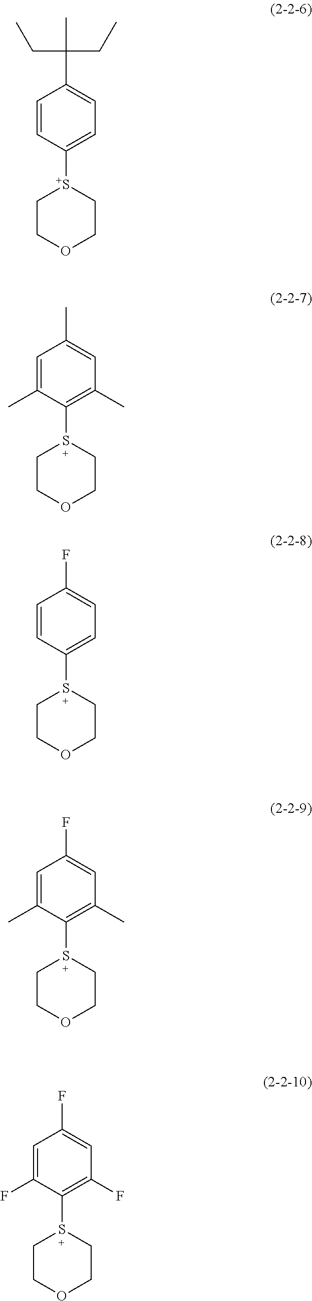

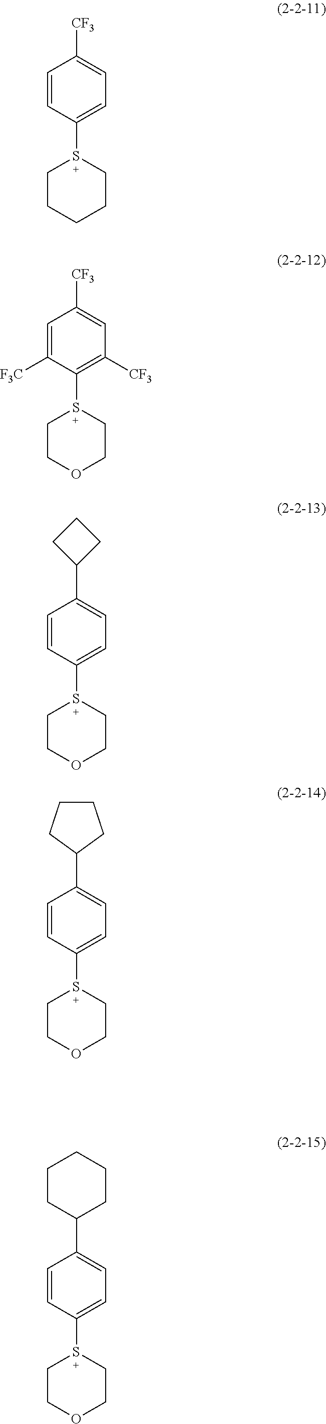

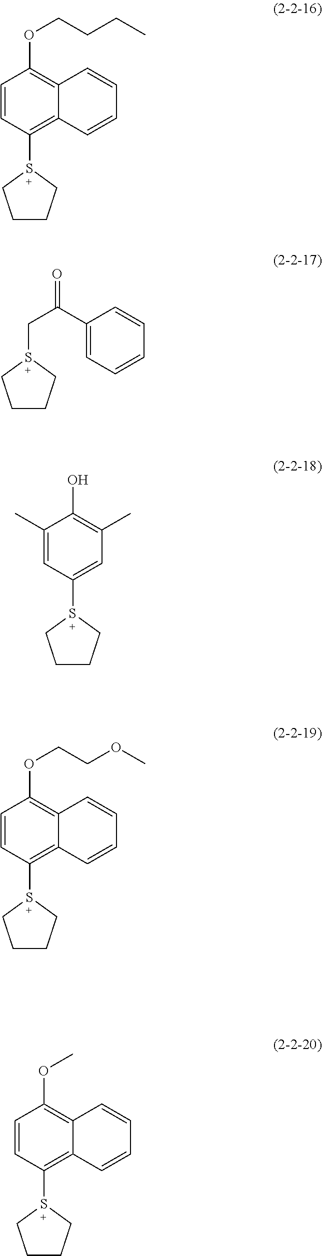

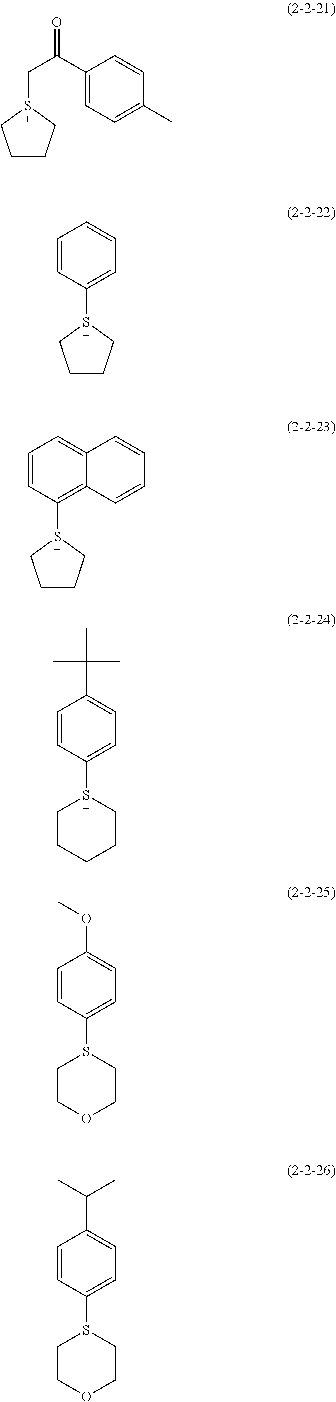

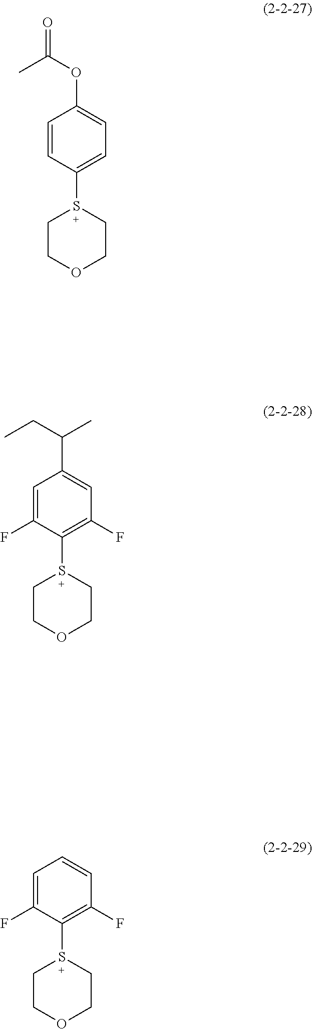

Examples of the second onium salt compound include structures obtained by arbitrarily combining the aforementioned anion moieties and the aforementioned radiation-sensitive onium cations. Specific examples of the second onium salt compound include, but not limited thereto, the onium salt compounds represented by the formulas (2-a) to (2-x).

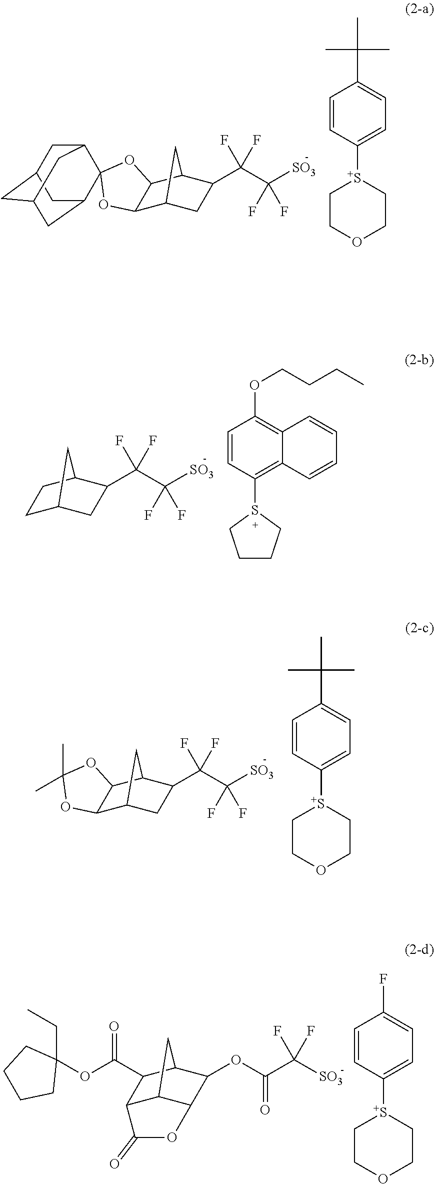

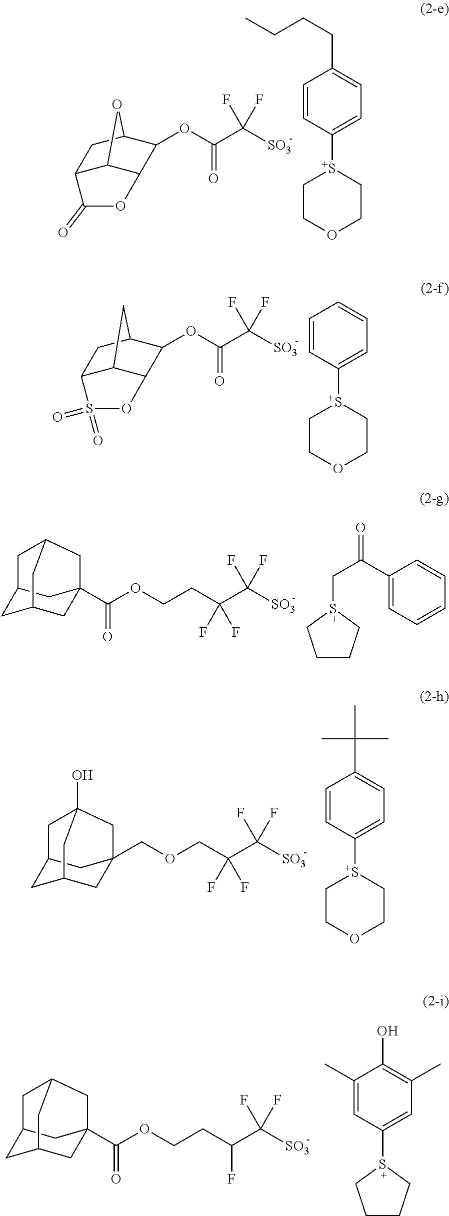

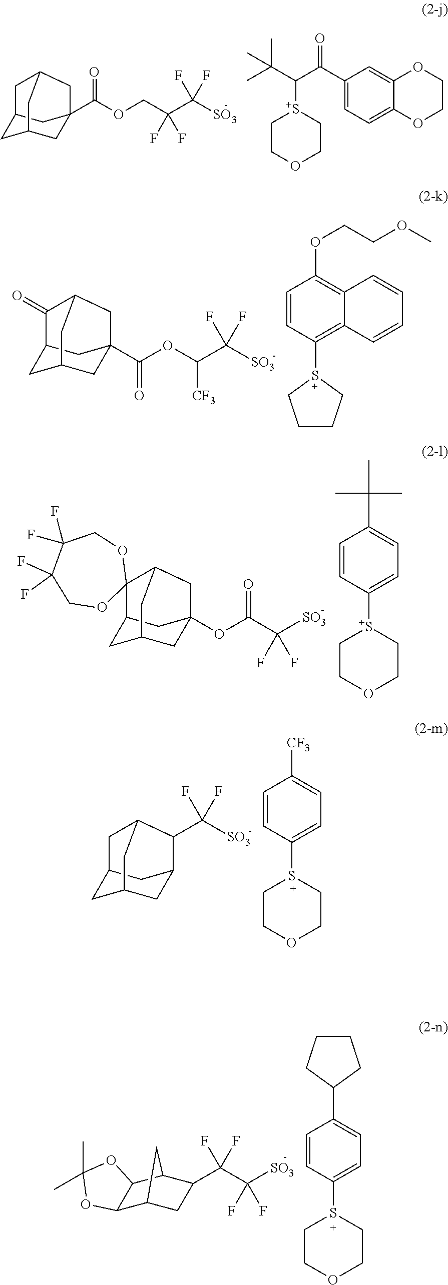

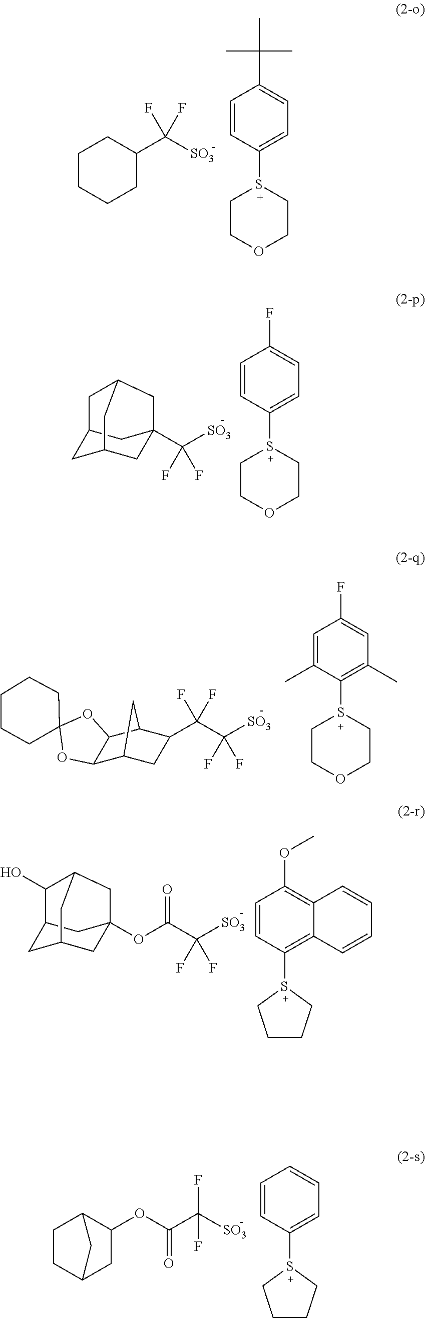

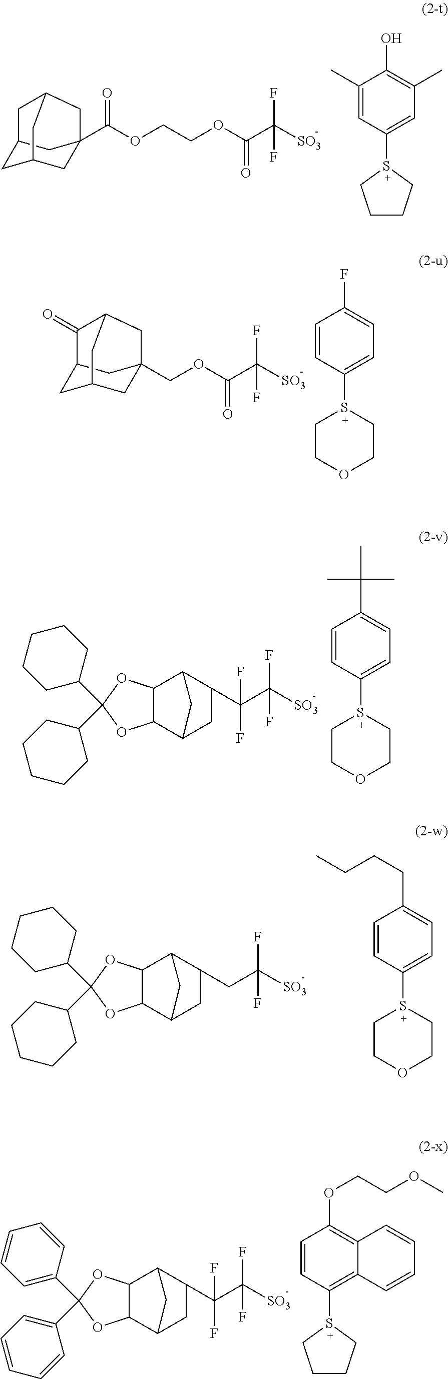

The lower limit of the content of the second onium salt compound (in the case of containing a plurality of types of the second onium salt compound, the total content thereof) is preferably 1 part by mass, more preferably 2 parts by mass, still more preferably 3 parts by mass, and particularly preferably 4 parts by mass based on 100 parts by mass of the resin to be described later. The upper limit of the content is preferably 50 parts by mass, more preferably 40 parts by mass, still more preferably 30 parts by mass, and particularly preferably 20 parts by mass. The content of the second onium salt compound is appropriately chosen according to the type of the resin to be used, the exposure conditions, the required sensitivity, etc. This makes it possible to exhibit superior sensitivity, LWR performance, DOF performance, pattern rectangularity, CDU performance, and pattern circularity when forming a resist pattern.

The lower limit of the ratio a/b on a mass basis of the content a of the first onium salt compound to the content b of the second onium salt compound is preferably 0.01, more preferably 0.1, still more preferably 0.2, and particularly preferably 0.5. The upper limit of the ratio a/b is preferably 20, more preferably 15, still more preferably 10, and particularly preferably 5.

### (Resin)

The resin is an aggregate of polymers having a structural unit (hereinafter, also referred to as “structural unit (I)”) containing an acid-dissociable group (hereinafter, this resin is also referred to as “base resin”). The “acid-dissociable group” refers to a group that substitutes for a hydrogen atom of a carboxy group, a phenolic hydroxyl group, an alcoholic hydroxyl group, a sulfo group, or the like, and is dissociated by the action of an acid. The radiation-sensitive resin composition is excellent in pattern-forming performance because the resin has the structural unit (I).

In addition to the structural unit (I), the base resin preferably has a structural unit (II) containing at least one selected from the group consisting of a lactone structure, a cyclic carbonate structure, and a sultone structure described later, and may have another structural unit other than the structural units (I) and (II). Each of the structural units will be described below.

### [Structural Unit (I)]

The structural unit (I) contains an acid-dissociable group. The structural unit (I) is not particularly limited as long as it contains an acid-dissociable group. Examples of such a structural unit (I) include a structural unit having a tertiary alkyl ester moiety, a structural unit having a structure obtained by substituting the hydrogen atom of a phenolic hydroxyl group with a tertiary alkyl group, and a structural unit having an acetal bond. From the viewpoint of improving the pattern-forming performance of the radiation-sensitive resin composition, a structural unit represented by the formula (3) (hereinafter also referred to as a “structural unit (I-1)”) is preferred.

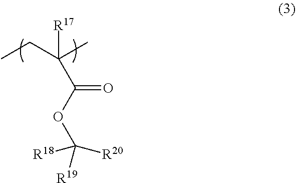

In the formula (3), R¹⁷ is a hydrogen atom, a fluorine atom, a methyl group, or a trifluoromethyl group, R¹⁸ is a monovalent hydrocarbon group having 1 to 20 carbon atoms, R¹⁹ and R²⁰ are each independently a monovalent chain hydrocarbon group having 1 to 10 carbon atoms or a monovalent alicyclic hydrocarbon group having 3 to 20 carbon atoms or represent a divalent alicyclic group having 3 to 20 carbon atoms formed by these groups combined together and a carbon atom to which they are bonded.

From the viewpoint of copolymerizability of a monomer that will give the structural unit (1-1), R¹⁷ is preferably a hydrogen atom or a methyl group, more preferably a methyl group.

Examples of the monovalent hydrocarbon group having 1 to 20 carbon atoms represented by R¹⁸ include a chain hydrocarbon group having 1 to 10 carbon atoms, a monovalent alicyclic hydrocarbon group having 3 to 20 carbon atoms, and a monovalent aromatic hydrocarbon group having 6 to 20 carbon atoms.

Examples of the chain hydrocarbon groups having 1 to 10 carbon atoms represented by R¹⁸ to R²⁰ include linear or branched saturated hydrocarbon groups having 1 to 10 carbon atoms and linear or branched unsaturated hydrocarbon groups having 1 to 10 carbon atoms.

As the alicyclic hydrocarbon groups having 3 to 20 carbon atoms represented by R¹⁸ to R²⁰, the monovalent alicyclic hydrocarbon groups having 3 to 20 carbon atoms in R² and R³ of the formula (1) can be suitably employed.

As the monovalent aromatic hydrocarbon group having 6 to 20 carbon atoms represented by R¹⁸, the monovalent aromatic hydrocarbon groups having 6 to 20 carbon atoms in R² and R³ in the formula (1) can be suitably employed.

R¹⁸ is preferably a linear or branched saturated hydrocarbon group having 1 to 10 carbon atoms or an alicyclic hydrocarbon group having 3 to 20 carbon atoms.

The divalent alicyclic group having 3 to 20 carbon atoms formed by R¹⁹ and R²⁰ combined together and a carbon atom to which R¹⁹ and R²⁰ are bonded is not particularly limited as long as it is a group obtained by removing two hydrogen atoms from the same carbon atom constituting a carbon ring of a monocyclic or polycyclic alicyclic hydrocarbon having the above-described carbon number. The divalent alicyclic group having 3 to 20 carbon atoms may either be a monocyclic hydrocarbon group or a polycyclic hydrocarbon group. The polycyclic hydrocarbon group may either be a bridged alicyclic hydrocarbon group or a condensed alicyclic hydrocarbon group and may either be a saturated hydrocarbon group or an unsaturated hydrocarbon group. It is to be noted that the condensed alicyclic hydrocarbon group refers to a polycyclic alicyclic hydrocarbon group in which two or more alicyclic rings share their sides (bond between two adjacent carbon atoms).

When the monocyclic alicyclic hydrocarbon group is a saturated hydrocarbon group, preferred examples thereof include a cyclopentanediyl group, a cyclohexanediyl group, a cycloheptanediyl group, and a cyclooctanediyl group. When the monocyclic alicyclic hydrocarbon group is an unsaturated hydrocarbon group, preferred examples thereof include a cyclopentanediyl group, a cyclohexanediyl group, a cycloheptenediyl group, a cyclooctenediyl group, and a cyclodecenediyl group. The polycyclic alicyclic hydrocarbon group is preferably a bridged alicyclic saturated hydrocarbon group, and preferred examples thereof include a bicyclo[2.2.1]heptane-2,2-diyl group (norbornane-2,2-diyl group), a bicyclo[2.2.2]octane-2,2-diyl group, and a tricyclo[3.3.1.1^{3,7}]decane-2,2-diyl group (adamantane-2,2-diyl group).

Among them, R¹⁸ is preferably an alkyl group having 1 to 4 carbon atoms, and the alicyclic structure formed by R¹⁹ and R²⁰ combined together and a carbon atom to which they are bonded is preferably a polycyclic or monocyclic cycloalkane structure.

Examples of the structural unit (I-1) include structural units represented by the formulas (3-1) to (3-6) (hereinafter also referred to as “structural units (I-1-1) to (I-1-6)”).

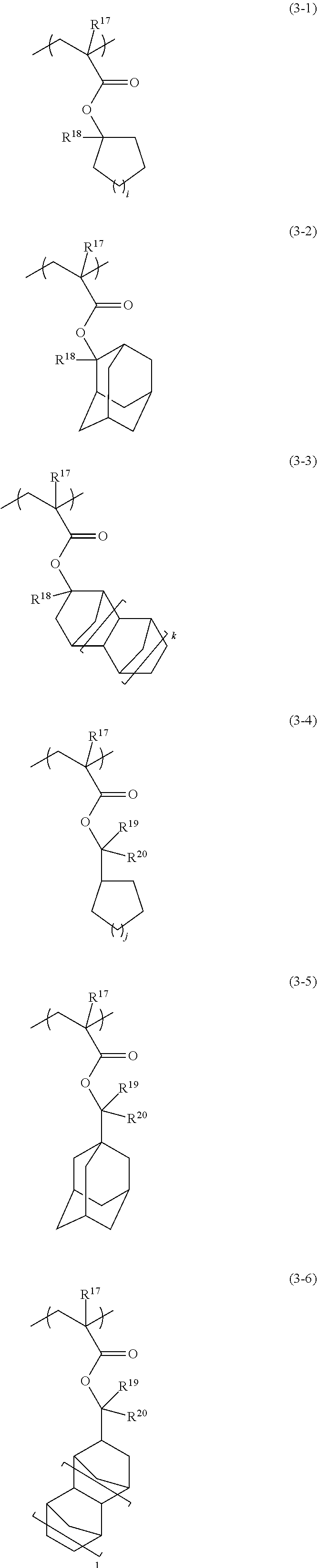

In the formulas (3-1) to (3-6), R¹⁷ to R²⁰ have the same meaning as in the formula (3), i and j are each independently an integer of 1 to 4, and k and 1 are each 0 or 1.

In the formulas (3-1) to (3-6), i and j are preferably 1, and R¹⁸ is preferably a methyl group, an ethyl group, an isopropyl group, or a cyclopentyl group. R¹⁹ and R²⁰ are each preferably a methyl group, or an ethyl group

The base resin may contain one type or a combination of two or more types of the structural units (I).

The lower limit of the content by percent of the structural unit (I) (a total content by percent when a plurality of types are contained) is preferably 10 mol %, more preferably 20 mol %, still more preferably 30 mol %, and particularly preferably 35 mol % based on all structural units constituting the base resin. The upper limit of the content by percent is preferably 80 mol %, more preferably 70 mol %, still more preferably 60 mol %, and particularly preferably 55 mol %. When the content of the structural unit (I) is set to fall within the above range, the pattern-forming performance of the radiation-sensitive resin composition can further be improved.

### [Structural Unit (II)]

The structural unit (II) is a structural unit including at least one selected from the group consisting of a lactone structure, a cyclic carbonate structure and a sultone structure. The solubility of the base resin into a developer can be adjusted by further introducing the structural unit (II). As a result, the radiation-sensitive resin composition can provide improved lithography properties such as the resolution. The adhesion between a resist pattern formed from the base resin and a substrate can also be improved.

Examples of the structural unit (II) include structural units represented by the formulae (T-1) to (T-10).

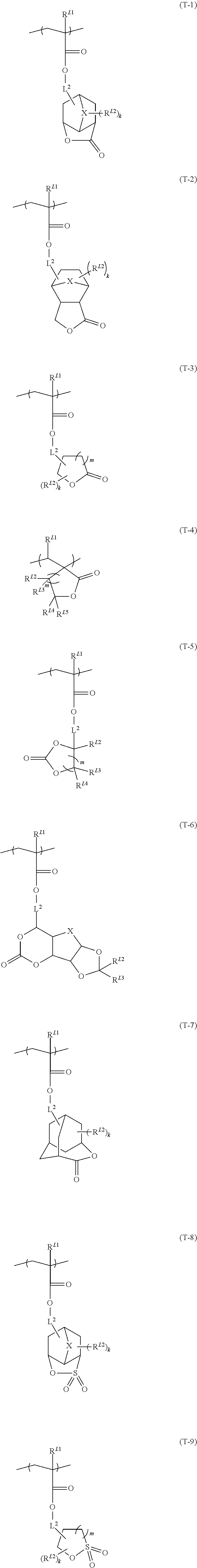

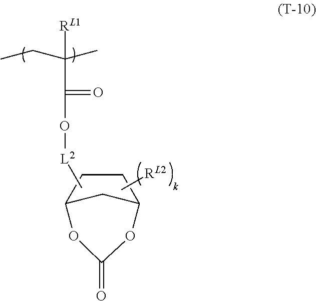

In the formulae, R^{L1} is a hydrogen atom, a fluorine atom, a methyl group, or a trifluoromethyl group; R^{L2} to R^{L5} are each independently a hydrogen atom, an alkyl group having a carbon number of 1 to 4, a cyano group, a trifluoromethyl group, a methoxy group, a methoxycarbonyl group, a hydroxy group, a hydroxymethyl group, or a dimethylamino group; R^{L4} and R^{L5} may be a divalent alicyclic group having a carbon number of 3 to 8, which is obtained by combining R^{L4} and R^{L5} with the carbon atom to which they are bound. L² is a single bond, or a divalent linking group; X is an oxygen atom or a methylene group; k is an integer of 0 to 3; and m is an integer of 1 to 3.

Example of the divalent alicyclic group having a carbon number of 3 to 8, which is composed of a combination of R^{L4} and R^{L5} with the carbon atom to which they are bound, includes the divalent alicyclic group having a carbon number of 3 to 8 in the divalent alicyclic group having a carbon number of 3 to 20, which is composed of a combination of R¹⁹ and R²⁰ in the formula (3) with the carbon atom to which they are bound. One or more hydrogen atoms on the alicyclic group may be substituted with a hydroxy group.

Examples of the divalent linking group represented by L² as described above include a divalent straight or branched chain hydrocarbon group having a carbon number of 1 to 10; a divalent alicyclic hydrocarbon group having a carbon number of 4 to 12; and a group composed of one or more of the hydrocarbon group thereof and at least one group of —CO—, —O—, —NH— and —S—.

Among them, the structural unit (II) is preferably a group having a lactone structure, more preferably a group having a norbornane lactone structure, and further preferably a group derived from a norbornane lactone-yl (meth)acrylate.

The lower limit of the content by percent of the structural unit (II) is preferably 15 mol %, more preferably 20 mol %, and still more preferably 25 mol % based on all structural units constituting the base resin. The upper limit of the content by percent is preferably 80 mol %, more preferably 70 mol %, and still more preferably 65 mol %. By adjusting the content by percent of the structural unit D within the ranges, the radiation-sensitive resin composition can provide improved lithography properties such as the resolution. The adhesion between the formed resist pattern and the substrate can also be improved.

### [Structural Unit (III)]

The base resin optionally has another structural unit in addition to the structural units (I) and (II). Another structural unit includes a structural unit (III) containing a polar group (excluding those corresponding to the structural unit (II)). When the base resin further has a structural unit (III), solubility in the developer can be adjusted. As a result, lithographic performance such as resolution of the radiation-sensitive resin composition can be improved. Examples of the polar group include a hydroxy group, a carboxy group, a cyano group, a nitro group, and a sulfonamide group. Among them, a hydroxy group and a carboxy group are preferable, and a hydroxy group is more preferable.

Examples of the structural unit (III) include structural units represented by the formulas.

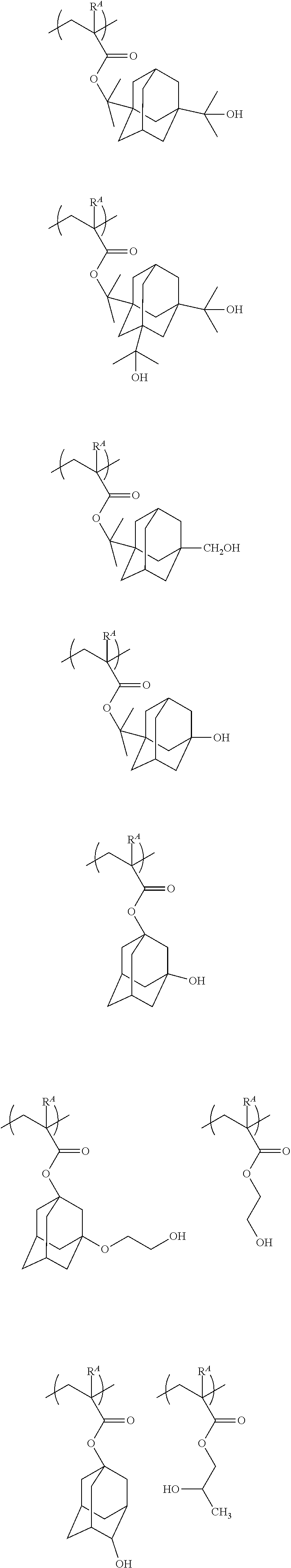

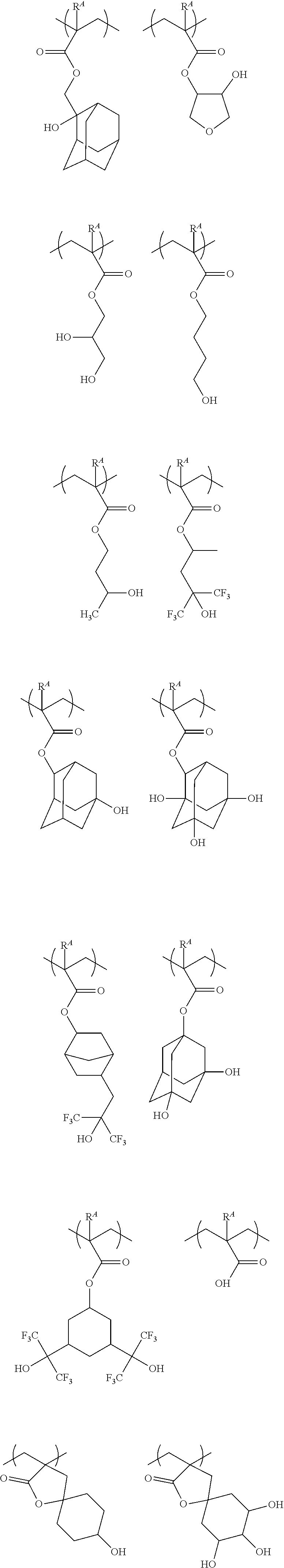

In the formulas, R^{A} is a hydrogen atom, a fluorine atom, a methyl group, or a trifluoromethyl group.

When the base resin has the structural unit (III) having a polar group, the lower limit of the content by percent of the structural unit (III) is preferably 5 mol %, more preferably 8 mol %, and still more preferably 10 mol % based on all structural units constituting the base resin. The upper limit of the content by percent is preferably 40 mol %, more preferably 30 mol %, and still more preferably 25 mol %. When the content of the structural unit having a polar group is set to fall within the above range, the radiation-sensitive resin composition can provide further improved lithography properties such as the resolution.

### [Structural Unit (IV)]

The base resin optionally has, as another structural unit, a structural unit derived from hydroxystyrene or a structural unit having a phenolic hydroxyl group (hereinafter, both are also collectively referred to as “structural unit (IV)”), in addition to the structural unit (III) having a polar group. The structural unit (IV) contributes to an improvement in etching resistance and an improvement in a difference in solubility of a developer (dissolution contrast) between an exposed part and a non-exposed part. In particular, the structural unit (IV) can be suitably applied to pattern formation using exposure with a radioactive ray having a wavelength of 50 nm or less, such as an electron beam or EUV. In this case, the resin preferably has the structural unit (I) together with the structural unit (IV).

The structural unit derived from hydroxystyrene is represented by, for example, the formulas (4-1) and (4-2), and the structural unit containing a phenolic hydroxy group is represented by, for example, the formulas (4-3) and (4-4).

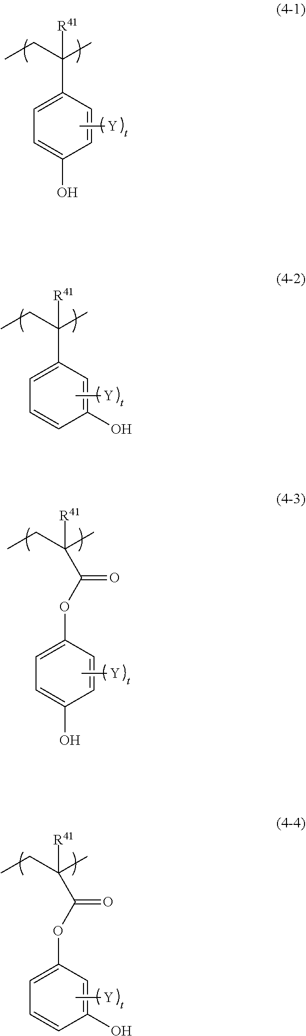

In the formulas (4-1) to (4-4), R⁴¹ is independently at each occurrence a hydrogen atom, a fluorine atom, a methyl group, or a trifluoromethyl group. Y is a halogen atom, a trifluoromethyl group, a cyano group, an alkyl or alkoxy group having 1 to 6 carbon atoms, or an acyl, acyloxy, or alkoxycarbonyl group having 2 to 7 carbon atoms. When there are a plurality of Y's, the plurality of Y's are the same or different from each other, t is an integer of 0 to 4.

When the structural unit (IV) is obtained, it is preferable to obtain the structural unit (IV) by polymerizing the monomer in a state where the phenolic hydroxy group is protected by a protecting group such as an alkali-dissociable group (e.g., an acyl group) during polymerization, and then deprotecting the polymerized product by hydrolysis.

In the case of a resin for exposure to radiation having a wavelength of 50 nm or less, the lower limit of the content by percent of the structural unit (IV) is preferably 10 mol %, and more preferably 20 mol % based on all structural units constituting the resin. The upper limit of the content by percent is preferably 70 mol %, and more preferably 60 mol %.

### [Other Structural Unit]

The base resin may contain, as a structural unit other than the structural units listed above, a structural unit represented by the formula (6) and containing an alicyclic structure.

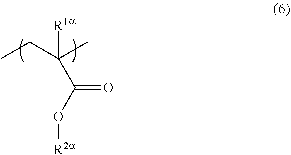

In the formula (6), R^{1α} represents a hydrogen atom, a fluorine atom, a methyl group, or a trifluoromethyl group, and R^{2α} represents a monovalent alicyclic hydrocarbon group having 3 to 20 carbon atoms.

In the formula (6), as the monovalent alicyclic hydrocarbon group having 3 to 20 carbon atoms represented by R^{2α}, the monovalent alicyclic hydrocarbon groups having 3 to 20 carbon atoms represented by R² and R³ in the formula (1) can be suitably employed.

When the base resin contains the structural unit having an alicyclic structure, the lower limit of the content by percent of the structural unit having an alicyclic structure is preferably 2 mol %, more preferably 5 mol %, and still more preferably 8 mol % based on all structural units constituting the base resin. The upper limit of the content by percent is preferably 30 mol %, more preferably 20 mol %, and still more preferably 15 mol %.

### Synthesis Method of Base Resin

For example, the base resin can be synthesized by performing a polymerization reaction of each monomer for providing each structural unit with a radical polymerization initiator or the like in a suitable solvent.

Examples of the radical polymerization initiator include an azo-based radical initiator, including azobisisobutyronitrile (AIBN), 2,2′-azobis(4-methoxy-2,4-dimethylvaleronitrile), 2,2′-azobis(2-cyclopropylpropanenitrile), 2,2′-azobis(2,4-dimethylvaleronitrile), and dimethyl 2,2′-azobisisobutyrate; and peroxide-based radical initiator, including benzoyl peroxide, t-butyl hydroperoxide, and cumene hydroperoxide. Among them, AIBN or dimethyl 2,2′-azobisisobutyrate is preferred, and AIBN is more preferred. The radical initiator may be used alone, or two or more radical initiators may be used in combination.

Examples of the solvent used for the polymerization reaction include
alkanes including n-pentane, n-hexane, n-heptane, n-octane, n-nonane, and n-decane;
cycloalkanes including cyclohexane, cycloheptane, cyclooctane, decalin, and norbornane;
aromatic hydrocarbons including benzene, toluene, xylene, ethylbenzene, and cumene;
halogenated hydrocarbons including chlorobutanes, bromohexanes, dichloroethanes, hexamethylenedibromide, and chlorobenzenes;
saturated carboxylate esters, including ethyl acetate, n-butyl acetate, i-butyl acetate, and methyl propionate;
ketones including acetone, methyl ethylketone, 2-butanone, 4-methyl-2-pentanone, and 2-heptanone;
ethers including tetrahydrofuran, dimethoxyethanes, and diethoxyethanes; and
alcohols including methanol, ethanol, 1-propanol, 2-propanol, and 4-methyl-2-pentanol. The solvent used for the polymerization reaction may be used alone, or two or more solvents may be used in combination.

The reaction temperature of the polymerization reaction is typically from 40° C. to 150° C., and preferably from 50° C. to 120° C. The reaction time is typically from 1 hour to 48 hours, and preferably from 1 hour to 24 hours.

The molecular weight of the base resin is not particularly limited, and the lower limit of the weight-average molecular weight (Mw) equivalent to polystyrene determined by gel permeation chromatography (GPC) is preferably 2,000, more preferably 3,000, still more preferably 4,000, and particularly preferably 4,500. The upper limit of the Mw is preferably 30,000, more preferably 20,000, still more preferably 10,000, and particularly preferably 8,000. Setting the Mw of the base resin to the above range makes a resist film to be obtained possible to exhibit good heat resistance and developability.

For the base resin as a base resin, the ratio of Mw to the number average molecular weight (Mn) as determined by GPC relative to standard polystyrene (Mw/Mn) is typically not less than 1 and not more than 5, preferably not less than 1 and not more than 3, and more preferably not less than 1 and not more than 2.

The Mw and Mn of the resin in the specification are amounts measured by using Gel Permeation Chromatography (GPC) with the condition as described below.
GPC column: two G2000HXL, one G3000HXL, and one G4000HXL (all manufactured from Tosoh Corporation)
Column temperature: 40° C.
Eluting solvent: tetrahydrofuran
Flow rate: 1.0 mL/min
Sample concentration: 1.0% by mass
Sample injection amount: 100 μL
Detector: Differential Refractometer
Reference material: monodisperse polystyrene

The content by percent of the base resin is preferably 60% by mass or more, more preferably 65% by mass or more, and still more preferably 70% by mass or more based on the total solid content of the radiation-sensitive resin composition.

### (Another Resin)

The radiation-sensitive resin composition according to the present embodiment may contain, as another resin, a resin having higher content by mass of fluorine atoms than the above-described base resin (hereinafter, also referred to as a “high fluorine-content resin”). When the radiation-sensitive resin composition contains the high fluorine-content resin, the high fluorine-content resin can be localized in the surface layer of a resist film compared to the base resin, which as a result makes it possible to enhance the water repellency of the surface of the resist film during immersion exposure or to perform surface modification of the resist film during EUV exposure or control of the distribution of the composition in the film.

The high fluorine-content resin preferably has, for example, a structural unit represented by the formula (5) (hereinafter, also referred to as “structural unit (V)”), and may have the structural unit (I) or the structural unit (III) in the base resin as necessary.

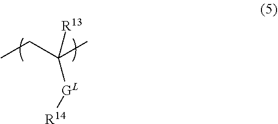

In the formula (5), R¹³ is a hydrogen atom, a methyl group, or a trifluoromethyl group; G^{L} is a single bond, an alkanediyl group having 1 to 5 carbon atoms, an oxygen atom, a sulfur atom, —COO—, —SO₂ONH—, —CONH—, —OCONH—, or a combination thereof; and R¹⁴ is a monovalent fluorinated chain hydrocarbon group having a carbon number of 1 to 20, or a monovalent fluorinated alicyclic hydrocarbon group having a carbon number of 3 to 20.

As R¹³ as described above, in terms of the copolymerizability of monomers resulting in the structural unit (V), a hydrogen atom or a methyl group is preferred, and a methyl group is more preferred.

As G^{L} as described above, in terms of the copolymerizability of monomers resulting in the structural unit (V), a single bond or —COO— is preferred, and —COO— is more preferred.

Example of the monovalent fluorinated chain hydrocarbon group having a carbon number of 1 to 20 represented by R¹⁴ as described above includes a group in which a part of or all of hydrogen atoms in the straight or branched chain alkyl group having a carbon number of 1 to 20 is/are substituted with a fluorine atom.

Example of the monovalent fluorinated alicyclic hydrocarbon group having a carbon number of 3 to 20 represented by R¹⁴ as described above includes a group in which a part of or all of hydrogen atoms in the monocyclic or polycyclic hydrocarbon group having a carbon number of 3 to 20 is/are substituted with a fluorine atom.

The R¹⁴ as described above is preferably a fluorinated chain hydrocarbon group, more preferably a fluorinated alkyl group, and further preferably 2,2,2-trifluoroethyl group, 2,2,3,3,3-pentafluoropropyl group, 1,1,1,3,3,3-hexafluoropropyl group and 5,5,5-trifluoro-1,1-diethylpentyl group.

When the high fluorine-content resin has the structural unit (V), the lower limit of the content by percent of the structural unit (V) is preferably 50 mol %, more preferably 60 mol %, and still more preferably 70 mol % based on the total amount of all structural units constituting the high fluorine-content resin. The upper limit of the content by percent is preferably 95 mol %, more preferably 90 mol %, and still more preferably 85 mol %. When the content of the structural unit (V) is set to fall within the above range, the content by mass of fluorine atoms of the high fluorine-content resin can more appropriately be adjusted to further promote the localization of the high fluorine-content resin in the surface layer of a resist film, as a result, the water repellency of the resist film during immersion exposure can be further improved.

The high fluorine-content resin may have a fluorine atom-containing structural unit represented by the formula (f-2) (hereinafter, also referred to as a “structural unit (VI)”) in addition to or in place of the structural unit (V). When the high fluorine-content resin has the structural unit (VI), solubility in an alkaline developing solution is improved, and therefore generation of development defects can be prevented.

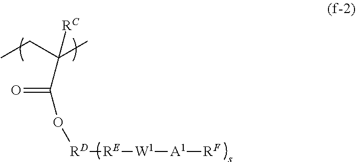

The structural unit (VI) is classified into two groups: a unit having an alkali soluble group (x); and a unit having a group (y) in which the solubility into the alkaline developing solution is increased by the dissociation by alkali (hereinafter, simply referred as an “alkali-dissociable group”). In both cases of (x) and (y), R^{C} in the formula (f-2) is a hydrogen atom, a fluorine atom, a methyl group, or a trifluoromethyl group; R^{D} is a single bond, a hydrocarbon group having a carbon number of 1 to 20 with the valency of (s+1), a structure in which an oxygen atom, a sulfur atom, —NR^{dd}—, a carbonyl group, —COO—, —OCO—, or —CONH— is connected to the terminal on R^{E} side of the hydrocarbon group, or a structure in which a part of hydrogen atoms in the hydrocarbon group is substituted with an organic group having a hetero atom; R^{dd} is a hydrogen atom, or a monovalent hydrocarbon group having a carbon number of 1 to 10; and s is an integer of 1 to 3.

When the structural unit (VI) has the alkali soluble group (x), R^{F} is a hydrogen atom; A¹ is an oxygen atom, —COO—* or —SO₂O—*; * refers to a bond to R^{E}; W¹ is a single bond, a hydrocarbon group having a carbon number of 1 to 20, or a divalent fluorinated hydrocarbon group. When A¹ is an oxygen atom, W¹ is a fluorinated hydrocarbon group having a fluorine atom or a fluoroalkyl group on the carbon atom connecting to A¹. R^{E} is a single bond, or a divalent organic group having a carbon number of 1 to 20. When s is 2 or 3, a plurality of R^{E}, W¹, A¹ and R^{E} may be each identical or different. The affinity of the high fluorine-content resin into the alkaline developing solution can be improved by including the structural unit (VI) having the alkali soluble group (x), and thereby prevent from generating the development defect. As the structural unit (VI) having the alkali soluble group (x), particularly preferred is a structural unit in which A¹ is an oxygen atom and W¹ is a 1,1,1,3,3,3-hexafluoro-2,2-methanediyl group.

When the structural unit (VI) has the alkali-dissociable group (y), R^{F} is a monovalent organic group having carbon number of 1 to 30; A¹ is an oxygen atom, —NR^{aa}—, —COO—*, —OCO—*, or —SO₂O—*; R^{aa} is a hydrogen atom, or a monovalent hydrocarbon group having a carbon number of 1 to 10; * refers to a bond to R^{F}; W¹ is a single bond, or a divalent fluorinated hydrocarbon group having a carbon number of 1 to 20; R^{E} is a single bond, or a divalent organic group having a carbon number of 1 to 20. When A¹ is —COO—*, —OCO—* or —SO₂O—*, W¹ or R^{F} has a fluorine atom on the carbon atom connecting to A¹ or on the carbon atom adjacent to the carbon atom. When A¹ is an oxygen atom, W¹ and R^{E} are a single bond; R^{D} is a structure in which a carbonyl group is connected at the terminal on R^{E} side of the hydrocarbon group having a carbon number of 1 to 20; and R^{F} is an organic group having a fluorine atom. When s is 2 or 3, a plurality of R^{E}, W¹, A¹ and R^{F} may be each identical or different. The surface of the resist film is changed from hydrophobic to hydrophilic in the alkaline developing step by including the structural unit (VI) having the alkali-dissociable group (y). As a result, the affinity of the high fluorine-content resin into the alkaline developing solution can be significantly improved, and thereby prevent from generating the development defect more efficiently. As the structural unit (VI) having the alkali-dissociable group (y), particularly preferred is a structural unit in which A¹ is —COO—*, and R^{F} or W¹, or both is/are a fluorine atom.

In terms of the copolymerizability of monomers resulting in the structural unit (VI), R^{C} is preferably a hydrogen atom or a methyl group, and more preferably a methyl group.

When R^{E} is a divalent organic group, R^{E} is preferably a group having a lactone structure, more preferably a group having a polycyclic lactone structure, and further preferably a group having a norbornane lactone structure.

When the high fluorine-content resin has the structural unit (VI), the lower limit of the content by percent of the structural unit (VI) is preferably 40 mol %, more preferably 50 mol %, and still more preferably 60 mol % based on the total amount of all structural units constituting the high fluorine-content resin. The upper limit of the content by percent is preferably 95 mol %, more preferably 90 mol %, and still more preferably 85 mol %. When the content by percent of the structural unit (VI) is set to fall within the above range, water repellency or development defect inhibition property of a resist film during immersion exposure can further be improved.

### [Other Structural Unit]

A high fluorine-containing resin may contain a structural unit having an alicyclic structure represented by the formula (6) as a structural unit other than the structural units listed above.

When the high fluorine-content resin contains the structural unit having an alicyclic structure, the lower limit of the content by percent of the structural unit having an alicyclic structure is preferably 10 mol %, more preferably 20 mol %, and still more preferably 30 mol % based on all structural units constituting the high fluorine-content resin. The upper limit of the content by percent is preferably 60 mol %, more preferably 50 mol %, and still more preferably 45 mol %.

The lower limit of the Mw of the high fluorine-content resin is preferably 2,000, more preferably 3,000, still more preferably 4,000, and particularly preferably 5,000. The upper limit of the Mw is preferably 30,000, more preferably 20,000, still more preferably 10,000, and particularly preferably 8,000.

The lower limit of the Mw/Mn of the high fluorine-content resin is usually 1, and more preferably 1.1. In addition, the upper limit of the Mw/Mn is usually 5, preferably 3, and more preferably 2.

When the radiation-sensitive resin composition contains the high-fluorine-content resin, the content of the high fluorine-containing resin is preferably 0.1 parts by mass or more, more preferably 0.5 parts by mass or more, still more preferably 1 part by mass or more, and particularly preferably 1.5 parts by mass or more based on 100 parts by mass of the base resin. The content of the high fluorine-containing resin is preferably 15 parts by mass or less, more preferably 10 parts by mass or less, still more preferably 8 parts by mass or less, and particularly preferably 5 parts by mass or less.

When the content of the high fluorine-content resin is set to fall within the above range, the high fluorine-content resin can more effectively be localized in the surface layer of a resist film, which as a result makes it possible to further enhance the water repellency of the surface of the resist film during immersion exposure or to perform surface modification of the resist film during EUV exposure or control of the distribution of the composition in the film. The radiation-sensitive resin composition may contain one kind of high fluorine-content resin or two or more kinds of high fluorine-content resins.

### (Method for Synthesizing High Fluorine-Content Resin)

The high fluorine-content resin can be synthesized by a method similar to the above-described method for synthesizing a base resin.

### (Acid Diffusion Controlling Agent)

The radiation-sensitive resin composition may include an acid diffusion controlling agent, if needed. The acid diffusion controlling agent has an effect of controlling the diffusion phenomenon in which an acid resulted from the first onium salt compound (1) and the second onium salt compound by the exposure is diffused in the resist film, and of inhibiting undesired chemical reaction in the non-exposed part. The acid diffusion controlling agent can also improve the storage stability of the resulting radiation-sensitive resin composition. The acid diffusion controlling agent can further improve the resolution of the resist pattern and prevent from changing the line width of the resist pattern because of the variation of the pulling and placing time, i.e., the time from the exposure to the developing treatment, and therefore provide the radiation-sensitive resin composition having an improved process stability.

Examples of the acid diffusion controlling agent include a compound represented by the formula (7) (hereinafter, also referred as a “nitrogen-containing compound (I)”); a compound having two nitrogen atoms in one molecule (hereinafter, also referred as a “nitrogen-containing compound (II)”); a compound having three nitrogen atoms in one molecule (hereinafter, also referred as a “nitrogen-containing compound (III)”); a compound having an amide group; a urea compound; and a nitrogen-containing heterocyclic ring compound.

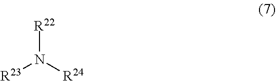

In the formula (7), R²², R²³ and R²⁴ are each independently a hydrogen atom, a substituted or unsubstituted alkyl group, a substituted or unsubstituted cycloalkyl group, a substituted or unsubstituted aryl group, or a substituted or unsubstituted aralkyl group.

Examples of the nitrogen-containing compound (I) include a monoalkylamine including n-hexylamine; a dialkylamine including di-n-butylamine; a trialkylamine including triethylamine; and an aromatic amine including aniline, 2,6-diisopropylaniline.

Examples of the nitrogen-containing compound (II) include ethylenediamine and N,N,N′,N′-tetramethylethylenediamine.

Examples of the nitrogen-containing compound (III) include a polyamine compound, including polyethyleneimine and polyallylamine; and a polymer including dimethylaminoethylacrylamide.

Examples of the amide-containing compound include formamide, N-methylformamide, N, N-dimethylformamide, acetamide, N-methylacetamide, N, N-dimethylacetamide, propionamide, benzamide, pyrrolidone, and N-methyl pyrrolidone.

Examples of the urea compound include urea, methylurea, 1,1-dimethylurea, 1,3-dimethylurea, 1,1,3,3-tetramethylurea, 1,3-diphenylurea, and tributylthiourea.

Examples of the nitrogen-containing heterocyclic ring compound include pyridines, including pyridine and 2-methylpyridine; morpholines, including N-propylmorpholine and N-(undecylcarbonyloxyethyl) morpholine; pyrazine, and pyrazole.

A compound having an acid-dissociable group may be used as the nitrogen-containing organic compound. Examples of the nitrogen-containing organic compound having an acid-dissociable group include N-t-butoxycarbonylpiperidine, N-t-butoxycarbonylimidazole, N-t-butoxycarbonylbenzimidazole, N-t-butoxycarbonyl-2-phenylbenzimidazole, N-(t-butoxycarbonyl)di-n-octylamine, N-(t-butoxycarbonyl) diethanolamine, N-(t-butoxycarbonyl)dicyclohexylamine, N-(t-butoxycarbonyl)diphenylamine, N-t-butoxycarbonyl-4-hydroxypiperidine, N-t-butoxycarbonyl-4-acetoxypiperidine, and N-t-amyloxycarbonyl-4-hydroxypiperidine.

As the acid diffusion control agent, a radiation-sensitive weak acid generator that generates a weak acid upon exposure can also be preferably used. The acid generated from the radiation-sensitive weak acid generator is a weak acid that does not induce the dissociation of the acid-dissociable groups in the resin under the conditions for dissociating the acid-dissociable groups. In the present specification, “dissociation” of an acid-dissociable group means dissociation upon post-exposure baking at 110° C. for 60 seconds.

Example of the radiation-sensitive weak acid generator includes an onium salt compound in which the compound is degraded by the exposure to lose the acid diffusion controlling properties. Examples of the onium salt compound include a sulfonium salt compound represented by the formula (8-1), and an iodonium salt compound represented by the formula (8-2). In addition, a compound represented by the formula (8-3) containing a sulfonium cation and an anion in the same molecule and a compound represented by the formula (8-4) containing an iodonium cation and an anion in the same molecule are also included.

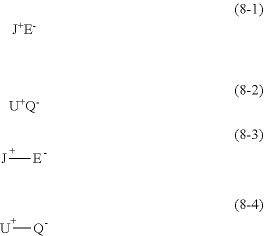

In the formulae (8-1) to formula (8-4), J⁺ is a sulfonium cation; and U⁺ is an iodonium cation. Examples of the sulfonium cation represented by J⁺ include sulfonium cations represented by the formulae (X-1) to (X-4). Examples of the iodonium cation represented by U⁺ include iodonium cations represented by the formulae (X-5) to (X-6). E⁻ and Q⁻ are each independently anion represented by OH⁻, R^{α}—COO⁻, and R^{α}—SO₃⁻. R^{α} is an alkyl group, an aryl group, or an aralkyl group. A hydrogen atom in the aromatic ring of the aryl group or the aralkyl group represented by R^{α} may be substituted with a hydroxy group, a fluorine atom-substituted or unsubstituted alkyl group having a carbon number of 1 to 12, or an alkoxy group having a carbon number of 1 to 12. R^{α} is a single bond, or a monovalent organic group having 1 to 30 carbon atoms. Examples of the organic group include a monovalent hydrocarbon group having 1 to 20 carbon atoms, a group containing a divalent hetero atom-containing group between two carbon atoms or at a carbon chain terminal of the foregoing hydrocarbon group, a group obtained by substituting some or all of the hydrogen atoms of the foregoing hydrocarbon group with a monovalent hetero atom-containing group, and a combination thereof.

As the monovalent hydrocarbon groups having 1 to 20 carbon atoms, the monovalent hydrocarbon groups having 1 to 20 carbon atoms in R² and R³ of the formula (1) can be suitably employed.

As the divalent hetero atom-containing group and the monovalent hetero atom-containing group, the divalent hetero atom-containing groups and the monovalent hetero atom-containing groups in R⁴ of the formula (2) can be suitably employed.

Examples of the radiation-sensitive weak acid generator include compounds represented by the formulae.

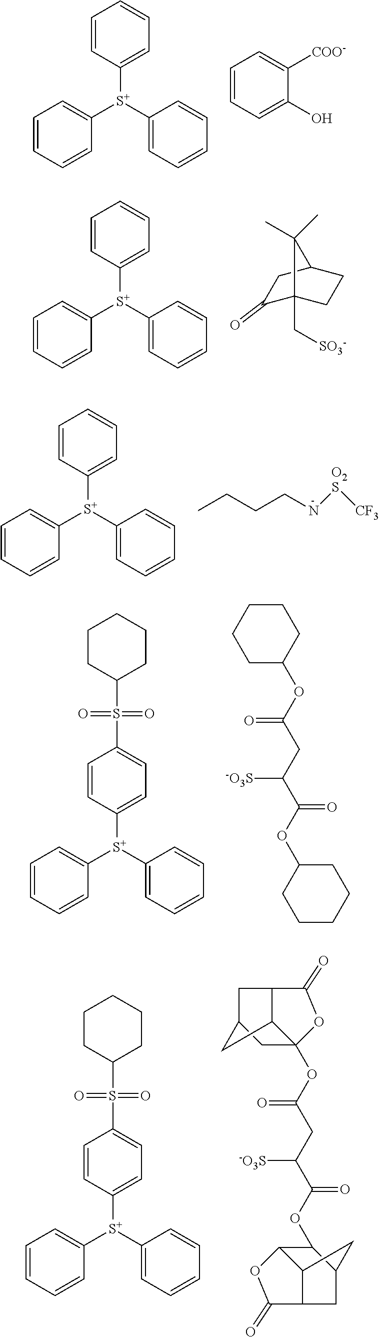

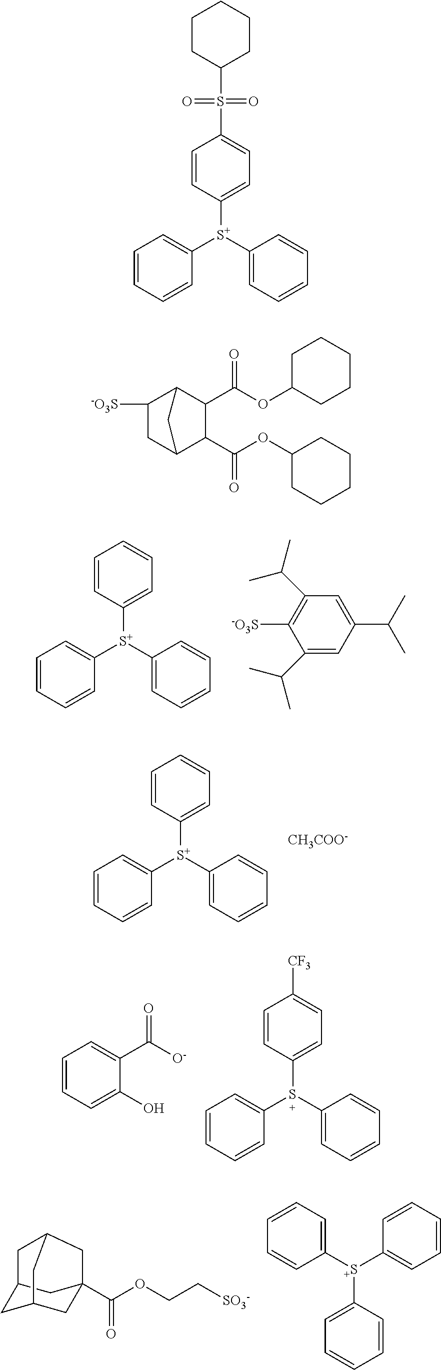

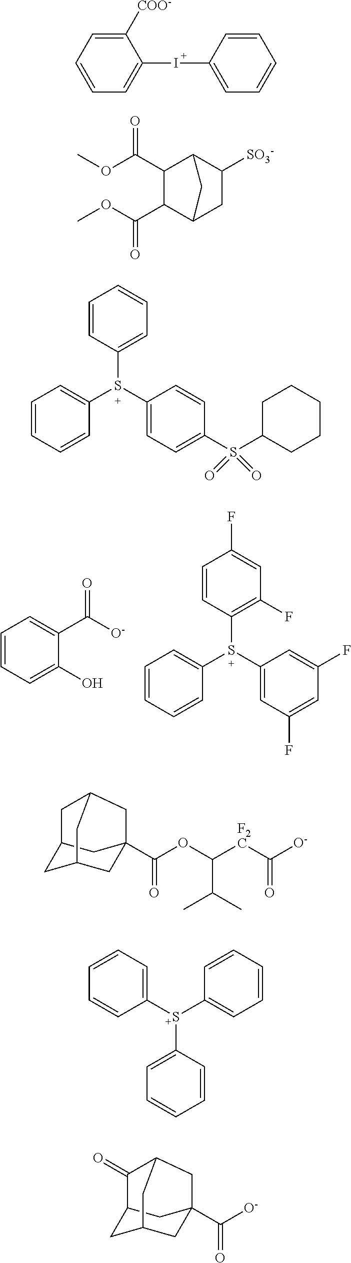

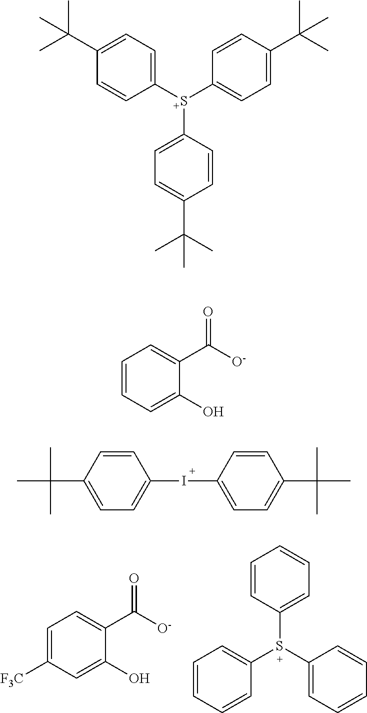

Among them, the radiation-sensitive weak acid generator is preferably the sulfonium salt, more preferably a triarylsulfonium salt, and further preferably a triphenylsulfonium salicylate or triphenylsulfonium 10-camphorsulfonate.

The lower limit of the content of the acid diffusion controlling agent is preferably 0.5 parts by mass, more preferably 1 part by mass, still more preferably 3 parts by mass, and particularly preferably 5 parts by mass based on 100 parts by mass of the resin. The upper limit of the content is preferably 40 parts by mass, more preferably 30 parts by mass, and still more preferably 25 parts by mass.

By adjusting the content of the acid diffusion controlling agent within the ranges, the radiation-sensitive resin composition can provide improved lithography properties. The radiation-sensitive resin composition may contain one type of the acid diffusion controlling agent, or two or more acid diffusion controlling agents in combination.

### (Solvent)

The radiation-sensitive resin composition according to the present embodiment contains a solvent. The solvent is not particularly limited as long as it can dissolve or disperse at least the first onium salt compound, the second onium salt compound, the resin, and an acid diffusion controlling agent or the like contained as necessary.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:
a monoalcohol-based solvent having a carbon number of 1 to 18, including iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
a polyhydric alcohol having a carbon number of 2 to 18, including ethylene glycol, 1,2-propylene glycol, 2-methyl-2,4-pentanediol, 2,5-hexanediol, diethylene glycol, dipropylene glycol, triethylene glycol, and tripropylene glycol; and
a partially etherized polyhydric alcohol-based solvent in which a part of hydroxy groups in the polyhydric alcohol-based solvent is etherized.

In the present embodiment, alcohol acid ester-based solvents such as methyl lactate, ethyl lactate, propyl lactate, butyl lactate, methyl 2-hydroxyisobutyrate, i-propyl 2-hydroxyisobutyrate, i-butyl 2-hydroxyisobutyrate, and n-butyl 2-hydroxyisobutyrate are also included in the alcohol-based solvent.

Examples of the ether-based solvent include:
a dialkyl ether-based solvent, including diethyl ether, dipropyl ether, and dibutyl ether;
a cyclic ether-based solvent, including tetrahydrofuran and tetrahydropyran;
an ether-based solvent having an aromatic ring, including diphenylether and anisole (methyl phenyl ether); and
an etherized polyhydric alcohol-based solvent in which a hydroxy group in the polyhydric alcohol-based solvent is etherized.

Examples of the ketone-based solvent include:
a chain ketone-based solvent, including acetone, butanone, and methyl-iso-butyl ketone;
a cyclic ketone-based solvent, including cyclopentanone, cyclohexanone, and methylcyclohexanone; and 2,4-pentanedione, acetonylacetone, and acetophenone.

Examples of the amide-based solvent include:
a cyclic amide-based solvent, including N,N′-dimethyl imidazolidinone and N-methylpyrrolidone; and
a chain amide-based solvent, including N-methylformamide, N, N-dimethylformamide, N, N-diethylformamide, acetamide, N-methylacetamide, N, N-dimethylacetamide, and N-methylpropionamide.

Examples of the ester-based solvent include:
a monocarboxylate ester-based solvent, including n-butyl acetate and ethyl lactate;
a partially etherized polyhydric alcohol acetate-based solvent, including diethylene glycol mono-n-butyl ether acetate, propylene glycol monomethyl ether acetate, and dipropylene glycol monomethyl ether acetate;
a lactone-based solvent, including γ-butyrolactone and valerolactone;
a carbonate-based solvent, including diethyl carbonate, ethylene carbonate, and propylene carbonate; and
a polyhydric carboxylic acid diester-based solvent, including propylene glycol diacetate, methoxy triglycol acetate, diethyl oxalate, ethyl acetoacetate, ethyl lactate, and diethyl phthalate.

Examples of the hydrocarbon-based solvent include:
an aliphatic hydrocarbon-based solvent, including n-hexane, cyclohexane, and methylcyclohexane;
an aromatic hydrocarbon-based solvent, including benzene, toluene, di-iso-propylbenzene, and n-amylnaphthalene.

Among these, an alcohol-based solvent, an ester-based solvent, and an ether-based solvent are preferable, an alcohol acid ester-based solvent, a polyhydric alcohol partial ether acetate-based solvent, a lactone-based solvent, a monocarboxylic acid ester-based solvent, and a polyhydric alcohol partial ether-based solvent are more preferable, and propylene glycol monomethyl ether acetate, γ-butyrolactone, ethyl lactate, and propylene glycol monomethyl ether are still more preferable. The radiation-sensitive resin composition may include one type of the solvent, or two or more types of the solvents in combination.

### <Other Optional Components>

The radiation-sensitive resin composition may contain other optional components other than the above-descried components. Examples of other optional components include a cross-linking agent, a localization enhancing agent, a surfactant, an alicyclic backbone-containing compound, and a sensitizer. These other optional components may be used singly or in combination of two or more of them.

### <Method for Preparing Radiation-Sensitive Resin Composition>

The radiation-sensitive resin composition can be prepared by, for example, mixing the first onium salt compound, the second onium salt compound, the resin, and, as necessary, the high fluorine-content resin or the like, as well as the solvent in a prescribed ratio. The radiation-sensitive resin composition is preferably filtered through, for example, a filter having a pore diameter of about 0.05 μm to 0.40 μm after mixing. The solid matter concentration of the radiation-sensitive resin composition is usually 0.1 mass % to 50 mass %, preferably 0.5 mass % to 30 mass %, more preferably 1 mass % to 20 mass %.

### <Method for Forming Pattern>

A pattern forming method according to an embodiment of the present disclosure includes:
a step (1) of applying the radiation-sensitive resin composition directly or indirectly on a substrate to form a resist film (hereinafter, also referred to as a “resist film forming step”);
a step (2) of exposing the resist film (hereinafter, also referred to as an “exposure step”); and
a step (3) of developing the exposed resist film (hereinafter, also referred to as a “developing step”).

In accordance with this method for forming a resist pattern, a high-quality resist pattern can be formed because of the use of the radiation-sensitive resin composition described above capable of forming a resist film superior in sensitivity, LWR performance, DOF performance, pattern rectangularity, CDU performance, and pattern circularity in an exposure step. Hereinbelow, each of the steps will be described.

### [Resist Film Forming Step]

In this step (the above mentioned step (1)), a resist film is formed with the radiation-sensitive resin composition. Examples of the substrate on which the resist film is formed include one traditionally known in the art, including a silicon wafer, silicon dioxide, and a wafer coated with aluminum. An organic or inorganic antireflection film may be formed on the substrate, as disclosed in JP-B-06-12452 and JP-A-59-93448. Examples of the applicating method include a rotary coating (spin coating), flow casting, and roll coating. After applicating, a prebake (PB) may be carried out in order to evaporate the solvent in the film, if needed. The temperature of PB is typically from 60° C. to 140° C., and preferably from 80° C. to 120° C. The duration of PB is typically from 5 seconds to 600 seconds, and preferably from 10 seconds to 300 seconds.

The lower limit of the thickness of the resist film to be formed is preferably 10 nm, more preferably 15 nm, and still more preferably 20 nm. The upper limit of the film thickness is preferably 500 nm, more preferably 400 nm, and still more preferably 300 nm. In particular, when a thick resist film is exposed to ArF excimer laser light in an exposure step described later, the lower limit of the film thickness may be 100 nm, may be 150 nm, or may be 200 nm.

When the immersion exposure is carried out, irrespective of presence of a water repellent polymer additive such as the high fluorine-content resin in the radiation-sensitive resin composition, the formed resist film may have a protective film for the immersion which is not soluble into the immersion liquid on the film in order to prevent a direct contact between the immersion liquid and the resist film. As the protective film for the immersion, a solvent-removable protective film that is removed with a solvent before the developing step (for example, see JP-A-2006-227632); or a developer-removable protective film that is removed during the development of the developing step (for example, see WO2005-069076 and WO2006-035790) may be used. In terms of the throughput, the developer-removable protective film is preferably used.

When the next step, the exposure step, is performed with radiation having a wavelength of 50 nm or less, it is preferable to use a resin having the structural unit (I) and the structural unit (IV) as the base resin in the composition.

### [Exposing Step]

In this step (the above mentioned step (2)), the resist film formed in the resist film forming step as the step (1) is exposed by irradiating with a radioactive ray through a photomask (optionally through an immersion medium such as water). Examples of the radioactive ray used for the exposure include visible ray, ultraviolet ray, far ultraviolet ray, extreme ultraviolet ray (EUV); an electromagnetic wave including X ray and γ ray; an electron beam; and a charged particle radiation such as a ray. Among them, far ultraviolet ray, an electron beam, or EUV is preferred. ArF excimer laser light (wavelength is 193 nm), KrF excimer laser light (wavelength is 248 nm), an electron beam, or EUV is more preferred. An electron beam or EUV having a wavelength of 50 nm or less which is identified as the next generation exposing technology is further preferred.

When the exposure is carried out by immersion exposure, examples of the immersion liquid include water and fluorine-based inert liquid. The immersion liquid is preferably a liquid which is transparent with respect to the exposing wavelength, and has a minimum temperature factor of the refractive index so that the distortion of the light image reflected on the film becomes minimum. However, when the exposing light source is ArF excimer laser light (wavelength is 193 nm), water is preferably used because of the ease of availability and ease of handling in addition to the above considerations. When water is used, a small proportion of an additive that decreases the surface tension of water and increases the surface activity may be added. Preferably, the additive cannot dissolve the resist film on the wafer and can neglect an influence on an optical coating at an under surface of a lens. The water used is preferably distilled water.

After the exposure, post exposure bake (PEB) is preferably carried out to promote the dissociation of the acid-dissociable group in the resin by the acid generated from the radiation-sensitive acid generator with the exposure in the exposed part of the resist film. The difference of solubility into the developer between the exposed part and the non-exposed part is generated by the PEB. The temperature of PEB is typically from 50° C. to 180° C., and preferably from 80° C. to 130° C. The duration of PEB is typically from 5 seconds to 600 seconds, and preferably from 10 seconds to 300 seconds.

### [Developing Step]

In this step (the above mentioned step (3)), the resist film exposed in the exposing step as the step (2) is developed. By this step, the predetermined resist pattern can be formed. After the development, the resist pattern is washed with a rinse solution such as water or alcohol, and the dried, in general.

Examples of the developer used for the development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferred, and 2.38% by mass of aqueous TMAH solution is more preferred.

In the case of the development with organic solvent, examples of the solvent include an organic solvent, including a hydrocarbon-based solvent, an ether-based solvent, an ester-based solvent, a ketone-based solvent, and an alcohol-based solvent; and a solvent containing an organic solvent. Examples of the organic solvent include one, two or more solvents listed as the solvent for the radiation-sensitive resin composition. Among them, an ether-based solvent, an ester-based solvent or a ketone-based solvent is preferred. As the ether-based solvent, a glycol ether-based solvent is preferable, and ethylene glycol monomethyl ether and propylene glycol monomethyl ether are more preferable. The ester-based solvent is preferably an acetate ester-based solvent, and more preferably n-butyl acetate or amyl acetate. The ketone-based solvent is preferably a chain ketone, and more preferably 2-heptanone. The content of the organic solvent in the developer is preferably not less than 80% by mass, more preferably not less than 90% by mass, further preferably not less than 95% by mass, and particularly preferably not less than 99% by mass. Examples of the ingredient other than the organic solvent in the developer include water and silicone oil.

As described above, the developer may be either an alkaline developer or an organic solvent developer. The developer can be appropriately selected depending on whether the desired positive pattern or negative pattern is desired.

Examples of the developing method include a method of dipping the substrate in a tank filled with the developer for a given time (dip method); a method of developing by putting and leaving the developer on the surface of the substrate with the surface tension for a given time (paddle method); a method of spraying the developer on the surface of the substrate (spray method); and a method of injecting the developer while scanning an injection nozzle for the developer at a constant rate on the substrate rolling at a constant rate (dynamic dispense method).

### EXAMPLES

Hereinafter, the present invention will be specifically described with reference to Examples, but the present invention is not limited to these Examples. Methods for measuring various physical property values are shown below.

### [Weight-Average Molecular Weight (Mw) and Number-Average Molecular Weight (Mn)]

The Mw and Mn of a resin were measured under the conditions described above. A degree of dispersion (Mw/Mn) was calculated from results of the measured Mw and Mn.

### [¹³C-NMR Analysis]

¹³C-NMR analysis of the resin was performed using a nuclear magnetic resonance apparatus (“JNM-Delta 400” manufactured by JEOL Ltd.).

### Synthesis of Resin

Monomers used for synthesis of resins in Examples and Comparative Examples are shown below. In the following synthesis examples, unless otherwise specified, “parts by mass” means a value taken when the total mass of the monomers used is 100 parts by mass, and “mol %” means a value taken when the total number of moles of the monomers used is 100 mol %.

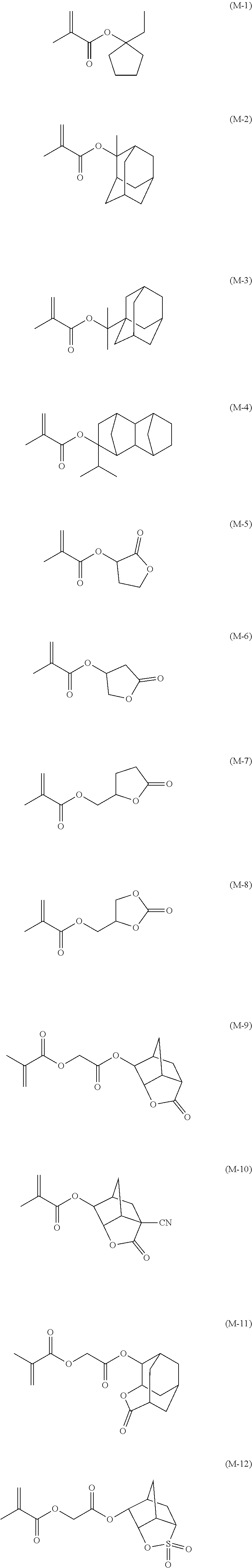

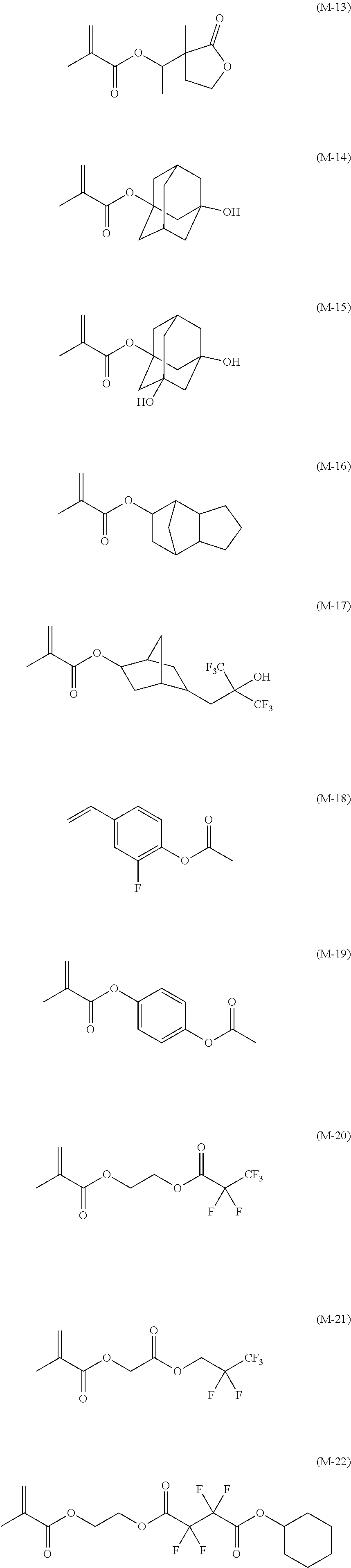

### Synthesis Example 1

### Synthesis of Resin (A-1)

A monomer (M-1), a monomer (M-2), a monomer (M-5), a monomer (M-10), and a monomer (M-14) were dissolved at a molar ratio of 40/10/20/20/10 (mol %) in 2-butanone (200 parts by mass), and AIBN (azobisisobutyronitrile) (5 mol % based on 100 mol % in total of the monomers used) was added thereto as an initiator to prepare a monomer solution. 2-butanone (100 parts 10 by mass) was placed in a reaction vessel, and the reaction vessel was purged with nitrogen for 30 minutes. Then, the temperature inside the reaction vessel was adjusted to 80° C., and the monomer solution was added dropwise thereto over 3 hours with stirring. A polymerization reaction was performed for 6 hours with the start of the dropwise addition regarded as the start time of the polymerization reaction. After the completion of the polymerization reaction, the polymerization solution was cooled with water to 30° C. or lower. The polymerization solution cooled was poured into methanol (2,000 parts by mass), and a precipitated white powder was collected by filtration. The white powder separated by filtration was washed with methanol twice, then separated by filtration, and dried at 50° C. for 24 hours to obtain a white powdery resin (A-1) (yield: 85%). The resin (A-1) had an Mw of 7,100 and an Mw/Mn of 1.61. As a result of ¹³C-NMR analysis, the contents by percent of the structural units derived from (M-1), (M-2), (M-5), (M-10), and (M-14) were 40.3 mol %, 9.2 mol %, 20.5 mol %, 19.8 mol %, and 10.2 mol %, respectively.

### Synthesis Examples 2 to 11

### Synthesis of Resins (A-2) to (A-11)

Resins (A-2) to (A-11) were synthesized in the same manner as in Synthesis Example 1 except that monomers of types and blending ratios shown in the following Table 1 were used. The content by percent (mol %) and physical property values (Mw and Mw/Mn) of each of the structural units of the resulting resins are also shown in Table 1. In Table 1, “-” indicates that the corresponding monomer was not used (the same applies to Tables below).

TABLE 1

| | | Monomer that gives structural | | | Monomer that gives structural | | | Monomer that affords structural | | | | |
|---|---|---|---|---|---|---|---|---|---|---|---|---|
| | | unit (I) | | | unit (II) | | | unit (III) and the like | | | | |
| | | | | Content by | | | Content by | | | Content by | | |
| | | | | percent of | | | percent of | | | percent of | | |
| | | | Blending | structural | | Blending | structural | | Blending | structural | | |
| | Resin | | ratio | unit | | ratio | unit | | ratio | unit | | |
| | [A] | Type | (mol %) | (mol %) | Type | (mol %) | (mol %) | Type | (mol %) | (mol %) | Mw | Mw/Mn |
| Synthesis | A-1 | M-1 | 40 | 40.3 | M-5 | 20 | 20.5 | M-14 | 10 | 10.2 | 7100 | 1.61 |
| Example 1 | | M-2 | 10 | 9.2 | M-10 | 20 | 19.8 | | | | | |
| Synthesis | A-2 | M-1 | 30 | 30.2 | M-9 | 50 | 50.6 | — | — | — | 7700 | 1.51 |
| Example 2 | | M-2 | 20 | 19.2 | | | | | | | | |
| Synthesis | A-3 | M-1 | 30 | 31.0 | M-11 | 50 | 49.4 | — | — | — | 7200 | 1.59 |
| Example 3 | | M-3 | 20 | 19.6 | | | | | | | | |
| Synthesis | A-4 | M-1 | 40 | 40.5 | M-12 | 50 | 49.2 | — | — | — | 6800 | 1.61 |
| Example 4 | | M-3 | 10 | 10.3 | | | | | | | | |
| Synthesis | A-5 | M-1 | 40 | 40.6 | M-13 | 50 | 51.3 | — | — | — | 6900 | 1.44 |
| Example 5 | | M-4 | 10 | 8.1 | | | | | | | | |
| Synthesis | A-6 | M-1 | 40 | 40.9 | M-6 | 20 | 20.5 | M-16 | 10 | 10.0 | 7500 | 1.51 |
| Example 6 | | M-4 | 10 | 8.3 | M-9 | 20 | 20.3 | | | | | |
| Synthesis | A-7 | M-1 | 50 | 50.2 | M-10 | 30 | 29.6 | M-14 | 20 | 20.2 | 7200 | 1.55 |
| Example 7 | | | | | | | | | | | | |
| Synthesis | A-8 | M-1 | 40 | 40.0 | M-7 | 20 | 20.5 | M-15 | 10 | 9.2 | 7100 | 1.62 |
| Example 8 | | M-3 | 10 | 10.1 | M-11 | 20 | 20.2 | | | | | |
| Synthesis | A-9 | M-1 | 50 | 50.3 | M-8 | 50 | 49.7 | — | — | — | 7000 | 1.51 |
| Example 9 | | | | | | | | | | | | |
| Synthesis | A-10 | M-1 | 40 | 40.2 | M-9 | 60 | 59.8 | — | — | — | 6700 | 1.50 |
| Example 10 | | | | | | | | | | | | |
| Synthesis | A-11 | M-2 | 40 | 39.4 | M-10 | 60 | 60.6 | — | — | — | 7500 | 1.49 |
| Example 11 | | | | | | | | | | | | |

### Synthesis of Resin (A-12)

Monomers (M-1) and (M-18) were dissolved at a molar ratio of 50/50 (mol %) in 1-methoxy-2 propanol (200 parts by mass), and AIBN (5 mol %) was added thereto as an initiator to prepare a monomer solution. 1-methoxy-2-propanol (100 parts by mass) was placed in a reaction vessel, and the reaction vessel was purged with nitrogen for 30 minutes. Then, the temperature inside the reaction vessel was adjusted to 80° C., and the monomer solution was added dropwise thereto over 3 hours with stirring. A polymerization reaction was performed for 6 hours with the start of the dropwise addition regarded as the start time of the polymerization reaction. After the completion of the polymerization reaction, the polymerization solution was cooled with water to 30° C. or lower. The cooled polymerization solution was poured into hexane (2,000 parts by mass), and a precipitated white powder was collected by filtration. The white powder separated by filtration was washed with hexane twice, then separated by filtration, and dissolved in 1-methoxy-2-propanol (300 parts by mass). Next, methanol (500 parts by mass), triethylamine (50 parts by mass) and ultrapure water (10 parts by mass) were added, and a hydrolysis reaction was performed at 70° C. for 6 hours with stirring. After the completion of the reaction, the remaining solvent was distilled off. The resulting solid was dissolved in acetone (100 parts by mass), and the solution was added dropwise to water (500 parts by mass) to solidify a resin. The resulting solid was separated by filtration, and dried at 50° C. for 13 hours to obtain a white powdery resin (A-12) (yield: 81%). The resin (A-12) had an Mw of 5,500 and an Mw/Mn of 1.62. As a result of ¹³C-NMR analysis, the contents by percent of the structural units derived from (M-1) and (M-18) were respectively 50.2 mol % and 49.8 mol %.

### Synthesis Examples 13 to 15

### Synthesis of Resins (A-13) to (A-15)

Resins (A-13) to (A-15) were synthesized in the same manner as in Synthesis Example 12 except that monomers of types and blending ratios shown in the following Table 2 were used. In the monomers that afford the structural unit (IV), all the alkali-dissociable groups had been hydrolyzed to phenolic hydroxyl groups. The content by percent (mol %) of each of the structural units and the physical property values (Mw and Mw/Mn) of the resins obtained are shown together in Table 2.

TABLE 2

| | | Monomer that gives structural | | | Monomer that gives structural | | | Monomer that gives structural | | | | |
|---|---|---|---|---|---|---|---|---|---|---|---|---|
| | | unit (I) | | | unit (III) | | | unit (IV) | | | | |
| | | | | Content by | | | Content by | | | Content by | | |
| | | | | percent of | | | percent of | | | percent of | | |
| | | | Blending | structural | | Blending | structural | | Blending | structural | | |
| | Resin | | ratio | unit | | ratio | unit | | ratio | unit | | |
| | [A] | Type | (mol %) | (mol %) | Type | (mol %) | (mol %) | Type | (mol %) | (mol %) | Mw | Mw/Mn |
| Synthesis | A-12 | M-1 | 50 | 50.2 | — | — | — | M-18 | 50 | 49.8 | 5500 | 1.62 |
| Example 12 | | | | | | | | | | | | |
| Synthesis | A-13 | M-3 | 50 | 46.6 | M-14 | 10 | 11.1 | M-19 | 40 | 42.3 | 5600 | 1.55 |
| Example 13 | | | | | | | | | | | | |
| Synthesis | A-14 | M-2 | 50 | 48.1 | M-17 | 20 | 21.3 | M-18 | 30 | 30.6 | 5100 | 1.59 |
| Example 14 | | | | | | | | | | | | |
| Synthesis | A-15 | M-1 | 55 | 55.7 | M-17 | 15 | 15.1 | M-19 | 30 | 29.2 | 6100 | 1.50 |
| Example 15 | | | | | | | | | | | | |

### Synthesis Example 16

### Synthesis of High Fluorine-Containing Resin (F-1)

Monomers (M-1) and (M-20) were dissolved at a molar ratio of 20/80 (mol %) in 2-butanone (200 parts by mass), and AIBN (4 mol %) was added thereto as an initiator to prepare a monomer solution. 2-butanone (100 parts by mass) was placed in a reaction vessel, and the reaction vessel was purged with nitrogen for 30 minutes. Then, the temperature inside the reaction vessel was adjusted to 80° C., and the monomer solution was added dropwise thereto over 3 hours with stirring. A polymerization reaction was performed for 6 hours with the start of the dropwise addition regarded as the start time of the polymerization reaction. After the completion of the polymerization reaction, the polymerization solution was cooled with water to 30° C. or lower. The solvent was replaced with acetonitrile (400 parts by mass). Hexane (100 parts by mass) was then added, followed by stirring, and an acetonitrile layer was collected. The operation was repeated three times. By replacing the solvent with propylene glycol monomethyl ether acetate, a solution of a high fluorine-containing resin (F-1) was obtained (yield: 75%). The high fluorine-containing resin (F-1) had an Mw of 6, 200 and an Mw/Mn of 1.77. As a result of ¹³C-NMR analysis, the contents by percent of the structural units derived from (M-1) and (M-20) were respectively 19.5 mol % and 80.5 mol %.

### Synthesis Examples 17 to 20

### Synthesis of High Fluorine-Containing Resins (F-2) to (F-5)

High fluorine-containing resins (F-2) to (F-5) were synthesized in the same manner as in Synthesis Example 16 except that monomers of types and blending ratios shown in Table 3 were used. The content by percent (mol %) and physical property values (Mw and Mw/Mn) of each of the structural units of the resulting high fluorine-containing resins are also shown in Table 3.

TABLE 3

| | | Monomer that gives | | | Monomer that gives | | | |
|---|---|---|---|---|---|---|---|---|
| | | structural unit (V) or (VI) | | | structural unit (I) | | | |
| | | | | Content by | | | Content by | |
| | High | | | percent of | | | percent of | |
| | fluorine- | | Blending | structural | | Blending | structural | Monomer that gives |
| | content | | ratio | unit | | ratio | unit | structural unit (III) |
| | resin [F] | Type | (mol %) | (mol %) | Type | (mol %) | (mol %) | Type |
| Synthesis | F-1 | M-20 | 80 | 80.5 | M-1 | 20 | 19.5 | — |
| Example | | | | | | | | |
| 16 | | | | | | | | |
| Synthesis | F-2 | M-21 | 80 | 80.2 | M-1 | 20 | 19.8 | — |
| Example | | | | | | | | |
| 17 | | | | | | | | |
| Synthesis | F-3 | M-22 | 60 | 62.3 | — | — | — | — |
| Example | | | | | | | | |
| 18 | | | | | | | | |
| Synthesis | F-4 | M-22 | 60 | 60.2 | M-2 | 20 | 19.4 | M-14 |
| Example | | | | | | | | |
| 19 | | | | | | | | |
| Synthesis | F-5 | M-20 | 60 | 60.0 | M-3 | 10 | 10.1 | M-17 |
| Example | | | | | | | | |
| 20 | | | | | | | | |

| | | Monomer that gives | | Monomer that gives | | | | |
|---|---|---|---|---|---|---|---|---|
| | | structural unit (III) | | other structural unit | | | | |
| | | | Content by | | | Content by | | |
| | High | | percent of | | | percent of | | |
| | fluorine- | Blending | structural | | Blending | structural | | |
| | content | ratio | unit | | ratio | unit | | Mw/ |
| | resin [F] | (mol %) | (mol %) | Type | (mol %) | (mol %) | Mw | Mn |
| Synthesis | F-1 | — | — | — | — | — | 6200 | 1.77 |
| Example | | | | | | | | |
| 16 | | | | | | | | |
| Synthesis | F-2 | — | — | — | — | — | 7100 | 1.82 |
| Example | | | | | | | | |
| 17 | | | | | | | | |
| Synthesis | F-3 | — | — | M-16 | 40 | 38.7 | 6900 | 1.91 |
| Example | | | | | | | | |
| 18 | | | | | | | | |
| Synthesis | F-4 | 20 | 20.4 | — | — | — | 7300 | 1.88 |
| Example | | | | | | | | |
| 19 | | | | | | | | |
| Synthesis | F-5 | 30 | 29.9 | — | — | — | 6700 | 1.87 |
| Example | | | | | | | | |
| 20 | | | | | | | | |

### Synthesis of First Onium Salt Compound B

### Synthesis Example 21

### Synthesis of Compound (B-1)

A compound (B-1) was synthesized according to the following synthesis scheme.

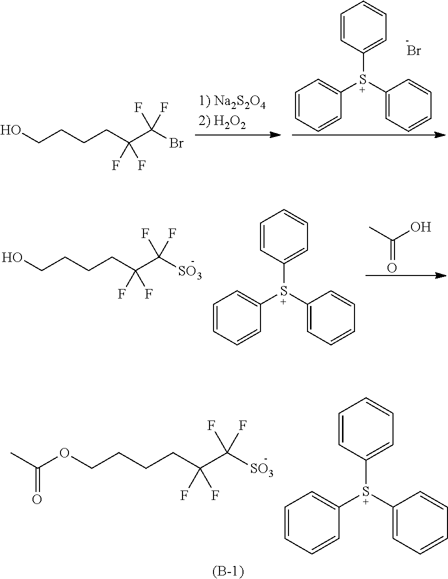

In a reaction vessel, a mixed solution of acetonitrile and water (1:1 (mass ratio)) was added to 20.0 mmol of 6-bromo-5,5,6,6-tetrafluorohexan-1-ol to form a 1 M solution. Then, 40.0 mmol of sodium dithionite and 60.0 mmol of sodium hydrogen carbonate were added, and the resulting mixture was reacted at 70° C. for 4 hours. After extraction with acetonitrile and distillation of the solvent, a mixed solution of acetonitrile and water (3:1 (mass ratio)) was added to form a 0.5 M solution. 60.0 mmol of hydrogen peroxide water and 2.00 mmol of sodium tungstate were added, and the mixture was heated and stirred at 50° C. for 12 hours. The mixture was extracted with acetonitrile, and the solvent was distilled off, affording a sodium sulfonate salt compound. 20.0 mmol of triphenylsulfonium bromide was added to the sodium sulfonate salt compound, and a mixed solution of water and dichloromethane (1:3 (mass ratio)) was added to form a 0.5 M solution. The solution was vigorously stirred at room temperature for 3 hours. Thereafter, dichloromethane was added thereto, followed by extraction, and then the organic layer was separated. After drying the resulting organic layer over sodium sulfate, a solvent was distilled off, and purification was performed by column chromatography, affording an onium salt form in good yield.

To the onium salt form were added 20.0 mmol of acetic acid, 30.0 mmol of dicyclohexylcarbodiimide, and 50 g of methylene chloride, followed by stirring at room temperature for 3 hours. Thereafter, the reaction product was diluted by adding water, and methylene chloride was then added thereto to perform extraction, thereby separating an organic layer. The resulting organic layer was washed with a saturated aqueous solution of sodium chloride and then with water. After drying over sodium sulfate, a solvent was distilled off, and purification was performed by column chromatography to obtain a compound (B-1) represented by the formula (B-1) in a good yield.

### Synthesis Examples 22 to 35

### Synthesis of Compounds (B-2) to (B-15)

First onium salt compounds represented by the formulas (B-2) to (B-15) were synthesized in the same manner as in Synthesis Example 21 except that the raw materials and the precursor were appropriately changed.

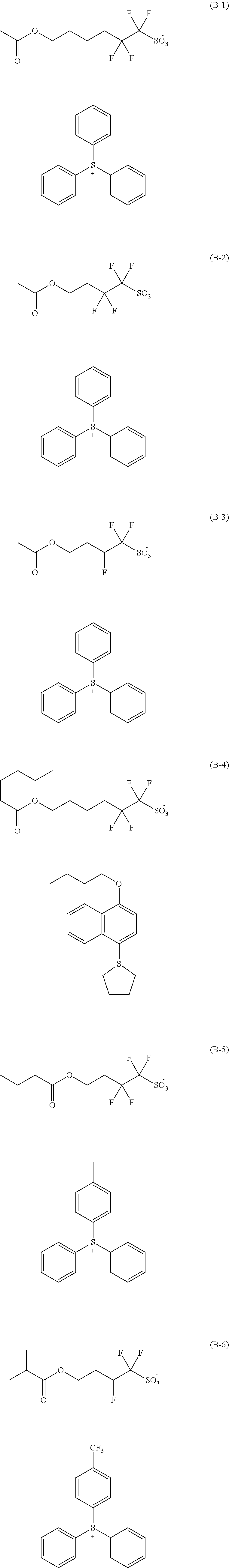

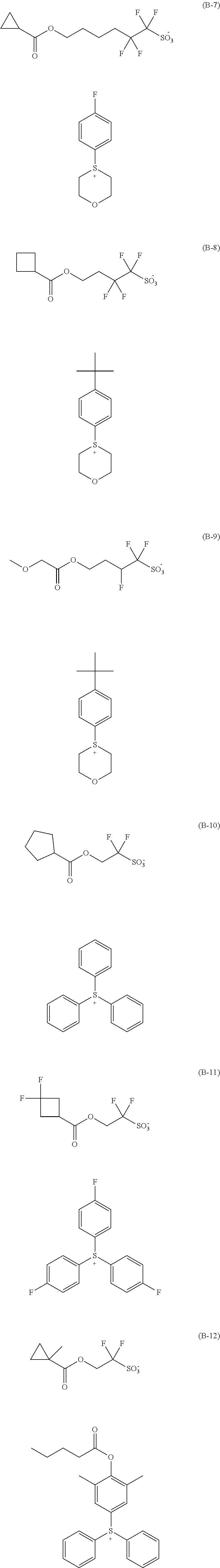

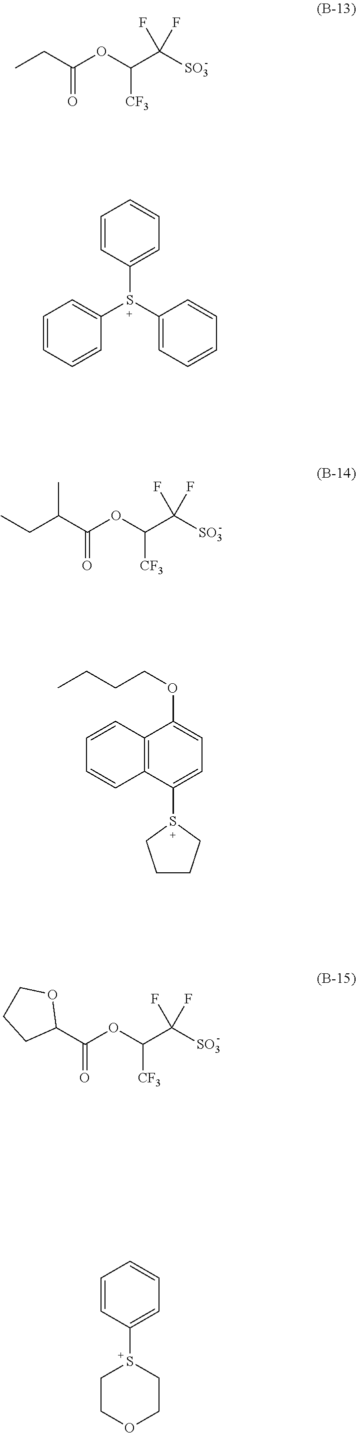

The following compounds were used as components other than the synthesized components.

### [Second Onium Salt Compounds (C-1) to (C-12)]

C-1 to C-12: Compounds represented by the formulas (C-1) to (C-12) (hereinafter, the compounds represented by the formulas (C-1) to (C-12) may be described as “compound (C-1)” to “compound (C-12)”, respectively).

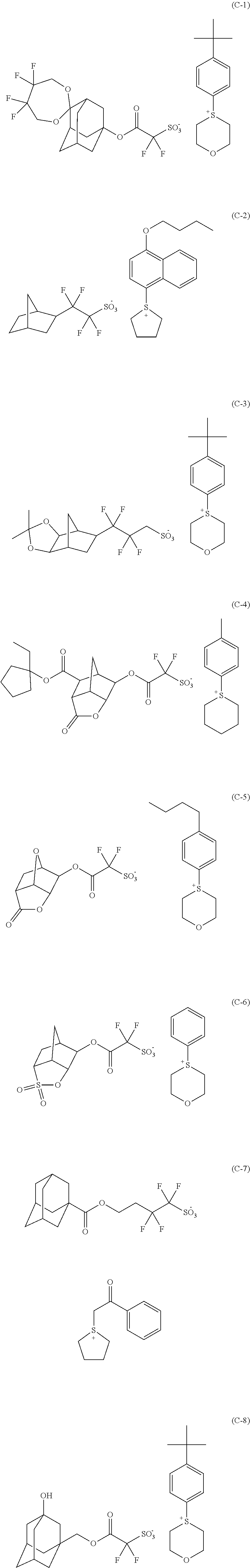

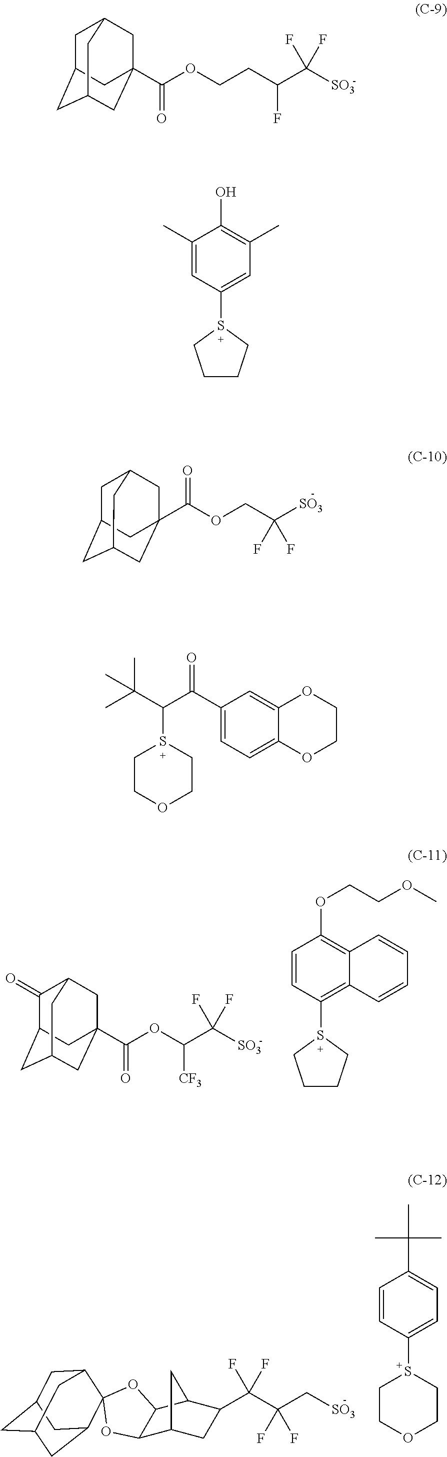

[Onium Salt Compounds Other than First Onium Salt Compounds (B-1) to (B-15) and Second Onium Salt Compounds (C-1) to (C-12)]

b-1 to b-7: Compounds represented by the formulas (b-1) to (b-7) (hereinafter, the compounds represented by the formulas (b-1) to (b-7) may be described as “compound (b-1)” to “compound (b-7)”, respectively).

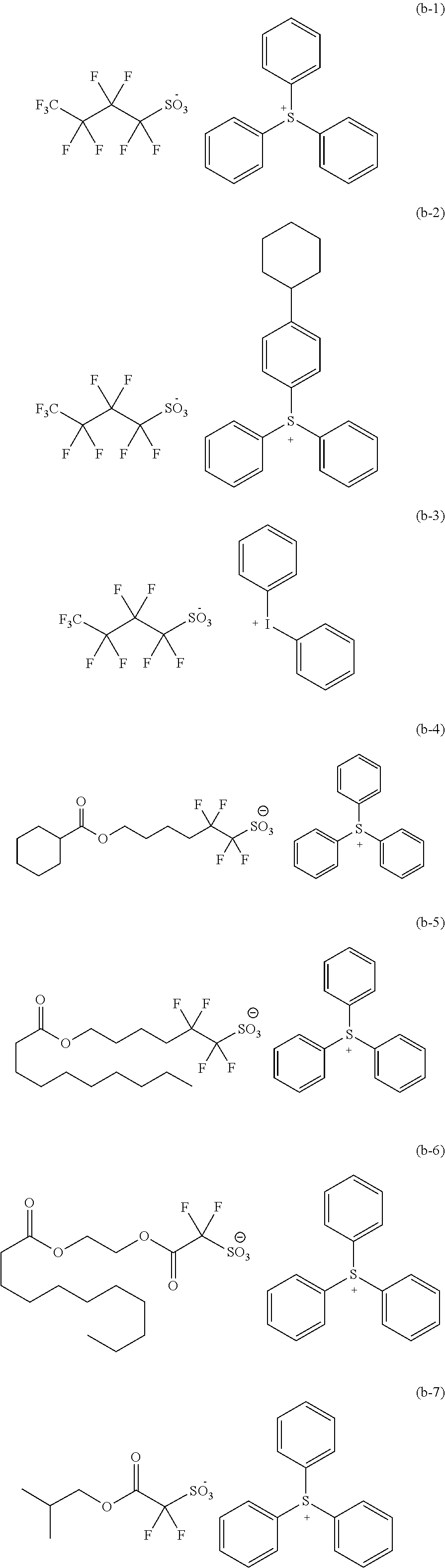

### [Acid Diffusion Controlling Agent [D]]

D-1 to D-7: Compounds represented by the formulas (D-1) to (D-7)

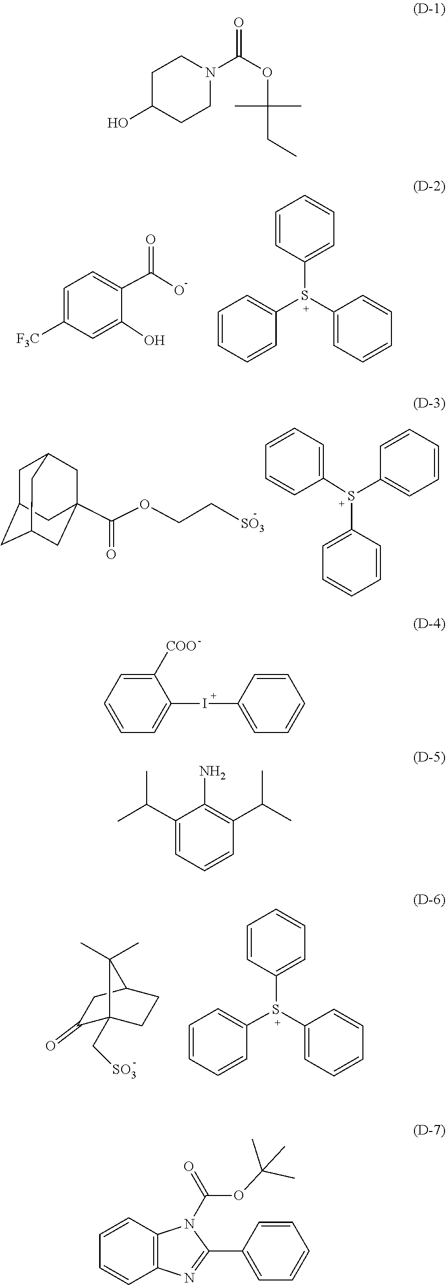

[Solvent [E]]

E-1: propylene glycol monomethyl ether acetate
E-2: Propylene glycol monomethyl ether
E-3: γ-butyrolactone
E-4: ethyl lactate

### Preparation of Positive Radiation-Sensitive Resin Composition for ArF Immersion Exposure

### Example 1

100 parts by mass of (A-1) as the resin [A], 6.0 parts by mass of (B-1) as the first onium salt compound [B], 6.0 parts by mass of (C-1) as the second onium salt compound [C], 6.0 parts by mass of (D-1) as the acid diffusion controlling agent [D], 3.0 parts by mass (solid content) of (F-1) as the high fluorine-content resin [F], and 3,230 parts by mass of a mixed solvent of (E-1)/(E-2)/(E-3) as the solvent [E] were mixed, and the mixture was filtered through a membrane filter having a pore size of 0.2 μm to prepare a radiation-sensitive resin composition (J-1).

### Examples 2 to 47 and Comparative Examples 1 to 11

Radiation-sensitive resin compositions (J-2) to (J-47) and (CJ-1) and (CJ-11) were prepared in the same manner as in Example 1 except that the components of the types and the contents shown in Tables 4-1 and 4-2 were used.

TABLE 4-1

| | | | | | | Second onium | | Acid diffusion | | | | | |
|---|---|---|---|---|---|---|---|---|---|---|---|---|---|
| | Radiation- | | | First onium salt | | salt compound | | controlling agent | | High fluorine- | | | |
| | sensitive | Resin [A] | | compound [B] | | [C] | | [D] | | content resin [F] | | Solvent [E] | |
| | resin | | Content | | Content | | Content | | Content | | Content | | Content |
| | composi- | | (parts by | | (parts by | | (parts by | | (parts by | | (parts by | | (parts by |
| | tion | Type | mass) | Type | mass) | Type | mass) | Type | mass) | Type | mass) | Type | mass) |
| Example 1 | J-1 | A-1 | 100 | B-1 | 6.0 | C-1 | 6.0 | D-1 | 6.0 | F-1 | 3.0 | E-1/E-2/E-3 | 2240/960/30 |
| Example 2 | J-2 | A-2 | 100 | B-1 | 6.0 | C-1 | 6.0 | D-1 | 6.0 | F-1 | 3.0 | E-1/E-2/E-3 | 2240/960/30 |
| Example 3 | J-3 | A-3 | 100 | B-1 | 6.0 | C-1 | 6.0 | D-1 | 6.0 | F-1 | 3.0 | E-1/E-2/E-3 | 2240/960/30 |
| Example 4 | J-4 | A-4 | 100 | B-1 | 6.0 | C-1 | 6.0 | D-1 | 6.0 | F-1 | 3.0 | E-1/E-2/E-3 | 2240/960/30 |
| Example 5 | J-5 | A-5 | 100 | B-1 | 6.0 | C-1 | 6.0 | D-1 | 6.0 | F-1 | 3.0 | E-1/E-2/E-3 | 2240/960/30 |
| Example 6 | J-6 | A-6 | 100 | B-1 | 6.0 | C-1 | 6.0 | D-1 | 6.0 | F-1 | 3.0 | E-1/E-2/E-3 | 2240/960/30 |
| Example 7 | J-7 | A-7 | 100 | B-1 | 6.0 | C-1 | 6.0 | D-1 | 6.0 | F-1 | 3.0 | E-1/E-2/E-3 | 2240/960/30 |
| Example 8 | J-8 | A-8 | 100 | B-1 | 6.0 | C-1 | 6.0 | D-1 | 6.0 | F-1 | 3.0 | E-1/E-2/E-3 | 2240/960/30 |
| Example 9 | J-9 | A-9 | 100 | B-1 | 6.0 | C-1 | 6.0 | D-1 | 6.0 | F-1 | 3.0 | E-1/E-2/E-3 | 2240/960/30 |
| Example 10 | J-10 | A-10 | 100 | B-1 | 6.0 | C-1 | 6.0 | D-1 | 6.0 | F-1 | 3.0 | E-1/E-2/E-3 | 2240/960/30 |
| Example 11 | J-11 | A-11 | 100 | B-1 | 6.0 | C-1 | 6.0 | D-1 | 6.0 | F-1 | 3.0 | E-1/E-2/E-3 | 2240/960/30 |
| Example 12 | J-12 | A-1 | 100 | B-1 | 6.0 | C-1 | 6.0 | D-2 | 6.0 | F-1 | 3.0 | E-1/E-2/E-3 | 2240/960/30 |
| Example 13 | J-13 | A-1 | 100 | B-1 | 6.0 | C-1 | 6.0 | D-3 | 6.0 | F-1 | 3.0 | E-1/E-2/E-3 | 2240/960/30 |
| Example 14 | J-14 | A-1 | 100 | B-1 | 6.0 | C-1 | 6.0 | D-4 | 6.0 | F-1 | 3.0 | E-1/E-2/E-3 | 2240/960/30 |
| Example 15 | J-15 | A-1 | 100 | B-1 | 6.0 | C-1 | 6.0 | D-5 | 6.0 | F-1 | 3.0 | E-1/E-2/E-3 | 2240/960/30 |
| Example 16 | J-16 | A-1 | 100 | B-1 | 6.0 | C-1 | 6.0 | D-6 | 6.0 | F-1 | 3.0 | E-1/E-2/E-3 | 2240/960/30 |
| Example 17 | J-17 | A-1 | 100 | B-1 | 6.0 | C-1 | 6.0 | D-7 | 6.0 | F-1 | 3.0 | E-1/E-2/E-3 | 2240/960/30 |
| Example 18 | J-18 | A-1 | 100 | B-2 | 6.0 | C-1 | 6.0 | D-1 | 6.0 | F-1 | 3.0 | E-1/E-2/E-3 | 2240/960/30 |
| Example 19 | J-19 | A-1 | 100 | B-3 | 6.0 | C-1 | 6.0 | D-1 | 6.0 | F-1 | 3.0 | E-1/E-2/E-3 | 2240/960/30 |
| Example 20 | J-20 | A-1 | 100 | B-4 | 6.0 | C-1 | 6.0 | D-1 | 6.0 | F-1 | 3.0 | E-1/E-2/E-3 | 2240/960/30 |
| Example 21 | J-21 | A-1 | 100 | B-5 | 6.0 | C-1 | 6.0 | D-1 | 6.0 | F-1 | 3.0 | E-1/E-2/E-3 | 2240/960/30 |
| Example 22 | J-22 | A-1 | 100 | B-6 | 6.0 | C-1 | 6.0 | D-1 | 6.0 | F-1 | 3.0 | E-1/E-2/E-3 | 2240/960/30 |
| Example 23 | J-23 | A-1 | 100 | B-7 | 6.0 | C-1 | 6.0 | D-1 | 6.0 | F-1 | 3.0 | E-1/E-2/E-3 | 2240/960/30 |
| Example 24 | J-24 | A-1 | 100 | B-8 | 6.0 | C-1 | 6.0 | D-1 | 6.0 | F-1 | 3.0 | E-1/E-2/E-3 | 2240/960/30 |
| Example 25 | J-25 | A-1 | 100 | B-9 | 6.0 | C-1 | 6.0 | D-1 | 6.0 | F-1 | 3.0 | E-1/E-2/E-3 | 2240/960/30 |
| Example 26 | J-26 | A-1 | 100 | B-10 | 6.0 | C-1 | 6.0 | D-1 | 6.0 | F-1 | 3.0 | E-1/E-2/E-3 | 2240/960/30 |
| Example 27 | J-27 | A-1 | 100 | B-11 | 6.0 | C-1 | 6.0 | D-1 | 6.0 | F-2 | 3.0 | E-1/E-2/E-3 | 2240/960/30 |
| Example 28 | J-28 | A-1 | 100 | B-12 | 6.0 | C-1 | 6.0 | D-1 | 6.0 | F-3 | 3.0 | E-1/E-2/E-3 | 2240/960/30 |
| Example 29 | J-29 | A-1 | 100 | B-13 | 6.0 | C-1 | 6.0 | D-1 | 6.0 | F-4 | 3.0 | E-1/E-2/E-3 | 2240/960/30 |
| Example 30 | J-30 | A-1 | 100 | B-14 | 6.0 | C-1 | 6.0 | D-1 | 6.0 | F-5 | 3.0 | E-1/E-2/E-3 | 2240/960/30 |
| Example 31 | J-31 | A-1 | 100 | B-15 | 6.0 | C-1 | 6.0 | D-1 | 6.0 | F-3 | 3.0 | E-1/E-2/E-3 | 2240/960/30 |
| Example 32 | J-32 | A-1 | 100 | B-1 | 6.0 | C-2 | 6.0 | D-1 | 6.0 | F-1 | 3.0 | E-1/E-2/E-3 | 2240/960/30 |
| Example 33 | J-33 | A-1 | 100 | B-1 | 6.0 | C-3 | 6.0 | D-1 | 6.0 | F-1 | 3.0 | E-1/E-2/E-3 | 2240/960/30 |
| Example 34 | J-34 | A-1 | 100 | B-1 | 6.0 | C-4 | 6.0 | D-1 | 6.0 | F-1 | 3.0 | E-1/E-2/E-3 | 2240/960/30 |
| Example 35 | J-35 | A-1 | 100 | B-1 | 6.0 | C-5 | 6.0 | D-1 | 6.0 | F-1 | 3.0 | E-1/E-2/E-3 | 2240/960/30 |
| Example 36 | J-36 | A-1 | 100 | B-1 | 6.0 | C-6 | 6.0 | D-1 | 6.0 | F-1 | 3.0 | E-1/E-2/E-3 | 2240/960/30 |
| Example 37 | J-37 | A-1 | 100 | B-1 | 6.0 | C-7 | 6.0 | D-1 | 6.0 | F-1 | 3.0 | E-1/E-2/E-3 | 2240/960/30 |
| Example 38 | J-38 | A-1 | 100 | B-1 | 6.0 | C-8 | 6.0 | D-1 | 6.0 | F-1 | 3.0 | E-1/E-2/E-3 | 2240/960/30 |
| Example 39 | J-39 | A-1 | 100 | B-1 | 6.0 | C-9 | 6.0 | D-1 | 6.0 | F-1 | 3.0 | E-1/E-2/E-3 | 2240/960/30 |
| Example 40 | J-40 | A-1 | 100 | B-1 | 6.0 | C-10 | 6.0 | D-1 | 6.0 | F-1 | 3.0 | E-1/E-2/E-3 | 2240/960/30 |
| Example 41 | J-41 | A-1 | 100 | B-1 | 6.0 | C-11 | 6.0 | D-1 | 6.0 | F-1 | 3.0 | E-1/E-2/E-3 | 2240/960/30 |
| Example 42 | J-42 | A-1 | 100 | B-1 | 6.0 | C-12 | 6.0 | D-1 | 6.0 | F-1 | 3.0 | E-1/E-2/E-3 | 2240/960/30 |
| Example 43 | J-43 | A-1 | 100 | B-1 | 3.0 | C-1 | 9.0 | D-1 | 6.0 | F-1 | 3.0 | E-1/E-2/E-3 | 2240/960/30 |
| Example 44 | J-44 | A-1 | 100 | B-1 | 9.0 | C-1 | 3.0 | D-1 | 6.0 | F-1 | 3.0 | E-1/E-2/E-3 | 2240/960/30 |
| Example 45 | J-45 | A-1 | 100 | B-1 | 6.0 | C-1 | 6.0 | D-1 | 6.0 | F-2 | 3.0 | E-1/E-2/E-3 | 2240/960/30 |
| Example 46 | J-46 | A-1 | 100 | B-1 | 6.0 | C-1 | 6.0 | D-1 | 6.0 | F-3 | 3.0 | E-1/E-2/E-3 | 2240/960/30 |
| Example 47 | J-47 | A-1 | 100 | B-1 | 6.0 | C-1 | 6.0 | D-1 | 6.0 | F-4 | 3.0 | E-1/E-2/E-3 | 2240/960/30 |

TABLE 4-2

| | | | | | | Second onium | | Acid diffusion | | High fluorine- | | | |
|---|---|---|---|---|---|---|---|---|---|---|---|---|---|
| | | | | First onium salt | | salt compound | | controlling agent | | content resin | | | |
| | Radiation- | Resin [A] | | compound [B] | | [C] | | [D] | | [F] | | Solvent [E] | |
| | sensitive | | Content | | Content | | Content | | Content | | Content | | Content |
| | resin | | (parts | | (parts | | (parts | | (parts | | (parts | | (parts |
| | composi- | | by | | by | | by | | by | | by | | by |
| | tion | Type | mass) | Type | mass) | Type | mass) | Type | mass) | Type | mass) | Type | mass) |
| Comparative | CJ-1 | A-1 | 100 | b-1 | 6.0 | C-1 | 6.0 | D-1 | 6.0 | F-1 | 3.0 | E-1/E-2/E-3 | 2240/960/30 |
| Example 1 | | | | | | | | | | | | | |
| Comparative | CJ-2 | A-1 | 100 | b-2 | 6.0 | C-1 | 6.0 | D-1 | 6.0 | F-1 | 3.0 | E-1/E-2/E-3 | 2240/960/30 |
| Example 2 | | | | | | | | | | | | | |
| Comparative | CJ-3 | A-1 | 100 | b-3 | 6.0 | C-1 | 6.0 | D-1 | 6.0 | F-1 | 3.0 | E-1/E-2/E-3 | 2240/960/30 |
| Example 3 | | | | | | | | | | | | | |
| Comparative | CJ-4 | A-1 | 100 | b-5 | 6.0 | C-1 | 6.0 | D-1 | 6.0 | F-1 | 3.0 | E-1/E-2/E-3 | 2240/960/30 |
| Example 4 | | | | | | | | | | | | | |
| Comparative | CJ-5 | A-1 | 100 | b-6 | 6.0 | C-1 | 6.0 | D-1 | 6.0 | F-1 | 3.0 | E-1/E-2/E-3 | 2240/960/30 |
| Example 5 | | | | | | | | | | | | | |
| Comparative | CJ-6 | A-1 | 100 | b-7 | 6.0 | C-1 | 6.0 | D-1 | 6.0 | F-1 | 3.0 | E-1/E-2/E-3 | 2240/960/30 |
| Example 6 | | | | | | | | | | | | | |
| Comparative | CJ-7 | A-1 | 100 | B-1 | 6.0 | b-4 | 6.0 | D-1 | 6.0 | F-1 | 3.0 | E-1/E-2/E-3 | 2240/960/30 |
| Example 7 | | | | | | | | | | | | | |
| Comparative | CJ-8 | A-1 | 100 | B-1 | 12.0 | — | — | D-1 | 6.0 | F-1 | 3.0 | E-1/E-2/E-3 | 2240/960/30 |
| Example 8 | | | | | | | | | | | | | |
| Comparative | CJ-9 | A-1 | 100 | — | — | C-1 | 12.0 | D-1 | 6.0 | F-1 | 3.0 | E-1/E-2/E-3 | 2240/960/30 |
| Example 9 | | | | | | | | | | | | | |
| Comparative | CJ-10 | A-1 | 100 | B-1/B-10 | 6.0/6.0 | — | — | D-1 | 6.0 | F-1 | 3.0 | E-1/E-2/E-3 | 2240/960/30 |
| Example 10 | | | | | | | | | | | | | |
| Comparative | CJ-11 | A-1 | 100 | — | — | C-1/C-7 | 6.0/6.0 | D-1 | 6.0 | F-1 | 3.0 | E-1/E-2/E-3 | 2240/960/30 |
| Example 11 | | | | | | | | | | | | | |

### <Formation of Resist Pattern Using Positive Radiation-Sensitive Resin Composition for ArF Immersion Exposure>

Onto the surface of a 12-inch silicon wafer, an underlayer antireflection film forming composition (“ARC66” manufactured by Brewer Science Incorporated.) was applied with use of a spin coater (“CLEAN TRACK ACT12” manufactured by Tokyo Electron Limited). The wafer was then heated at 205° C. for 60 seconds to form an underlayer antireflection film having an average thickness of 100 nm. The positive radiation-sensitive resin composition for ArF immersion exposure prepared above was applied onto the underlayer antireflection film with use of the spin coater, followed by performing PB (pre-baking) at 100° C. for 60 seconds. Thereafter, cooling was performed at 23° C. for 30 seconds to form a resist film having an average thickness of 90 nm. Next, the resist film was exposed through a 40 nm line-and-space mask pattern using an ArF excimer laser immersion exposure apparatus (“TWINSCAN XT-1900i” manufactured by ASML) with NA of 1.35 under an optical condition of Dipole (σ=0.9/0.7). After the exposure, PEB (post exposure baking) was performed at 100° C. for 60 seconds. Thereafter, the resist film was developed with an alkali with use of a 2.38% by mass aqueous TMAH solution as an alkaline developer, followed by washing with water and further drying to form a positive resist pattern (40 nm line-and-space pattern).

### <Evaluation>

The resist pattern formed using the positive radiation-sensitive resin composition for ArF immersion exposure was evaluated on sensitivity, LWR performance, DOF performance, and pattern rectangularity in accordance with the following methods. The results are shown in the following Table 5. A scanning electron microscope (“CG-5000” manufactured by Hitachi High-Tech Corporation) was used for measuring the length of the resist pattern. The results are shown in the following Tables 5-1 and 5-2.

### [Sensitivity]

An exposure dose at which a 40 nm line-and-space pattern was formed in the aforementioned resist pattern formation using each of the positive radiation-sensitive resin compositions for ArF immersion exposure was defined as an optimum exposure dose, and this optimum exposure dose was defined as sensitivity (mJ/cm²). The sensitivity was evaluated to be “good” in a case of being 30 mJ/cm² or less, and “poor” in a case of exceeding 30 mJ/cm².

### [LWR Performance]

A 40 nm line-and-space resist pattern was formed by irradiation with the optimum exposure dose obtained in the evaluation of the sensitivity. The formed resist pattern was observed from above the pattern with use of the scanning electron microscope. The variation in the line width was measured at a total of 500 points. The 3 sigma value was obtained from the distribution of the measurement values, and defined as LWR performance (nm). The smaller the value of the LWR is, the smaller the roughness of the line is, which is better. The LWR performance was evaluated to be “good” in a case of being 2.5 nm or less, and “poor” in a case of exceeding 2.5 nm.

### [DOF Performance]

In accordance with the method described in the “Measurement of sensitivity”, the range of depth of focus (DOF) in which the line width of the line and space pattern formed as described above was 30 nm or more and 50 nm or less was measured using a mask having dimensions such that the line width of the line and space pattern (1LIS) to be formed was 40 nm. The DOF performance was evaluated to be “good” in a case of being 150 nm or more, and “poor” in a case of being less than 150 nm.

### [Pattern Rectangularity]

The 40 nm line-and-space resist pattern formed by irradiation with the optimum exposure amount obtained in the evaluation of the sensitivity was observed using the scanning electron microscope, and the sectional shape of the line-and-space pattern was evaluated. The rectangularity of the resist pattern was evaluated as “A” (extremely good) when the ratio of the length of the lower side to the length of the upper side in the sectional shape was 1 or more and 1.05 or less, “B” (good) when the ratio was more than 1.05 and 1.10 or less, and “C” (poor) when the ratio was more than 1.10.

TABLE 5-1

| | Radiation- | | | | |
|---|---|---|---|---|---|
| | sensitive | | | | |
| | resin | Sensitivity | LWR | DOF | Pattern |
| | composition | (mJ/cm²) | (nm) | (nm) | rectangularity |
| Example 1 | J-1 | 25 | 2.0 | 180 | A |
| Example 2 | J-2 | 24 | 2.3 | 200 | A |
| Example 3 | J-3 | 26 | 2.2 | 190 | A |
| Example 4 | J-4 | 27 | 1.8 | 180 | A |
| Example 5 | J-5 | 25 | 1.9 | 190 | A |
| Example 6 | J-6 | 25 | 2.1 | 180 | A |
| Example 7 | J-7 | 24 | 2.0 | 180 | A |
| Example 8 | J-8 | 23 | 2.2 | 170 | A |
| Example 9 | J-9 | 26 | 2.1 | 170 | A |
| Example 10 | J-10 | 25 | 1.7 | 180 | A |
| Example 11 | J-11 | 27 | 1.8 | 190 | A |
| Example 12 | J-12 | 25 | 1.9 | 180 | A |
| Example 13 | J-13 | 26 | 1.8 | 180 | A |
| Example 14 | J-14 | 24 | 2.0 | 200 | A |
| Example 15 | J-15 | 27 | 2.1 | 180 | A |
| Example 16 | J-16 | 28 | 2.1 | 200 | A |
| Example 17 | J-17 | 24 | 2.2 | 180 | A |
| Example 18 | J-18 | 24 | 2.1 | 180 | A |
| Example 19 | J-19 | 26 | 1.8 | 170 | A |
| Example 20 | J-20 | 27 | 1.8 | 170 | A |
| Example 21 | J-21 | 25 | 2.1 | 180 | A |
| Example 22 | J-22 | 28 | 2.0 | 180 | A |
| Example 23 | J-23 | 25 | 2.3 | 200 | A |
| Example 24 | J-24 | 24 | 2.1 | 210 | A |
| Example 25 | J-25 | 25 | 2.3 | 200 | A |
| Example 26 | J-26 | 27 | 1.8 | 190 | A |
| Example 27 | J-27 | 23 | 1.8 | 180 | A |
| Example 28 | J-28 | 22 | 1.9 | 190 | A |
| Example 29 | J-29 | 25 | 2.0 | 180 | A |
| Example 30 | J-30 | 26 | 2.1 | 200 | A |
| Example 31 | J-31 | 24 | 2.2 | 200 | A |
| Example 32 | J-32 | 25 | 2.1 | 180 | A |
| Example 33 | J-33 | 26 | 2.0 | 180 | A |
| Example 34 | J-34 | 27 | 2.2 | 200 | A |
| Example 35 | J-35 | 24 | 1.8 | 170 | A |
| Example 36 | J-36 | 24 | 1.8 | 170 | A |
| Example 37 | J-37 | 23 | 1.9 | 180 | A |
| Example 38 | J-38 | 28 | 2.0 | 180 | A |
| Example 39 | J-39 | 22 | 2.1 | 200 | A |
| Example 40 | J-40 | 22 | 2.2 | 180 | A |
| Example 41 | J-41 | 25 | 2.3 | 180 | A |
| Example 42 | J-42 | 26 | 2.1 | 180 | A |
| Example 43 | J-43 | 28 | 1.8 | 170 | A |
| Example 44 | J-44 | 23 | 2.2 | 200 | A |
| Example 45 | J-45 | 25 | 2.5 | 180 | A |
| Example 46 | J-46 | 25 | 2.5 | 180 | A |
| Example 47 | J-47 | 24 | 2.5 | 180 | A |

TABLE 5-2

| | Radiation- | | | | |
|---|---|---|---|---|---|
| | sensitive | | | | |
| | resin | Sensitivity | LWR | DOF | Pattern |
| | composition | (mJ/cm²) | (nm) | (nm) | rectangularity |
| Comparative | CJ-1 | 32 | 3.0 | 60 | C |
| Example 1 | | | | | |
| Comparative | CJ-2 | 33 | 3.1 | 50 | C |
| Example 2 | | | | | |
| Comparative | CJ-3 | 33 | 3.2 | 80 | C |
| Example 3 | | | | | |
| Comparative | CJ-4 | 36 | 3.1 | 100 | C |
| Example 4 | | | | | |
| Comparative | CJ-5 | 35 | 3.3 | 110 | C |
| Example 5 | | | | | |
| Comparative | CJ-6 | 33 | 3.0 | 80 | C |
| Example 6 | | | | | |
| Comparative | CJ-7 | 35 | 3.0 | 70 | B |
| Example 7 | | | | | |
| Comparative | CJ-8 | 31 | 2.8 | 120 | C |
| Example 8 | | | | | |
| Comparative | CJ-9 | 40 | 3.2 | 90 | B |
| Example 9 | | | | | |
| Comparative | CJ-10 | 32 | 2.7 | 120 | C |
| Example 10 | | | | | |
| Comparative | CJ-11 | 42 | 3.1 | 80 | B |
| Example 11 | | | | | |

As is apparent from the results in Tables 5-1 and 5-2, the radiation-sensitive resin compositions of Examples were good in sensitivity, LWR performance, DOF performance, and pattern rectangularity when used for ArF immersion exposure, whereas the radiation-sensitive resin compositions of Comparative Examples were inferior in the characteristics to those of Examples. Therefore, when the radiation-sensitive resin compositions of Examples are used for ArF immersion exposure, resist patterns having good LWR performance, DOF performance, and pattern rectangularity can be formed with high sensitivity.

### Preparation of Positive Radiation-Sensitive Resin Composition for ArF-Dry Exposure

### Example 48

100 parts by mass of (A-1) as the resin [A], 6.0 parts by mass of (B-1) as the first onium salt compound [B], 6.0 parts by mass of (C-1) as the second onium salt compound [C], 6.0 parts by mass of (D-1) as the acid diffusion controlling agent [D], and 3,230 parts by mass of a mixed solvent of (E-1)/(E-2)/(E-3) as the solvent [E] were mixed, and the mixture was filtered through a membrane filter having a pore size of 0.2 μm to prepare a radiation-sensitive resin composition (J-48).

### Examples 49 to 63 and Comparative Examples 12 to 19

Radiation-sensitive resin compositions (J-49) to (J-63) and (CJ-12) to (CJ-19) were prepared in the same manner as in Example 48 except that the components of the types and the contents shown in Table 6 were used.

TABLE 6

| | | | | | | | | Acid diffusion | | | |
|---|---|---|---|---|---|---|---|---|---|---|---|
| | | | | First onium salt | | Second onium salt | | controlling agent | | | |
| | Radiation- | Resin [A] | | compound [B] | | compound [C] | | [D] | | Solvent [E] | |
| | sensitive | | Content | | Content | | Content | | Content | | Content |
| | resin | | (parts by | | (parts by | | (parts by | | (parts by | | (parts by |
| | composition | Type | mass) | Type | mass) | Type | mass) | Type | mass) | Type | mass) |
| Example 48 | J-48 | A-1 | 100 | B-1 | 6.0 | C-1 | 6.0 | D-1 | 6.0 | E-1/E-2/E-3 | 2240/960/30 |
| Example 49 | J-49 | A-6 | 100 | B-1 | 6.0 | C-1 | 6.0 | D-1 | 6.0 | E-1/E-2/E-3 | 2240/960/30 |
| Example 50 | J-50 | A-7 | 100 | B-1 | 6.0 | C-1 | 6.0 | D-1 | 6.0 | E-1/E-2/E-3 | 2240/960/30 |
| Example 51 | J-51 | A-8 | 100 | B-1 | 6.0 | C-1 | 6.0 | D-1 | 6.0 | E-1/E-2/E-3 | 2240/960/30 |
| Example 52 | J-52 | A-1 | 100 | B-1 | 6.0 | C-1 | 6.0 | D-5 | 6.0 | E-1/E-2/E-3 | 2240/960/30 |
| Example 53 | J-53 | A-1 | 100 | B-1 | 6.0 | C-1 | 6.0 | D-6 | 6.0 | E-1/E-2/E-3 | 2240/960/30 |
| Example 54 | J-54 | A-1 | 100 | B-5 | 6.0 | C-1 | 6.0 | D-1 | 6.0 | E-1/E-2/E-3 | 2240/960/30 |
| Example 55 | J-55 | A-1 | 100 | B-8 | 6.0 | C-1 | 6.0 | D-1 | 6.0 | E-1/E-2/E-3 | 2240/960/30 |
| Example 56 | J-56 | A-1 | 100 | B-9 | 6.0 | C-1 | 6.0 | D-1 | 6.0 | E-1/E-2/E-3 | 2240/960/30 |
| Example 57 | J-57 | A-1 | 100 | B-12 | 6.0 | C-1 | 6.0 | D-1 | 6.0 | E-1/E-2/E-3 | 2240/960/30 |
| Example 58 | J-58 | A-1 | 100 | B-13 | 6.0 | C-1 | 6.0 | D-1 | 6.0 | E-1/E-2/E-3 | 2240/960/30 |
| Example 59 | J-59 | A-1 | 100 | B-1 | 6.0 | C-2 | 6.0 | D-1 | 6.0 | E-1/E-2/E-3 | 2240/960/30 |
| Example 60 | J-60 | A-1 | 100 | B-1 | 6.0 | C-5 | 6.0 | D-1 | 6.0 | E-1/E-2/E-3 | 2240/960/30 |
| Example 61 | J-61 | A-1 | 100 | B-1 | 6.0 | C-9 | 6.0 | D-1 | 6.0 | E-1/E-2/E-3 | 2240/960/30 |
| Example 62 | J-62 | A-1 | 100 | B-1 | 6.0 | C-11 | 6.0 | D-1 | 6.0 | E-1/E-2/E-3 | 2240/960/30 |
| Example 63 | J-63 | A-1 | 100 | B-1 | 6.0 | C-12 | 6.0 | D-1 | 6.0 | E-1/E-2/E-3 | 2240/960/30 |
| Comparative | CJ-12 | A-1 | 100 | b-5 | 6.0 | C-1 | 6.0 | D-1 | 6.0 | E-1/E-2/E-3 | 2240/960/30 |
| Example 12 | | | | | | | | | | | |
| Comparative | CJ-13 | A-1 | 100 | b-6 | 6.0 | C-1 | 6.0 | D-1 | 6.0 | E-1/E-2/E-3 | 2240/960/30 |
| Example 13 | | | | | | | | | | | |
| Comparative | CJ-14 | A-1 | 100 | b-7 | 6.0 | C-1 | 6.0 | D-1 | 6.0 | E-1/E-2/E-3 | 2240/960/30 |
| Example 14 | | | | | | | | | | | |
| Comparative | CJ-15 | A-1 | 100 | B-1 | 6.0 | b-4 | 6.0 | D-1 | 6.0 | E-1/E-2/E-3 | 2240/960/30 |
| Example 15 | | | | | | | | | | | |
| Comparative | CJ-16 | A-1 | 100 | B-1 | 12.0 | — | — | D-1 | 6.0 | E-1/E-2/E-3 | 2240/960/30 |
| Example 16 | | | | | | | | | | | |
| Comparative | CJ-17 | A-1 | 100 | — | — | C-1 | 12.0 | D-1 | 6.0 | E-1/E-2/E-3 | 2240/960/30 |
| Example 17 | | | | | | | | | | | |
| Comparative | CJ-18 | A-1 | 100 | B-1/B-10 | 6.0/6.0 | — | — | D-1 | 6.0 | E-1/E-2/E-3 | 2240/960/30 |
| Example 18 | | | | | | | | | | | |
| Comparative | CJ-19 | A-1 | 100 | — | — | C-1/C-10 | 6.0/6.0 | D-1 | 6.0 | E-1/E-2/E-3 | 2240/960/30 |
| Example 19 | | | | | | | | | | | |

### <Formation of Resist Pattern Using Positive Radiation-Sensitive Resin Composition for ArF-Dry Exposure>

Onto the surface of an 8-inch silicon wafer, an underlayer antireflection film forming composition (“ARC29” manufactured by Brewer Science Incorporated) was applied with use of a spin coater (“CLEAN TRACK ACT8” manufactured by Tokyo Electron Limited). The wafer was then heated at 205° C. for 60 seconds to form an underlayer antireflection film having an average thickness of 77 nm. The positive radiation-sensitive resin composition for ArF-Dry exposure prepared above was applied onto the underlayer antireflection film with use of the spin coater, followed by performing PB (pre-baking) at 100° C. for 60 seconds. Thereafter, cooling was performed at 23° C. for 30 seconds to form a resist film having an average thickness of 250 nm. Next, a resist pattern having a line-and-space of 90 nm in line width was formed on this resist film using an ArF excimer laser exposure apparatus (“S306C” manufactured by Nikon Corporation) at NA=0.75 under an optical condition of Annular (σ=0.8/0.6). After the exposure, PEB (post exposure baking) was performed at 100° C. for 60 seconds. Thereafter, the resist film was developed with an alkali with use of a 2.38% by mass aqueous TMAH solution as an alkaline developer, followed by washing with water and further drying to form a positive resist pattern (90 nm line-and -space resist pattern).

### <Evaluation>

The resist pattern formed using the positive radiation-sensitive resin composition for ArF-Dry exposure was evaluated on sensitivity, LWR performance, DOF performance, and pattern rectangularity in accordance with the following methods. The results are shown in the following Table 7. A scanning electron microscope (“S-9380” manufactured by Hitachi High-Tech Corporation) was used for measuring the length of the resist pattern.

### [Sensitivity]

An exposure dose at which a 90 nm line-and-space pattern was formed in the aforementioned resist pattern formation using each of the positive radiation-sensitive resin compositions for ArF-Dry exposure was defined as an optimum exposure dose, and this optimum exposure dose was defined as sensitivity (mJ/cm²). The sensitivity was evaluated to be “good” in a case of being 30 mJ/cm² or less, and “poor” in a case of exceeding 30 mJ/cm².

### [LWR Performance]

A 90 nm line-and-space resist pattern was formed by irradiation with the optimum exposure dose obtained in the evaluation of the sensitivity. The formed resist pattern was observed from above the pattern with use of the scanning electron microscope. The variation in the line width was measured at a total of 500 points. The 3 sigma value was obtained from the distribution of the measurement values, and defined as LWR performance (nm). The smaller the value of the LWR is, the smaller the roughness of the line is, which is better. The LWR performance was evaluated to be “good” in a case of being 4.5 nm or less, and “poor” in a case of exceeding 4.5 nm.

### [DOF Performance]

In accordance with the method described in the “Measurement of sensitivity”, the range of depth of focus (DOF) in which the line width of the line and space pattern formed as described above was 80 nm or more and 100 nm or less was measured using a mask having dimensions such that the line width of the line and space pattern (1L1S) to be formed was 90 nm. The DOF performance was evaluated to be “good” in a case of being 200 nm or more, and “poor” in a case of being less than 200 nm.

### [Pattern Rectangularity]

The 90 nm line-and-space resist pattern formed by irradiation with the optimum exposure amount obtained in the evaluation of the sensitivity was observed using the scanning electron microscope, and the sectional shape of the line-and-space pattern was evaluated. The rectangularity of the resist pattern was evaluated as “A” (extremely good) when the ratio of the length of the lower side to the length of the upper side in the sectional shape was 1 or more and 1.05 or less, “B” (good) when the ratio was more than 1.05 and 1.10 or less, and “C” (poor) when the ratio was more than 1.10.

TABLE 7

| | Radiation- | | | | |
|---|---|---|---|---|---|
| | sensitive | | | | |
| | resin | Sensitivity | LWR | DOF | Pattern |
| | composition | (mJ/cm²) | (nm) | (nm) | rectangularity |
| Example 48 | J-48 | 25 | 3.5 | 220 | A |
| Example 49 | J-49 | 26 | 3.8 | 230 | A |
| Example 50 | J-50 | 24 | 3.2 | 220 | A |
| Example 51 | J-51 | 23 | 3.7 | 220 | A |
| Example 52 | J-52 | 27 | 3.2 | 230 | A |
| Example 53 | J-53 | 27 | 3.2 | 250 | A |
| Example 54 | J-54 | 24 | 3.9 | 220 | A |
| Example 55 | J-55 | 26 | 3.6 | 230 | A |
| Example 56 | J-56 | 24 | 3.8 | 240 | A |
| Example 57 | J-57 | 23 | 3.4 | 220 | A |
| Example 58 | J-58 | 25 | 3.8 | 220 | A |
| Example 59 | J-59 | 22 | 3.9 | 230 | A |
| Example 60 | J-60 | 24 | 4.0 | 240 | A |
| Example 61 | J-61 | 26 | 3.9 | 220 | A |
| Example 62 | J-62 | 25 | 3.2 | 220 | A |
| Example 63 | J-63 | 22 | 3.5 | 230 | A |
| Comparative | CJ-12 | 33 | 4.9 | 120 | C |
| Example 12 | | | | | |
| Comparative | CJ-13 | 35 | 4.8 | 150 | C |
| Example 13 | | | | | |
| Comparative | CJ-14 | 32 | 5.0 | 180 | C |
| Example 14 | | | | | |
| Comparative | CJ-15 | 37 | 5.2 | 160 | B |
| Example 15 | | | | | |
| Comparative | CJ-16 | 32 | 4.8 | 180 | C |
| Example 16 | | | | | |
| Comparative | CJ-17 | 40 | 5.1 | 120 | B |
| Example 17 | | | | | |
| Comparative | CJ-18 | 32 | 4.7 | 180 | C |
| Example 18 | | | | | |
| Comparative | CJ-19 | 42 | 5.0 | 140 | B |
| Example 19 | | | | | |

As is apparent from the results in Table 7, the radiation-sensitive resin compositions of Examples were good in sensitivity, LWR performance, DOF performance, and pattern rectangularity when used for ArF-Dry exposure, whereas the radiation-sensitive resin compositions of Comparative Examples were inferior in the characteristics to those of Examples. Therefore, when the radiation-sensitive resin compositions of Examples are used for ArF-Dry exposure, resist patterns having good LWR performance, DOF performance, and pattern rectangularity can be formed with high sensitivity.

### Preparation of Positive Radiation-Sensitive Resin Composition for Extreme Ultraviolet (EUV) Exposure

### Example 64

100 parts by mass of (A-12) as the resin [A], 15.0 parts by mass of (B-1) as the first onium salt compound [B], 15.0 parts by mass of (C-1) as the second onium salt compound [C], 20.0 parts by mass of (D-1) as the acid diffusion controlling agent [D], 3.0 parts by mass (solid content) of (F-5) as the high fluorine-content resin [F], and 6, 110 parts by mass of a mixed solvent of (E-1)/(E-4) as the solvent [E] were mixed, and the mixture was filtered through a membrane filter having a pore size of 0.2 μm to prepare a radiation-sensitive resin composition (J-64).

### Examples 65 to 76 and Comparative Examples 20 to 25

Radiation-sensitive resin compositions (J-65) to (J-76) and (CJ-20) to (CJ-25) were prepared in the same manner as in Example 64 except that the components of the types and the contents shown in Table 8 were used.

TABLE 8

| | | | | | | | | Acid diffusion | | High fluorine- | | | |
|---|---|---|---|---|---|---|---|---|---|---|---|---|---|
| | | | | First onium salt | | Second onium salt | | controlling agent | | content resin | | | |
| | Radiation- | Resin [A] | | compound [B] | | compound [C] | | [D] | | [F] | | Solvent [E] | |
| | sensitive | | Content | | Content | | Content | | Content | | Content | | Content |
| | resin | | (parts | | (parts | | (parts | | (parts | | (parts | | (parts |
| | composi- | | by | | by | | by | | by | | by | | by |
| | tion | Type | mass) | Type | mass) | Type | mass) | Type | mass) | Type | mass) | Type | mass) |
| Example 64 | J-64 | A-12 | 100 | B-1 | 15.0 | C-1 | 15.0 | D-1 | 20.0 | F-5 | 3.0 | E-1/E-4 | 4280/1830 |
| Example 65 | J-65 | A-12 | 100 | B-6 | 15.0 | C-1 | 15.0 | D-1 | 20.0 | F-5 | 3.0 | E-1/E-4 | 4280/1830 |
| Example 66 | J-66 | A-12 | 100 | B-5 | 15.0 | C-1 | 15.0 | D-1 | 20.0 | F-5 | 3.0 | E-1/E-4 | 4280/1830 |
| Example 67 | J-67 | A-12 | 100 | B-11 | 15.0 | C-1 | 15.0 | D-1 | 20.0 | F-5 | 3.0 | E-1/E-4 | 4280/1830 |
| Example 68 | J-68 | A-12 | 100 | B-14 | 15.0 | C-1 | 15.0 | D-1 | 20.0 | F-5 | 3.0 | E-1/E-4 | 4280/1830 |
| Example 69 | J-69 | A-12 | 100 | B-1 | 15.0 | C-4 | 15.0 | D-1 | 20.0 | F-5 | 3.0 | E-1/E-4 | 4280/1830 |
| Example 70 | J-70 | A-12 | 100 | B-1 | 15.0 | C-6 | 15.0 | D-1 | 20.0 | F-5 | 3.0 | E-1/E-4 | 4280/1830 |
| Example 71 | J-71 | A-12 | 100 | B-1 | 15.0 | C-7 | 15.0 | D-1 | 20.0 | F-5 | 3.0 | E-1/E-4 | 4280/1830 |
| Example 72 | J-72 | A-12 | 100 | B-1 | 15.0 | C-8 | 15.0 | D-1 | 20.0 | F-5 | 3.0 | E-1/E-4 | 4280/1830 |
| Example 73 | J-73 | A-12 | 100 | B-1 | 15.0 | C-1 | 15.0 | D-4 | 20.0 | F-5 | 3.0 | E-1/E-4 | 4280/1830 |
| Example 74 | J-74 | A-13 | 100 | B-1 | 15.0 | C-1 | 15.0 | D-1 | 20.0 | F-5 | 3.0 | E-1/E-4 | 4280/1830 |
| Example 75 | J-75 | A-14 | 100 | B-1 | 15.0 | C-1 | 15.0 | D-1 | 20.0 | F-5 | 3.0 | E-1/E-4 | 4280/1830 |
| Example 76 | J-76 | A-15 | 100 | B-1 | 15.0 | C-1 | 15.0 | D-1 | 20.0 | F-5 | 3.0 | E-1/E-4 | 4280/1830 |
| Comparative | CJ-20 | A-12 | 100 | b-6 | 15.0 | C-1 | 15.0 | D-1 | 20.0 | F-5 | 3.0 | E-1/E-4 | 4280/1830 |
| Example 20 | | | | | | | | | | | | | |
| Comparative | CJ-21 | A-12 | 100 | b-7 | 15.0 | C-1 | 15.0 | D-1 | 20.0 | F-5 | 3.0 | E-1/E-4 | 4280/1830 |
| Example 21 | | | | | | | | | | | | | |
| Comparative | CJ-22 | A-12 | 100 | B-1 | 30.0 | — | — | D-1 | 20.0 | F-5 | 3.0 | E-1/E-4 | 4280/1830 |
| Example 22 | | | | | | | | | | | | | |
| Comparative | CJ-23 | A-12 | 100 | — | — | C-1 | 30.0 | D-1 | 20.0 | F-5 | 3.0 | E-1/E-4 | 4280/1830 |
| Example 23 | | | | | | | | | | | | | |
| Comparative | CJ-24 | A-12 | 100 | B-1/B-13 | 15.0/15.0 | — | — | D-1 | 20.0 | F-5 | 3.0 | E-1/E-4 | 4280/1830 |
| Example 24 | | | | | | | | | | | | | |
| Comparative | CJ-25 | A-12 | 100 | — | — | C-1/C-11 | 15.0/15.0 | D-1 | 20.0 | F-5 | 3.0 | E-1/E-4 | 4280/1830 |
| Example 25 | | | | | | | | | | | | | |

### <Formation of Resist Pattern Using Positive Radiation-Sensitive Resin Composition for EUV Exposure>

Onto the surface of a 12-inch silicon wafer, an underlayer antireflection film forming composition (“ARC66” manufactured by Brewer Science Incorporated) was applied with use of a spin coater (“CLEAN TRACK ACT12” manufactured by Tokyo Electron Limited). The wafer was then heated at 205° C. for 60 seconds to form an underlayer antireflection film having an average thickness of 105 nm. The positive radiation-sensitive resin composition for EUV exposure prepared above was applied onto the underlayer antireflection film with use of the spin coater, followed by performing PB at 130° C. for 60 seconds. Thereafter, cooling was performed at 23° C. for 30 seconds to form a resist film having an average thickness of 55 nm. Next, the resist film was exposed by an EUV exposure apparatus (“NXE3300”, manufactured by ASML) with NA of 0.33 under a lighting condition of Conventional s=0.89 and with a mask of imecDEFECT32FFR02. After exposing, PEB was performed at 120° C. for 60 seconds. Thereafter, the resist film was developed with an alkali with use of a 2.38% by mass aqueous TMAH solution as an alkaline developer, followed by washing with water and further drying to form a positive resist pattern (32 nm line-and-space pattern).

### <Evaluation>

The resist pattern formed using the positive radiation-sensitive resin composition for EUV exposure was evaluated on sensitivity, LWR performance, and pattern rectangularity in accordance with the following methods. The results are shown in the following Table 9. A scanning electron microscope (“CG-5000” manufactured by Hitachi High-Tech Corporation) was used for measuring the length of the resist pattern.

### [Sensitivity]

An exposure dose at which a 32 nm line-and-space pattern was formed in the aforementioned resist pattern formation using the positive radiation-sensitive resin composition for EUV exposure was defined as an optimum exposure dose, and this optimum exposure dose was defined as sensitivity (mJ/cm²). The sensitivity was evaluated to be “good” in a case of being 30 mJ/cm² or less, and “poor” in a case of exceeding 30 mJ/cm².

### [LWR Performance]

A resist pattern was formed by adjusting a mask size so as to form a 32 nm line-and-space pattern by irradiation with the optimum exposure dose obtained in the evaluation of the sensitivity. The formed resist pattern was observed from above the pattern with use of the scanning electron microscope. The variation in the line width was measured at a total of 500 points. The 3 sigma value was obtained from the distribution of the measurement values, and defined as LWR performance (nm). The smaller the value of the LWR is, the smaller the wobble of the line is, which is better. The LWR performance was evaluated to be “good” in a case of being 3.0 nm or less, and “poor” in a case of exceeding 3.0 nm.

### [Pattern Rectangularity]

The 32 nm line-and-space resist pattern formed by irradiation with the optimum exposure amount obtained in the evaluation of the sensitivity was observed using the scanning electron microscope, and the sectional shape of the line-and-space pattern was evaluated. The rectangularity of the resist pattern was evaluated as “A” (extremely good) when the ratio of the length of the lower side to the length of the upper side in the sectional shape was 1 or more and 1.05 or less, “B” (good) when the ratio was more than 1.05 and 1.10 or less, and “C” (poor) when the ratio was more than 1.10.

TABLE 9

| | Radiation- | | | |
|---|---|---|---|---|
| | sensitive | | | |
| | resin | Sensitivity | LWR | Pattern |
| | composition | (mJ/cm²) | (nm) | rectangularity |
| Example 64 | J-64 | 26 | 2.6 | A |
| Example 65 | J-65 | 27 | 2.4 | A |
| Example 66 | J-66 | 26 | 2.3 | A |
| Example 67 | J-67 | 25 | 2.5 | A |
| Example 68 | J-68 | 25 | 2.5 | A |
| Example 69 | J-69 | 27 | 2.3 | A |
| Example 70 | J-70 | 26 | 2.4 | A |
| Example 71 | J-71 | 27 | 2.8 | A |
| Example 72 | J-72 | 28 | 2.7 | A |
| Example 73 | J-73 | 25 | 2.7 | A |
| Example 74 | J-74 | 26 | 2.4 | A |
| Example 75 | J-75 | 26 | 2.7 | A |
| Example 76 | J-76 | 27 | 2.5 | A |
| Comparative | CJ-20 | 33 | 3.7 | C |
| Example 20 | | | | |
| Comparative | CJ-21 | 32 | 3.9 | C |
| Example 21 | | | | |
| Comparative | CJ-22 | 32 | 3.6 | C |
| Example 22 | | | | |
| Comparative | CJ-23 | 40 | 3.2 | B |
| Example 23 | | | | |
| Comparative | CJ-24 | 32 | 3.5 | C |
| Example 24 | | | | |
| Comparative | CJ-25 | 42 | 3.5 | B |
| Example 25 | | | | |

As is apparent from the results in Table 9, the radiation-sensitive resin compositions of Examples were good in sensitivity, LWR performance, and pattern rectangularity when used for EUV exposure, whereas the radiation-sensitive resin compositions of Comparative Examples were inferior in the characteristics to those of Examples.

### Preparation of Negative Radiation-Sensitive Resin Composition for ArF Exposure, and Formation and Evaluation of Resist Pattern Using this Composition

### Example 77

100 parts by mass of (A-1) as the resin [A], 6.0 parts by mass of (B-1) as the first onium salt compound [B], 6.0 parts by mass of (C-3) as the second onium salt compound [C], 6.0 parts by mass of (D-3) as the acid diffusion controlling agent [D], 3.0 parts by mass (solid content) of (F-4) as the high fluorine-content resin [F], and 3,230 parts by mass of a mixed solvent of (E-1)/(E-2)/(E-3) (blending amounts: 2240/960/30 parts by mass) as the solvent [E] were mixed, and the mixture was filtered through a membrane filter having a pore size of 0.2 μm to prepare a radiation-sensitive resin composition (J-77).

Onto the surface of a 12-inch silicon wafer, an underlayer antireflection film forming composition (“ARC66” manufactured by Brewer Science Incorporated) was applied with use of a spin coater (“CLEAN TRACK ACT12” manufactured by Tokyo Electron Limited). The wafer was then heated at 205° C. for 60 seconds to form an underlayer antireflection film having an average thickness of 100 nm. The negative radiation-sensitive resin composition for ArF exposure (J-77) prepared above was applied onto the underlayer antireflection film with use of the spin coater, followed by performing PB (pre-baking) at 100° C. for 60 seconds. Thereafter, cooling was performed at 23° C. for 30 seconds to form a resist film having an average thickness of 90 nm. Next, this resist film was exposed through a mask pattern having a hole of 40 nm and a pitch of 105 nm using an ArF excimer laser immersion exposure apparatus (“TWINSCAN XT-1900i” manufactured by ASML) with NA of 1.35 under an optical condition of Annular (σ=0.8/0.6). After the exposure, PEB (post exposure baking) was performed at 100° C. for 60 seconds. Thereafter, the resist film was developed with an organic solvent using n-butyl acetate as an organic solvent developer, and dried to form a negative resist pattern (contact hole pattern with hole of 40 nm and pitch of 105 nm).

The resist pattern using the negative radiation-sensitive resin composition for ArF exposure was evaluated on sensitivity in the same manner as in the evaluation of the resist pattern using the positive radiation-sensitive resin composition for ArF exposure. In addition, CDU performance and pattern circularity were evaluated in accordance with the following methods.

### [CDU Performance]

Contact holes with a 40 nm hole and a 105 nm pitch were formed by irradiation with an optimum exposure dose determined in the evaluation of sensitivity. The formed resist pattern was observed from above the pattern with use of the scanning electron microscope. The variation of the contact holes was measured at 500 points in total. The 3 sigma value was determined from the distribution of the measurement values, and defined as CDU (nm). The smaller the value of the CDU is, the smaller the roughness of the contact holes is, which is better. When the value was less than 3.5 nm, the CDU performance was evaluated to be “good”, and when the value was 3.5 nm or more, the CDU performance was evaluated to be “poor”.

### [Pattern Circularity]

The contact holes with a 40 nm hole and a 105 nm pitch formed by irradiation with the optimum exposure dose determined in the evaluation of sensitivity were observed in plan view using the scanning electron microscope, and the size in the longitudinal direction and the size in the lateral direction were measured. When the ratio of the size in the longitudinal direction to the size in the lateral direction was 0.95 or more and less than 1.05, the pattern circularity was evaluated as “A” (extremely good), when the ratio was 0.90 or more and less than 0.95, or 1.05 or more and less than 1.10, the pattern circularity was evaluated as “B” (good), and when the ratio was less than 0.90, or 1.10 or more, the pattern circularity was evaluated as “C” (poor).

As a result, the radiation-sensitive resin composition of Example 77 had good sensitivity, CDU performance, and pattern circularity even when a negative resist pattern was formed by ArF exposure.

### Preparation of Negative Radiation-Sensitive Resin Composition for EUV Exposure, and Formation and Evaluation of Resist Pattern Using this Composition

### Example 78

100 parts by mass of (A-15) as the resin [A], 15.0 parts by mass of (B-1) as the first onium salt compound [B], 15.0 parts by mass of (C-5) as the second onium salt compound [C], 10.0 parts by mass of (D-2) as the acid diffusion controlling agent [D], 3.0 parts by mass (solid content) of (F-5) as the high fluorine-content resin [F], and 6, 110 parts by mass of a mixed solvent of (E-1)/(E-4) (blending amounts: 4280/1830 parts by mass) as the solvent [E] were mixed, and the mixture was filtered through a membrane filter having a pore size of 0.2 μm to prepare a radiation-sensitive resin composition (J-78).

Onto the surface of a 12-inch silicon wafer, an underlayer antireflection film forming composition (“ARC66” manufactured by Brewer Science Incorporated) was applied with use of a spin coater (“CLEAN TRACK ACT12” manufactured by Tokyo Electron Limited). The wafer was then heated at 205° C. for 60 seconds to form an underlayer antireflection film having an average thickness of 105 nm. The negative radiation-sensitive resin composition for EUV exposure (J-78) prepared above was applied onto the underlayer antireflection film with use of the spin coater, followed by performing PB at 130° C. for 60 seconds. Thereafter, cooling was performed at 23° C. for 30 seconds to form a resist film having an average thickness of 55 nm. Next, the resist film was exposed by an EUV exposure apparatus (“NXE3300”, manufactured by ASML) with NA of 0.33 under a lighting condition of Conventional s=0.89 and with a mask of imecDEFECT32FFR15. After exposing, PEB was performed at 120° C. for 60 seconds. Thereafter, the resist film was developed with an organic solvent using n-butyl acetate as an organic solvent developer, and dried to form a negative resist pattern (contact hole pattern with hole of 25 nm and pitch of 50 nm).

The resist pattern formed using the negative radiation-sensitive resin composition for EUV exposure was evaluated in the same manner as the resist pattern formed using the negative radiation-sensitive resin composition for ArF exposure. As a result, the radiation-sensitive resin composition of Example 78 had good sensitivity, CDU performance, and pattern circularity even when a negative resist pattern was formed by EUV exposure.

According to the radiation-sensitive resin composition and the method for forming a resist pattern described above, a resist pattern having good sensitivity to exposure light and being superior in LWR performance, DOF performance, pattern rectangularity, CDU performance, and pattern circularity can be formed. Therefore, these can be suitably used for a machining process and the like of a semiconductor device in which micronization is expected to further progress in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive resin composition comprising:
a first onium salt compound represented by formula (1);
a second onium salt compound represented by formula (2), which is other than the first onium salt compound;
a resin comprising a structural unit having an acid-dissociable group; and
a solvent, 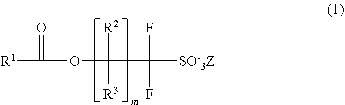
wherein,
R¹ is a substituted or unsubstituted monovalent hydrocarbon group having 1 to 5 carbon atoms or a group comprising a divalent hetero atom-containing group between two adjacent carbon atoms of the hydrocarbon group,
R² and R³ are each independently a hydrogen atom, a fluorine atom, a monovalent hydrocarbon group, or a monovalent fluorinated hydrocarbon group, when there are a plurality of R²s and R³s, the plurality of R²s are each the same or different from each other, and the plurality of R³s are each the same or different from each other,
m is an integer of 0 to 8, and
Z⁺ represents a monovalent radiation-sensitive onium cation, 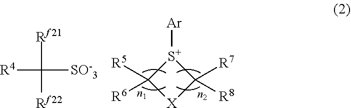
wherein,
R⁴ is a monovalent organic group having 1 to 40 carbon atoms,
one of R^{f21} and R^{f22} is a fluorine atom, and the other is a fluorine atom or a monovalent fluorinated hydrocarbon group,
Ar is a monovalent organic group comprising an aromatic ring having 5 to 40 ring atoms,
R⁵, R⁶, R⁷, and R⁸ each independently represent a hydrogen atom, a hydroxy group, a halogen atom, or a monovalent organic group having 1 to 20 carbon atoms, when there are a plurality of R⁵s, R⁶s, R⁷s, and R⁸s, the plurality of R⁵s are each the same or different from each other, the plurality of R⁶s are each the same or different from each other, the plurality of R⁷s are each the same or different from each other, and the plurality of R⁸s are each the same or different from each other,
n₁ and n₂ are each independently an integer of 1 to 6, and
X is a single bond or a divalent hetero atom-containing group.

2. The radiation-sensitive resin composition according to claim 1, wherein the first onium salt compound is represented by formula (1-1), 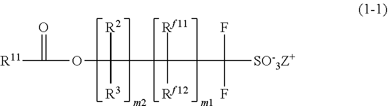
wherein,
R¹¹ is a substituted or unsubstituted monovalent saturated hydrocarbon group having 1 to 5 carbon atoms or a group containing a divalent hetero atom-containing group between two adjacent carbon atoms of the saturated hydrocarbon group,
R¹² and R¹³ are each independently a hydrogen atom or a monovalent hydrocarbon group, when there are a plurality of R¹²s and R¹³s, the plurality of R¹²s are each the same or different from each other, and the plurality of R¹³s are each the same or different from each other,
one of R^{f11} and R^{f12} is a fluorine atom, and the other is a hydrogen atom, a fluorine atom, or a monovalent fluorinated hydrocarbon group,
m1 is 0 or 1,
m2 is an integer of 1 to 6, and
Z⁺ is as defined in the formula (1).

3. The radiation-sensitive resin composition according to claim 1, wherein the second onium salt compound is represented by formula (2-1), 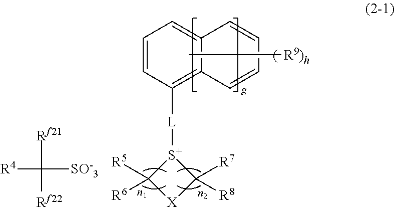
wherein, R⁴, R^{f21}, R^{f22}, R⁵, R⁶, R⁷, and R⁸ are each as defined in the formula (2),
X is a single bond or an oxygen atom,
L is a single bond or a divalent linking group,
R⁹ is a halogen atom, a hydroxy group, a carboxy group, a cyano group, a nitro group, a first group which is an alkyl group, an alkoxy group, an alkoxyalkoxy group, an alkoxycarbonyl group, an alkoxycarbonyloxy group, an acyl group, an acyloxy group, or a group in which a hydrogen atom of the first group has been substituted with a halogen atom, when there are a plurality of R⁹s, the plurality of R⁷s are the same or different from each other,
n₁ and n₂ are each independently an integer of 1 to 3,
g is 0 or 1, and
h is an integer of 0 to 4.

4. The radiation-sensitive resin composition according to claim 1, wherein the monovalent radiation-sensitive onium cation represented by Z⁺ is a sulfonium cation or an iodonium cation.

5. The radiation-sensitive resin composition according to claim 1, wherein R⁴ is a monovalent organic group having 3 to 40 carbon atoms and comprising a cyclic structure.

6. The radiation-sensitive resin composition according to claim 1, wherein a content of the first onium salt compound in the radiation-sensitive resin composition is 1 part by mass or more and 50 parts by mass or less based on 100 parts by mass of the resin.

7. The radiation-sensitive resin composition according to claim 1, wherein a mass ratio (a/b) of a mass content of the first onium salt compound (a) to a mass content of the second onium salt compound (b) in the radiation-sensitive resin composition is 0.01 or more and 20 or less.

8. The radiation-sensitive resin composition according to claim 1, wherein the structural unit having an acid-dissociable group is represented by formula (3), 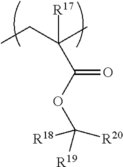
wherein,
R¹⁷ is a hydrogen atom, a fluorine atom, a methyl group, or a trifluoromethyl group,
R¹⁸ is a monovalent hydrocarbon group having 1 to 20 carbon atoms,
R¹⁹ and R²⁰ are each independently a monovalent chain hydrocarbon group having 1 to 10 carbon atoms or a monovalent alicyclic hydrocarbon group having 3 to 20 carbon atoms, or R¹⁹ and R²⁰ taken together represent a divalent alicyclic group having 3 to 20 carbon atoms together with the carbon atom to which R¹⁹ and R²⁰ are bonded.

9. The radiation-sensitive resin composition according to claim 1, further comprising an acid diffusion controlling agent.

10. A pattern formation method, the method comprising:
applying the radiation-sensitive resin composition according to claim 1 directly or indirectly to a substrate to form a resist film;
exposing the resist film; and
developing the exposed resist film with a developer.

11. The pattern formation method according to claim 10, wherein exposing the resist film comprises exposing the resist film to an ArF excimer laser.
